(19) United States
(12) Patent Application Publication
(10) Pub. No.: US 2026/0117121 A1
(43) Pub. Date: Apr. 30, 2026

(54) QUANTUM DOT, ELECTRONIC DEVICE INCLUDING THE SAME AND ELECTRONIC APPARATUS INCLUDING THE ELECTRONIC DEVICE

(71) Applicant: Samsung Display Co., Ltd., Yongin-si (KR)

(72) Inventors: Kyungsig Lee, Yongin-si (KR); Taekjoon Lee, Yongin-si (KR); Seunghee Jang, Yongin-si (KR); Jaebok Chang, Yongin-si (KR)

(21) Appl. No.: 19/364,974

(22) Filed: Oct. 21, 2025

(30) Foreign Application Priority Data
Oct. 28, 2024 (KR) 10-2024-0148962
Mar. 26, 2025 (KR) 10-2025-0039049

(51) Int. Cl. C09K 11/62; B82Y 20/00; H10K 50/115

(52) U.S. Cl. CPC C09K 11/623; B82Y 20/00; C09K 2211/10; C09K 2211/14; H10K 50/115

(57) ABSTRACT

A quantum dot, an electronic device including the quantum dot, and an electronic apparatus including the electronic device are disclosed. The quantum dot may include a core including CuInGaS₂, a shell around (e.g., surrounding) at least a portion of the core, and a metal-containing ligand around (e.g., surrounding) at least a portion of the shell. The metal-containing ligand may include a metal and a repeating unit represented by Formula 1.

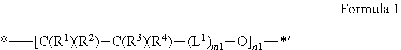

### CROSS-REFERENCE TO RELATED APPLICATIONS

The present application claims priority to and the benefit of Korean Patent Application No. 10-2024-0148962, filed on Oct. 28, 2024, and Korean Patent Application No. 10-2025-0039049, filed on Mar. 26, 2025, in the Korean Intellectual Property Office, the entire disclosures of both of which are incorporated herein by reference.

### BACKGROUND

### 1. Field

One or more embodiments of the present disclosure relate to a quantum dot, an electronic device including the quantum dot, and an electronic apparatus including the electronic device.

### 2. Description of the Related Art

Quantum dots may be utilized as materials that perform one or more suitable optical functions (e.g., photo-conversion and/or light emission) in optical components and one or more suitable electronic devices. Quantum dots are semiconductor nanocrystals of nanoscale size that exhibit optoelectronic properties due to the quantum confinement effect. By adjusting or optimizing the size and composition of the nanocrystals, quantum dots may have different energy bandgaps leading to emission of light having one or more emission wavelengths.

An optical component including the quantum dots may be in the form of a thin film, for example, a thin film patterned on the basis of sub-pixels. The optical member may be utilized as a color conversion member of devices including one or more suitable light sources.

Also, quantum dots may be utilized in one or more suitable types or kinds of electronic devices for one or more suitable purposes. For example, the quantum dots may be utilized as emitters (e.g., photon emitters or light emitters). For example, quantum dots may be included in an emission layer of a light-emitting device including a pair of electrodes and the emission layer, serving as emitters (e.g., photon emitters or light emitters).

To realize high-quality optical components and electronic devices, it is desirable to develop quantum dots having high external quantum efficiency (EQE) and a long lifespan.

### SUMMARY

One or more aspects of embodiments of the present disclosure are directed toward quantum dots having a high external quantum efficiency and long lifespan and easily applied to an inkjet process.

Additional aspects of embodiments will be set forth in part in the description which follows and, in part, will be apparent from the description, or may be learned by practice of the presented embodiments of the disclosure.

According to one or more embodiments, a quantum dot includes a core including CuInGaS₂, a shell around (e.g., surrounding) at least a portion of the core, and a metal-containing ligand around (e.g., surrounding) at least a portion of the shell, wherein the metal-containing ligand includes a metal and a repeating unit represented by Formular 1.

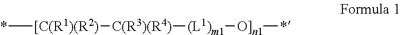

In Formula 1,
L¹ is a C₁-C₆₀ alkylene group unsubstituted or substituted with at least one R₁₀ₐ,
m1 is 0 or 1,
n1 is 1 to 20,
R¹ to R⁴ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
wherein R₁₀ₐ is
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ are each independently,
hydrogen, deuterium, —F, —Cl, —Br, —I, a hydroxyl group, a cyano group, or a nitro group, or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ are each independently a binding site with a neighboring atom.

According to one or more embodiments, an electronic device includes a first electrode, a second electrode opposite to the first electrode, an intermediate layer between the first electrode and the second electrode, a thin film transistor electrically connected to the first electrode, and the quantum dot as described in one or more embodiments.

According to one or more embodiments, an electronic apparatus includes the electronic device as described in one or more embodiments and at least one selected from among a processor configured or provided to transmit a signal to the electronic device, a memory configured or provided to store data information for an operation of the electronic device, and a power module configured or provided to supply power for the operation of the electronic device.

### BRIEF DESCRIPTION OF THE DRAWINGS

The above and other aspects and features of certain embodiments of the present disclosure will be more apparent from the following description taken in conjunction with the accompanying drawings, in which:

FIG. 1 illustrates energy levels of a quantum dot not including a metal-containing ligand and a quantum dot including a metal-containing ligand;

FIG. 2 is a diagram schematically illustrating an electronic device according to one or more embodiments;

FIG. 3 is a diagram schematically illustrating an electronic device according to one or more embodiments;

FIG. 4 is a diagram schematically illustrating an intermediate layer included in an electronic device according to one or more embodiments;

FIG. 5 is a diagram schematically illustrating an electronic device according to one or more embodiments;

FIG. 6 is a diagram schematically illustrating an electronic device according to one or more embodiments;

FIG. 7 is a block diagram of an electronic apparatus including an electronic device according to one or more embodiments;

FIG. 8 is a schematic diagram illustrating electronic apparatuses according to one or more embodiments;

FIG. 9 is a perspective view schematically illustrating an electronic apparatus including an electronic device according to one or more embodiments;

FIG. 10 is a diagram schematically illustrating the exterior of a vehicle as an electronic apparatus including an electronic device according to one or more embodiments; and

FIGS. 11A-11C are diagrams schematically illustrating the interior of the vehicle of FIG. 10.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the figures, to explain the aspects and features of the present disclosure to those skilled in the art.

The singular forms, “a,” “an,” and “the,” include plural references unless the context clearly requires otherwise.

As used herein, the term “and/or” includes any and all combinations of one or more of the associated listed items. For example, “A and/or B” indicates cases where it is A, B, or both (e.g., simultaneously) A and B.

The utilization of “may” if (e.g., when) describing embodiments of the present disclosure refers to “one or more embodiments of the present disclosure.”

In the context of the present disclosure and unless otherwise defined, the terms, “use,” “using,” and “used,” may be considered synonymous with the terms, “utilize,” “utilizing,” and “utilized,” respectively.

Throughout the disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms, “substantially,” “about,” and/or the like, are used as terms of approximation and not as terms of degree and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the claims, to expressly recite any sub-range subsumed within the ranges expressly recited herein.

The term “is bonded to” refers to that two atoms are directly bonded to each other via a covalent bond, a coordinate covalent bond, and/or the like without an intervening atoms therebetween.

The term “is connected to” not only refers to “is bound to”, but also encompasses a case where one or more other atoms may be present between two atoms. For example, if (e.g., when) a first atom is bonded to a second atom and the second atom is bonded to a third atom, the first atom is connected to the third atom.

For example, if (e.g., when) atoms A₁ to A₃ are in an “A₁-A₂-A₃” relationship, atom A₂ is bonded to atom A₁ connected to atom A₁, atom A₂ is bonded to atom A₃ and connected to atom A₃, and atom A₁ is not bonded to atom A₃ but connected to atom A₃.

According to one or more embodiments, a quantum dot may include: a core including CuInGaS₂; a shell around (e.g., surrounding) at least a portion of the core; and a metal-containing ligand around (e.g., surrounding) at least a portion of the shell, wherein the metal-containing ligand includes a metal and a repeating unit represented by Formular 1.

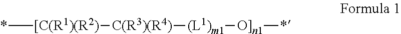

In Formula 1,
L¹ may be a C₁-C₆₀ alkylene group unsubstituted or substituted with at least one R₁₀ₐ,
m1 may be 0 or 1,
n1 may be 1 to 20, and
R¹ to R⁴ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
wherein R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ may each independently be a binding site with a neighboring atom.

For example, the quantum dot may include both (e.g., simultaneously) the CuInGaS₂ core and the metal-containing ligand and may be clearly different from quantum dots including a CuInS core or AgCuInGaS core and a metal-containing ligand, as well as from quantum dots including a CuInGaS₂ core and a metal-free ligand.

According to one or more embodiments, the metal may be connected to the repeating unit represented by Formula 1. For example, the metal-containing ligand may further include a linker connecting the metal with the repeating unit.

According to one or more embodiments, the quantum dot may absorb light having a wavelength of 400 nm to 500 nm and emit light having a wavelength of 600 nm to 680 nm. For example, the quantum dot may absorb blue light and emit red light.

According to one or more embodiments, a difference between a conduction band minimum (CBM) of the core and a CBM of the shell surrounded by the metal-containing ligand may be greater than 0.3 eV. For example, the difference between the CBM of the core and the CBM of the shell surrounded by the metal-containing ligand may be about 0.4 eV to about 2.0 eV, about 0.5 eV to about 2.0 eV, about 0.6 eV to about 2.0 eV, about 0.7 eV to about 2.0 eV, about 0.4 eV to about 1.5 eV, about 0.4 eV to about 1.0 eV, about 0.4 eV to about 0.9 eV, about 0.4 eV to about 0.8 eV, or about 0.5 eV to about 0.8 eV. By satisfying the foregoing ranges, excited electrons of the core may not easily migrate to the shell surrounded by the metal-containing ligand. If (e.g., when) the difference between the CBM of the core and the CMB of the shell surrounded by the metal-containing ligand is less than the foregoing ranges, excited electrons of the core may easily migrate to the shell surrounded by the metal-containing ligand. The CBM of the core may be equal to or less than the CBM of the shell surrounded by the metal-containing ligand. The CBM of the CuInGaS₂ core may be about −2.6 eV. For example, a CBM of an AgInGaS core may be about −3.5 eV, a CBM of a CuInS core may be about −3.2 eV, and a CBM of an InGaP core may be about −3.8 eV.

According to one or more embodiments, a difference between a lattice constant of the core and a lattice constant of the shell may be about 0 Å to about 0.2 Å. For example, the lattice constant of the core may be equal to the lattice constant of the shell. For example, the difference between the lattice constant of the core and the lattice constant of the shell may be about 0 Å to about 0.15 Å, about 0 Å to about 0.1 Å, or about 0 Å to about 0.5 Å. The lattice constant of the CuInGaS₂ core may be about 5.3 Å to about 5.5 Å, about 5.3 Å to about 5.4 Å, about 5.4 Å to about 5.5 Å, or 5.4 Å. The lattice constant of the shell may be about 5.1 Å to about 5.7 Å, about 5.1 Å to about 5.6 Å, about 5.1 Å to about 5.5 Å, about 5.1 Å to about 5.4 Å, about 5.3 Å to about 5.7 Å, about 5.3 Å to about 5.6 Å, about 5.3 Å to about 5.5 Å, about 5.3 Å to about 5.4 Å, or about 5.4 Å. By satisfying the foregoing ranges, a degree of lattice mismatch between the core and the shell is small, so that (e.g., such that) the quantum dot may have a relatively high external quantum efficiency (EQE). Outside the foregoing ranges, the lattice mismatch between the core and the shell increases, so that (e.g., such that) the quantum dot may have a relatively low EQE. The lattice constant of the CuInGaS₂ core may be 5.4 Å. For example, a lattice constant of the AgInGaS core may be about 5.7 Å to about 5.9 Å, a lattice constant of the CuInS core may be about 5.52 Å, and a lattice constant of the InGaP core may be about 5.8 Å to about 5.9 Å.

According to one or more embodiments, the shell may include ZnS, ZnMgS, ZnMnS, ZnAlS, MnS, or any combination thereof. For example, the shell may exclude ZnSe having a lattice constant of 5.7 Å and MgS having a lattice constant of 5.7 Å. A lattice constant of ZnS may be 5.4 Å. A lattice constant of ZnMgS may be 5.5 Å. A lattice constant of ZnMnS may be 5.5 Å. A lattice constant of ZnAlS may be 5.4 Å. A lattice constant of MnS may be 5.6 Å.

According to one or more embodiments, a mole fraction of the metal-containing ligand based on a total number of moles of the ligands around (e.g., surrounding) the shell may be about 70% to about 100%. For example, the quantum dot may further include a metal-free ligand as well as the metal-containing ligand around (e.g., surrounding) at least a portion of the shell. The metal-free ligand may include oleylamine, oleic acid, a compound represented by mPEG4-COO—H, and/or a compound represented by mPEG4-S—H, but embodiments of the present disclosure are not limited thereto.

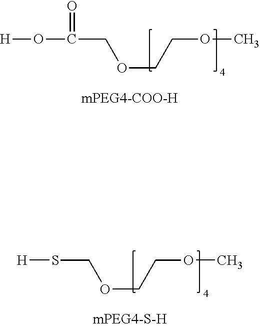

The quantum dot according to one or more embodiments may be formed or provided by forming or providing a quantum dot including only the metal-free ligand as the ligand around (e.g., surrounding) at least a portion of the shell, and then substituting one or more or all moles of the metal-free ligand with the metal-containing ligand. Therefore, the mole fraction of the metal-containing ligand based on the total number of moles of the ligands around (e.g., surrounding) the shell may also be referred to as substitution rate.

For example, the mole fraction of the metal-containing ligand based on the total number of moles of the ligands around (e.g., surrounding) the shell (substitution rate) may be about 75% to about 100%, about 80% to about 100%, about 70% to about 95%, about 70% to about 90%, about 70% to about 85%, or about 70% to about 80%. By satisfying the foregoing ranges, the CBM of the shell surrounded by the metal-containing ligand may be effectively or suitably increased. Thus, excited electrons of the core may not easily migrate to the shell surrounded by the metal-containing ligand.

According to one or more embodiments, the metal-containing ligand may have a molecular weight of about 200 g/mol to about 1000 g/mol. If (e.g., when) the molecular weight of the metal-containing ligand is less than the foregoing range, dispersibility of the quantum dot may decrease. If (e.g., when) the molecular weight of the metal-containing ligand is greater than the foregoing range, viscosity of a composition including the quantum dot may excessively or substantially increase. Therefore, by satisfying the foregoing range, the quantum dot may be easily applied to an inkjet process.

According to one or more embodiments, the metal may be Mg, Mn, or Zn. If (e.g., when) the metal is selected from among Mg, Mn, and Zn, the metal-containing ligand may be effectively or suitably bound to the shell due to electrostatic attraction and/or the like, and the quantum dot may have a high external quantum efficiency (EQE).

According to one or more embodiments, in Formula 1, m1 may be 0. For example, a backbone of the repeating unit may include two carbon atoms and one oxygen atom.

According to one or more embodiments, in Formula 1, R¹ to R⁴ may each independently be hydrogen, deuterium, —F, —Cl, —Br, —I, a hydroxyl group, a cyano group, or a C₁-C₆₀ alkyl group unsubstituted or substituted with at least one R₁₀ₐ. For example, R¹ to R⁴ may each independently be hydrogen or deuterium.

According to one or more embodiments, the metal-containing ligand may be represented by Formula 2.

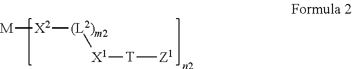

In Formula 2,
M may be the metal,
n2 may be 1 to 6,
T may be a repeating unit represented by Formula 1, * of Formula 1 may be a binding site with X¹ of Formula 2, and *′ of Formula 1 may be a binding site with Z¹ of Formula 2,
L² may be a C₁-C₆₀ alkylene group unsubstituted or substituted with at least one R₁₀ₐ,
m2 may be 0 or 1,
X¹ may be O or S,
X² may be *¹—O(C═O)—*², *¹—O—*², *¹—S—*², *¹—N(Z²)—*² or *¹—P(Z²)—*², wherein *¹ is a binding site with M and *² is a binding site with L² or X¹,
Z¹ and Z² may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
R₁₀ₐ and Q₁ to Q₃ may be the same as defined in Formula 1, respectively.

In Formula 2, X²-(L²)ₘ₂-X¹ may be referred to as the linker as described in one or more embodiments.

According to one or more embodiments, n2 of Formula 2 may be 1.

According to one or more embodiments, the metal-containing ligand may be selected from the group consisting of compounds represented by Mg-COO-mPEG4, Mg-S-mPEG4, Mn-COO-mPEG4, Mn-S-mPEG4, Zn-COO-mPEG4, and Zn-S-mPEG4.

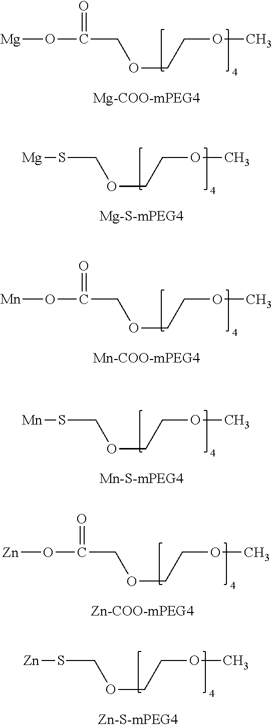

In the compound represented by Mg-COO-mPEG4, Mg refers to the metal (or M in Formula 2) and COO refers to X² of Formula 2, and 4 of mPEG4 refers to n1 of Formula 1. For example, the metal-containing ligand may be a compound represented by Mg-COO-mPEG1, Mg-COO-mPEG5, Mg-COO-mPEG6, Mg-COO-mPEG10, Mg-COO-mPEG20, Mg-O-mPEG4, Mg-N-mPEG4 (where X² in Formula 2 is *¹—N(Z²)—*²), Mg-P-mPEG4 (where X² in Formula 2 is *¹—P(Z²)—*²), Mn-COO-mPEG10, Mn-COO-mPEG20, Mn-O-mPEG4, Mn-N-mPEG4, Mn-P-mPEG4, Zn-COO-mPEG10, Zn-COO-mPEG20, Zn-O-mPEG4, Zn-N-mPEG4, Zn-P-mPEG4, and/or the like.

Hereinafter, if (e.g., when) one or more or all moles of the metal-free ligand are substituted with the metal-containing ligand, the metal-containing ligand may be indicated regardless of the presence or absence of the metal-free ligand. For example, a quantum dot including a CuInGaS₂ core, a ZnS shell, and a Mg-COO-mPEG4 ligand may be represented by CuInGaS₂/ZnS/Mg-COO-mPEG4 which may or may not include the oleylamine ligand.

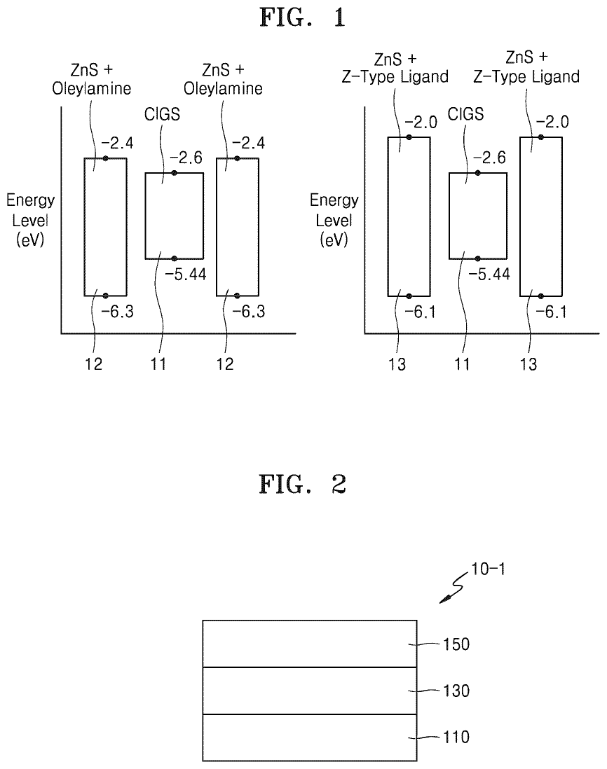

FIG. 1 illustrates energy levels of a quantum dot including a CuInGaS₂ core, a ZnS shell, and an oleylamine ligand (excluding a metal-containing ligand) and energy levels of a quantum dot in which the oleylamine ligand is substituted with the metal-containing ligand.

Referring to FIG. 1, the CuInGaS₂ core 11 (abbreviated as CIGS) has a conduction band minimum (CBM) of about −2.6 eV and a valence band maximum (VBM) of about −5.44 eV, and the ZnS shell 12 surrounded by the oleylamine ligand has a CBM of about −2.4 eV and a VBM of about −6.3 eV. The ZnS shell 13 in which one or more or all moles of the oleylamine ligand are substituted with the metal-containing ligand has a CBM of about −2.0 eV and a VBM of about −6.1 eV. The CBM and VBM may be measured by the ultraviolet photoelectron spectroscopy (UPS).

In the quantum dot having the CuInGaS₂/ZnS/oleylamine structure, a difference between the CBM of the core and the CBM of the shell surrounded by the ligand is relatively small, so that (e.g., such that) excited electrons of the core may easily migrate to the shell. Therefore, there may be a higher possibility that the ligand detaches from the surface of the quantum dot.

In the quantum dot having the CuInGaS₂/ZnS/metal-containing ligand structure, a difference between the CBM of the core and the CBM of the shell surrounded by the metal-containing ligand is relatively large because the CBM of the shell surrounded by the ligand increases, so that (e.g., such that) excited electrons of the core may not easily migrate to the shell. Therefore, the possibility that the ligands (e.g., a metal-containing ligand and/or a metal-free ligand) detach from the surface of the quantum dot may be reduced.

Table 1 shows CBMs and VBMs of a case in which the oleylamine ligand is applied to ZnS shells with a small lattice mismatch with or the substantially identical lattice constant to that of the CuInGaS₂ core. Table 1 also shows CBMs and VBMs of a case in which one or more or all moles of the oleylamine ligand are substituted with the ligands shown in Table 1.

TABLE 1

| | | | | Difference of CBM |
|---|---|---|---|---|
| | | | | from that of |
| | | CBM | VBM | CuInGaS₂ core |
| Shell | Ligand | (eV) | (eV) | (eV) |
| ZnS | oleylamine | −2.3 | −6.3 | 0.3 |
| | mPEG4-COO—H | −2.4 | −6.3 | 0.2 |
| | mPEG4-S—H | −2.3 | −6.3 | 0.3 |
| | Mg—COO-mPEG4 | −1.9 | −6.1 | 0.7 |
| | Mg—S-mPEG4 | −2.0 | −6.1 | 0.6 |

Based on Table 1, if (e.g., when) one or more or all moles of the oleylamine ligand are substituted with the metal-containing ligand in the quantum dot including the CuInGaS₂ core and the ZnS shell, excited electrons of the core may not easily migrate to the shell, and thus the possibility that the ligand detaches from the surface of the quantum dot may be reduced. Because the external quantum efficiency (EQE) of the quantum dot may be reduced by detachment of the ligand, the quantum dot including the CuInGaS₂ core, the ZnS shell having a small lattice mismatch with or substantially the same lattice constant as the lattice constant of the core, and the metal-containing ligand may have a high EQE.

According to one or more embodiments, a quantum dot composition may include the quantum dot as described in one or more embodiments and a monomer that dissolves the quantum dot.

The monomer may include 1,6-hexanediol diacrylate, cyclopentylbenzene, cyclohexylbenzene, dodecane, tridecane, tetradecane, pentadecane, hexadecane, heptadecane, octadecane, nonadecane, icosane, hexylbenzene, heptylbenzene, octylbenzene, nonylbenzene, decylbenzene, or any combination thereof.

According to one or more embodiments, the quantum dot composition may further include a scattering agent (e.g., a light scattering agent), a photoinitiator, an additive, or any combination thereof. The scattering agent may be TiO₂, the photoinitiator may be diphenyl(2,4,6-trimethylbenzoyl)phosphine oxide (TPO), and the additive may be an amine-based light stabilizer (e.g., hindered amine light stabilizers (HALS)) type or kind antioxidant, without being limited thereto.

According to one or more embodiments, a weight ratio of the quantum dot may be about 25 wt % to about 35 wt % and a weight ratio of the monomer may be about 55 wt % to about 75 wt % based on a total weight (e.g., based on 100 wt %) of the quantum dot composition. For example, the weight ratio of the quantum dot may be 30 wt %, and the weight ratio of the monomer may be 64 wt %.

The quantum dot composition having appropriate or suitable viscosity and dispersibility may be utilized in an inkjet process.

According to one or more embodiments, an electronic device may include: a first electrode; a second electrode opposite to the first electrode; an intermediate layer between the first electrode and the second electrode; a thin film transistor electrically connected to the first electrode; and the quantum dot as described in one or more embodiments.

FIG. 2 is a schematic cross-sectional view of an electronic device 10-1 according to one or more embodiments.

Referring to FIG. 2, the electronic device 10-1 may include a first electrode 110, an intermediate layer 130, and a second electrode 150. The electronic device 10-1 may further include other components in addition to the first electrode 110, the intermediate layer 130, and the second electrode 150, for example, components located or provided outside the first electrode 110 and/or components located or provided outside the second electrode 150. A structure formed or composed of the first electrode 110, the intermediate layer 130, and the second electrode 150 may also be referred to as a light-emitting element. As used herein, the term “intermediate layer” refers to a single layer and/or two or more layers disposed or provided between the first electrode and the second electrode of the light-emitting element.

The intermediate layer 130 may include a hole transport region, an emission layer, and an electron transport region that are sequentially stacked on the first electrode 110. For example, the hole transport region may be disposed or provided between the first electrode 110 and the emission layer, and the electron transport region may be disposed or provided between the emission layer and the second electrode 150. The hole transport region, the emission layer, and the electron transport region may collectively be referred to as a stack ST. If (e.g., when) a plurality of stacks STs are provided, the light-emitting element may be a tandem light-emitting element. Each of the plurality of stacks STs may be referred to as a first stack, a second stack, and/or the like, and the tandem light-emitting element may further include a charge generation layer (CGL) disposed or provided between the plurality of stacks STs. The tandem light-emitting element will be described in more detail herein with reference to FIG. 4.

### First Electrode 110

A substrate may further be disposed or provided on the lower side of the first electrode 110 or on the upper side of the second electrode 150 as illustrated in FIG. 2. The substrate may be a glass substrate and/or a plastic substrate. The substrate may be a flexible substrate. For example, the substrate may include a plastic having excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed or provided by applying a first electrode-forming material to the upper side of the substrate by deposition and/or sputtering. If (e.g., when) the first electrode 110 is an anode, a high work function material suitable for hole injection may be used as the first electrode-forming material.

The first electrode 110 may be a reflective electrode, a semi-transparent electrode, or a transparent electrode. To form or provide the first electrode 110 as a transparent electrode, indium tin oxide (ITO), indium zinc oxide (IZO), tin oxide (e.g., SnOₖ, wherein 0<k≤2; e.g., SnO₂), zinc oxide (e.g., ZnOₓ, wherein 0<x≤2; e.g., ZnO), or any combination thereof may be used as the first electrode-forming material. To form or provide the first electrode 110 as a semi-transparent electrode or reflective electrode, magnesium (Mg), silver (Ag), aluminum (Al), aluminum-lithium (Al—Li), calcium (Ca), magnesium-indium (Mg—In ), magnesium-silver (Mg—Ag), or any combination thereof may be used as the first electrode-forming material.

The first electrode 110 may have a single-layer structure consisting of (e.g., including) a single layer or a multi-layer structure including a plurality of layers. For example, the first electrode 110 may have a three-layer structure of ITO/Ag/ITO.

### Hole Transport Region

The hole transport region may have i) a single-layer structure consisting of (e.g., including) a single layer consisting of (e.g., including) a single material, ii) a single-layer structure consisting of (e.g., including) a single layer including a plurality of different materials, or iii) a multi-layer structure including a plurality of layers including a plurality of different materials.

The hole transport region may include a hole injection layer, a hole transport layer, an emission auxiliary layer, an electron blocking layer, or any combination thereof.

For example, the hole transport region may have a multi-layer structure of hole injection layer/hole transport layer, hole injection layer/hole transport layer/emission auxiliary layer, hole injection layer/emission auxiliary layer, hole transport layer/emission auxiliary layer, or hole injection layer/hole transport layer/electron blocking layer, each sequentially stacked on the first electrode 110.

The hole transport region may include a compound represented by Formula 201, a compound represented by Formula 202, or any combination thereof.

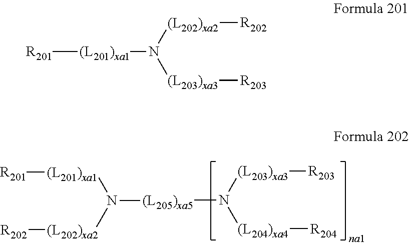

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer of 0 to 5,
xa5 may be an integer of 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be connected to each other via a single bond (e.g., a single covalent bond), a C₁-C₅alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ (e.g., carbazole group) (e.g., See Compound HT16),
R₂₀₃ and R₂₀₄ may optionally be connected to each other via a single bond (e.g., a single covalent bond), a C₁-C₅alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer of 1 to 4.

For example, each of Formulae 201 and 202 may include at least one selected from among the groups represented by Formulae CY201 to CY217.

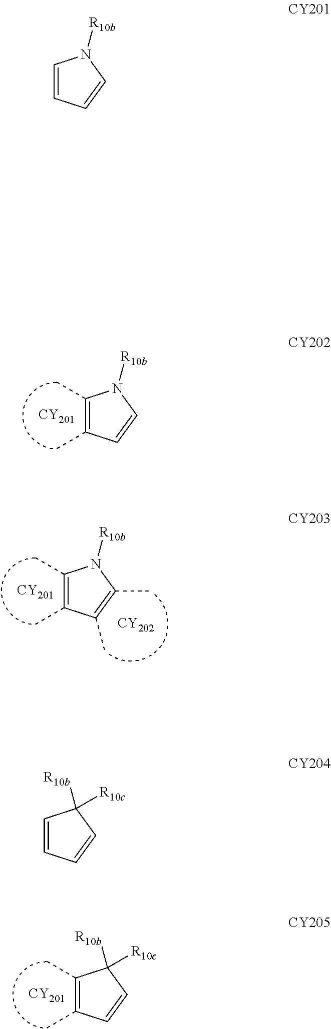

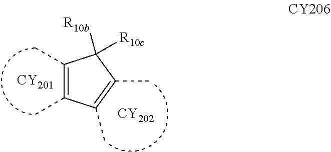

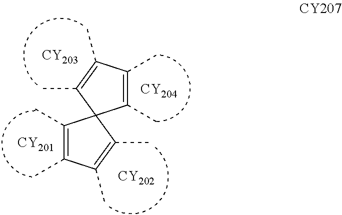

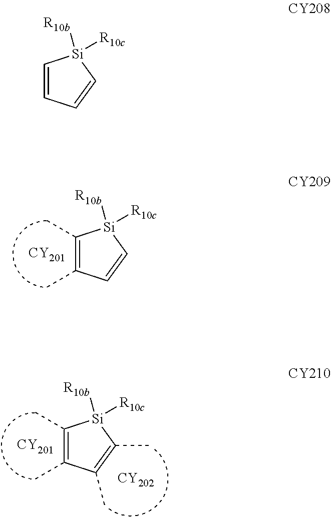

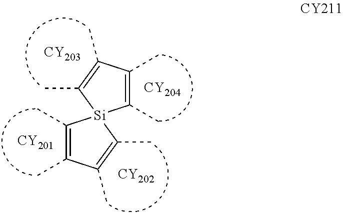

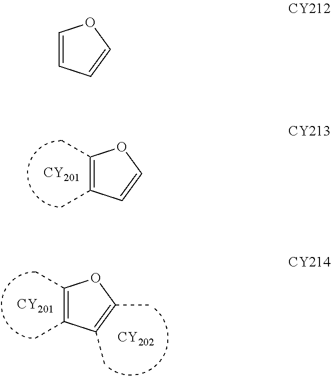

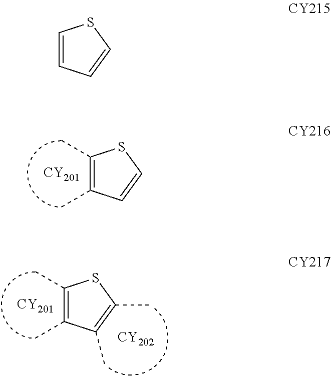

For descriptions of R_{10b} and R_{10c} in Formulae CY201 to CY217, refer to the description of R₁₀ₐ provided in one or more embodiments. Rings CY201 to CY204 may each independently be a C₃-C₂₀ carbocyclic group or a C₁-C₂₀ heterocyclic group, and at least one hydrogen of Formulae CY201 to CY217 may be unsubstituted or substituted with R₁₀ₐ as described in one or more embodiments.

According to one or more embodiments, the rings CY201 to CY204 in Formulae CY201 to CY217 may each independently be a benzene group, a naphthalene group, a phenanthrene group, or an anthracene group.

According to one or more embodiments, each of Formulae 201 and 202 may include at least one selected from among the groups represented by Formulae CY201 to CY203.

According to one or more embodiments, Formula 201 may include at least one selected from among the groups represented by Formulae CY201 to CY203 and at least one selected from among the groups represented by Formulae CY204 to CY217.

According to one or more embodiments, the xa1 of Formula 201 may be 1, R₂₀₁ may be one selected from among the groups represented by Formulae CY201 to CY203, the xa2 may be 0, and R₂₀₂ may be one selected from among the groups represented by Formulae CY204 to CY207.

According to one or more embodiments, each of Formulae 201 and 202 may exclude the groups represented by Formulae CY201 to CY203.

According to one or more embodiments, each of Formulae 201 and 202 may exclude the groups represented by Formulae CY201 to CY203 and may include at least one selected from among the groups represented by Formulae CY204 to CY217.

According to one or more embodiments, each of Formulae 201 and 202 may exclude the groups represented by Formulae CY201 to CY217.

For example, the hole transport region may include one selected from among Compounds HT1 to HT46, m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), polyaniline/poly(4-styrenesulfonate) (PANI/PSS), or any combination thereof.

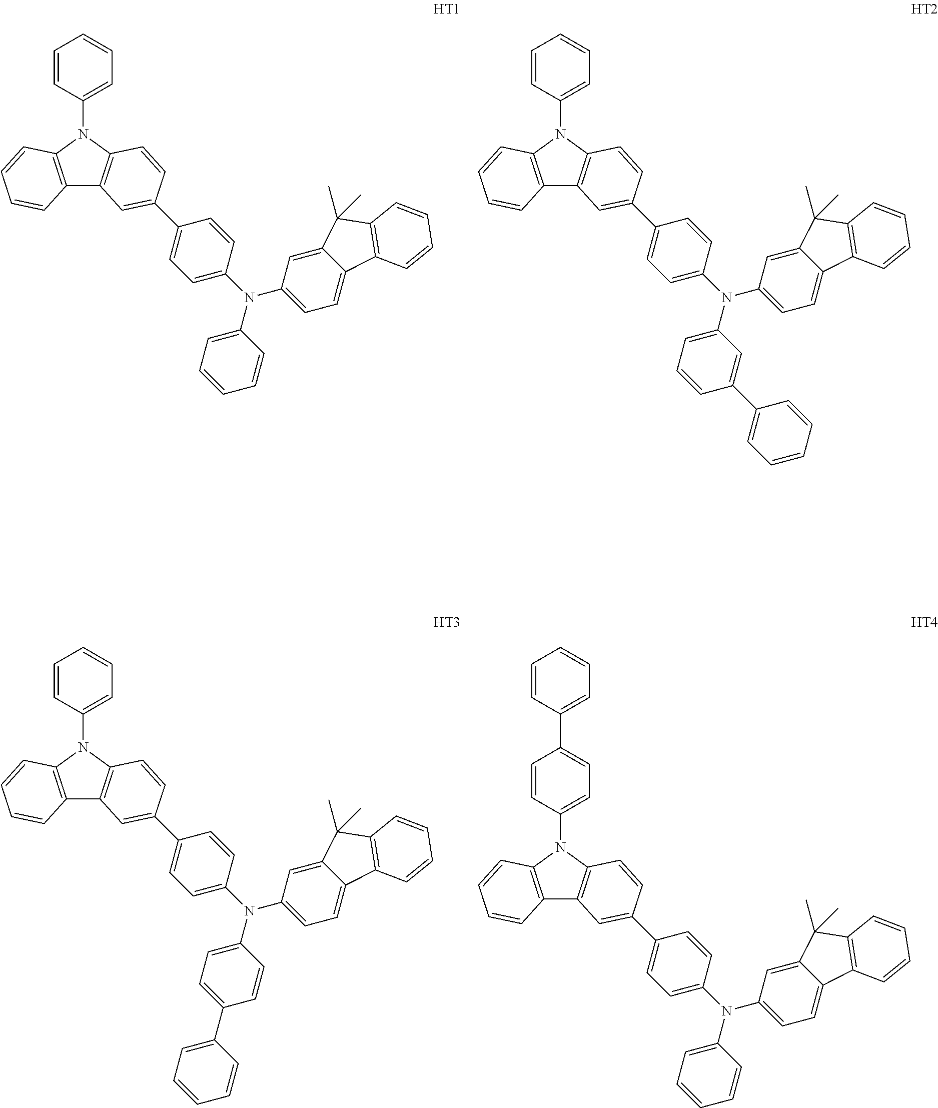 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

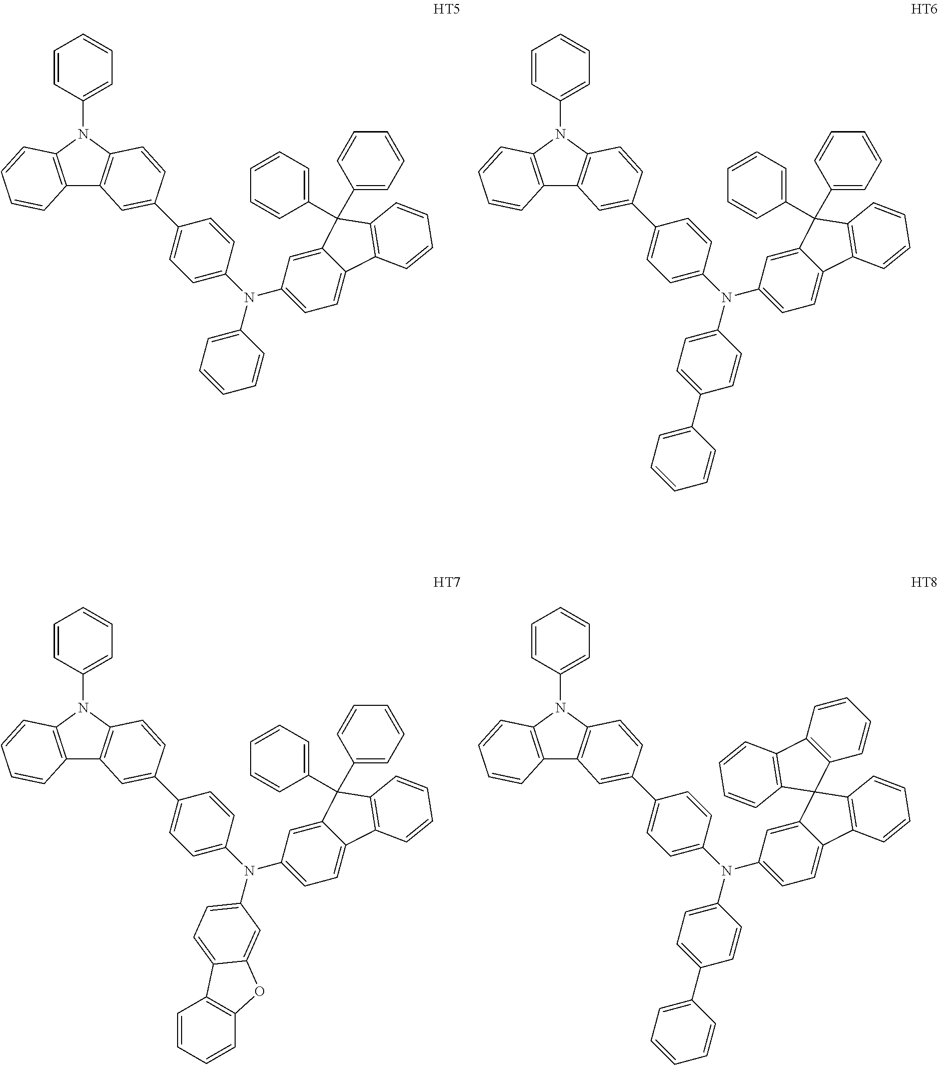 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

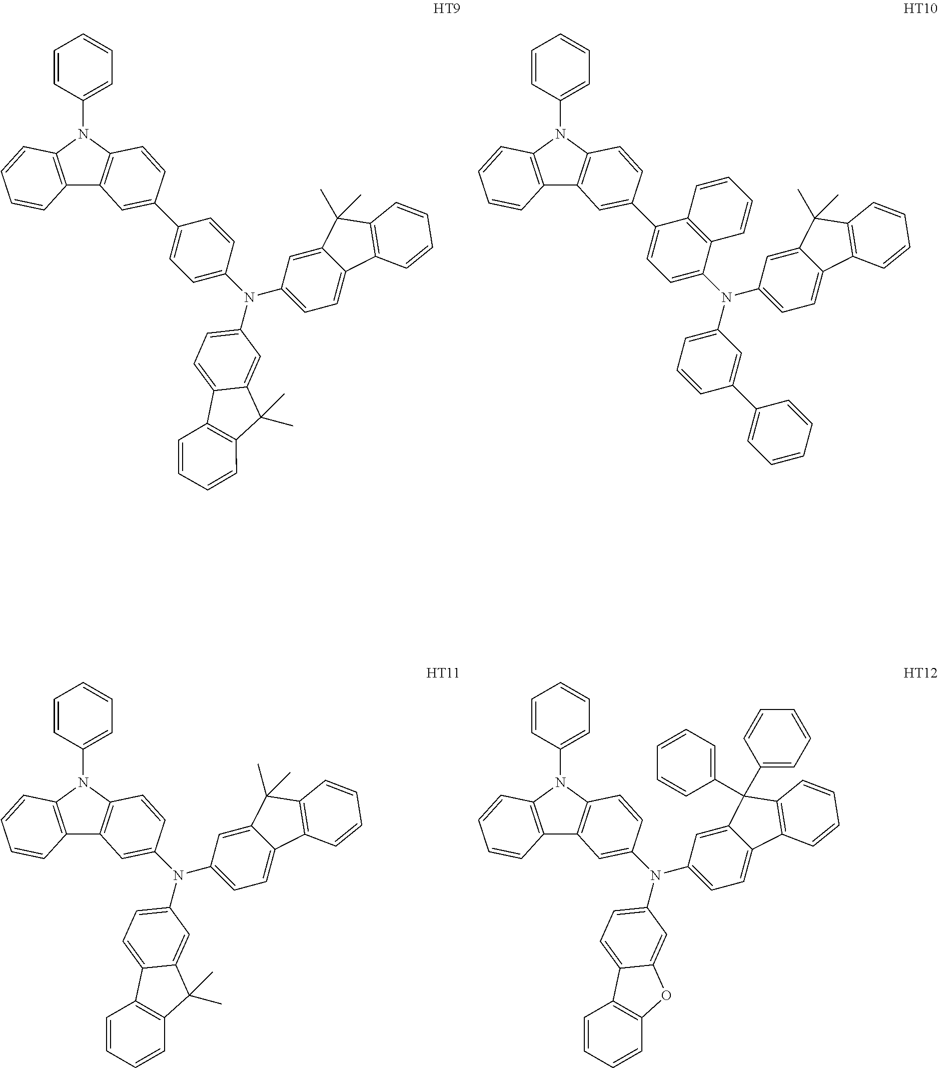 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

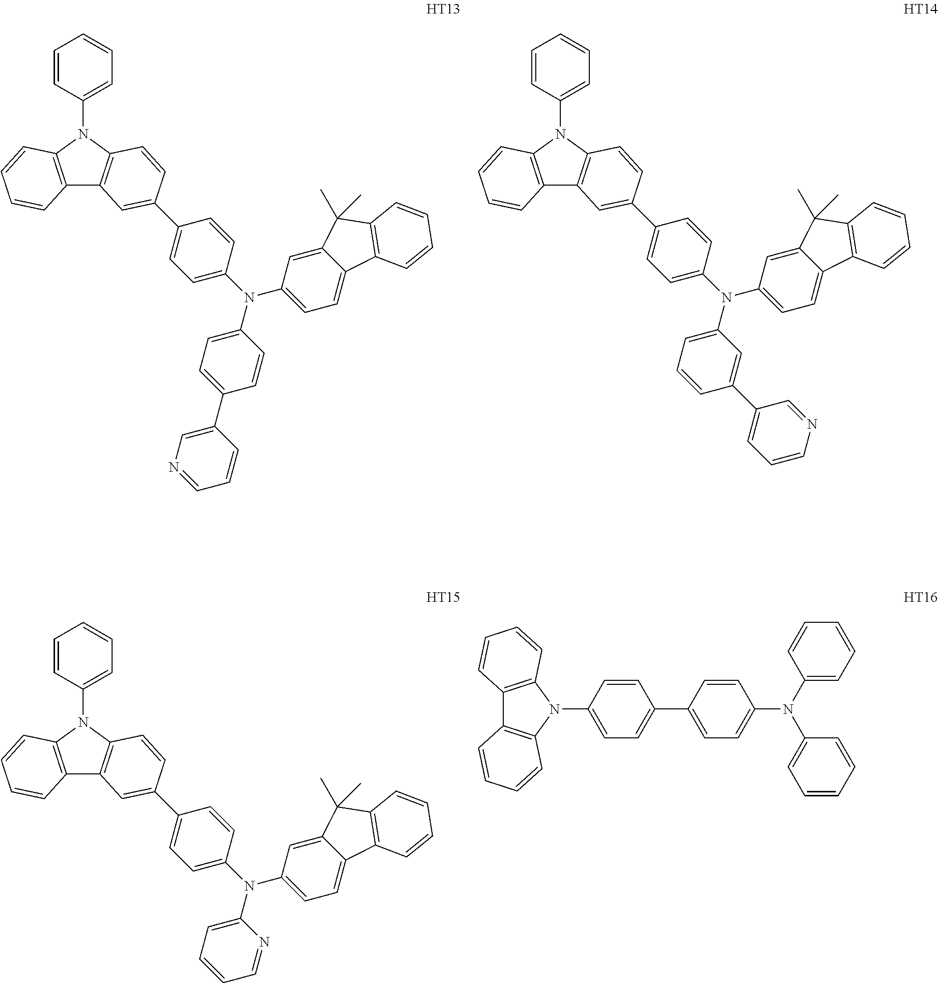 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

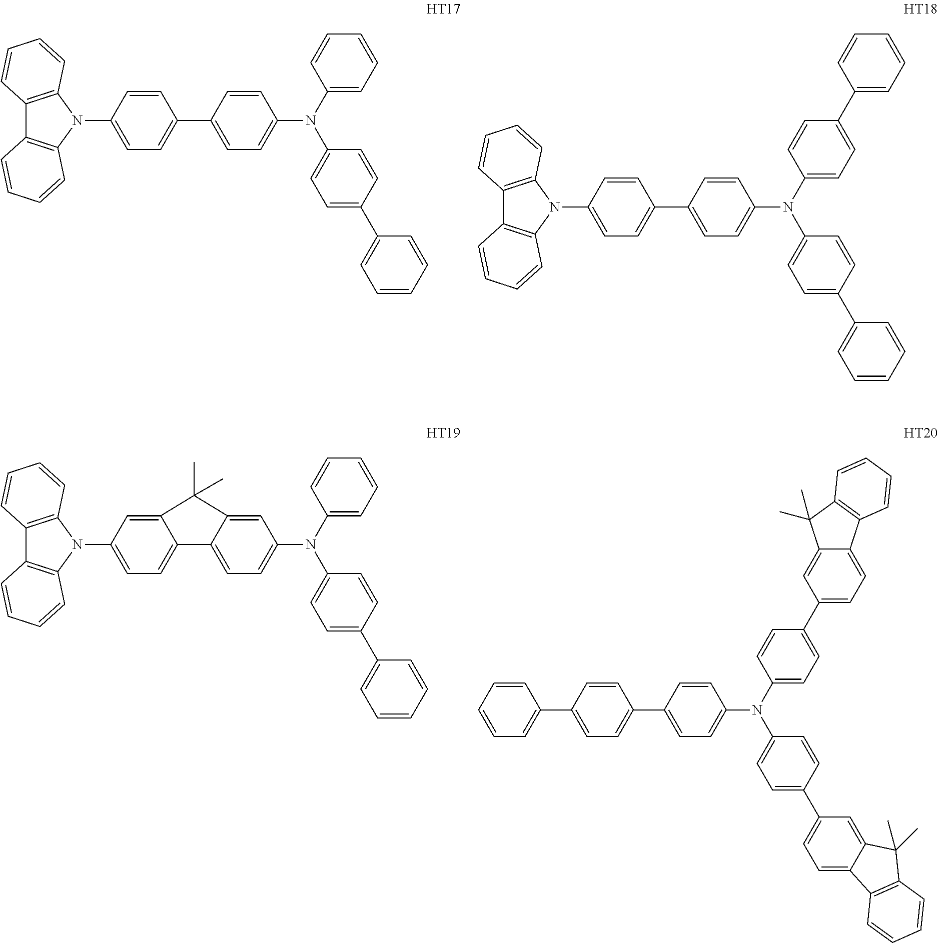 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

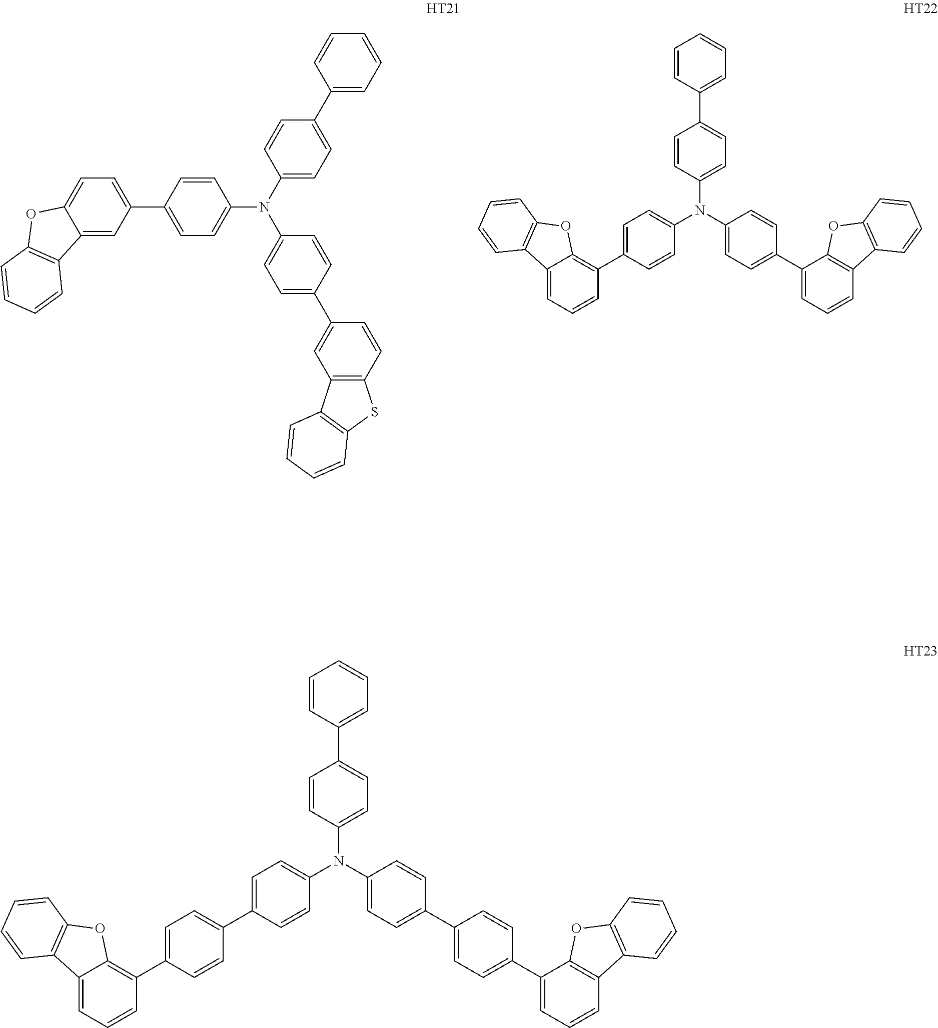 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

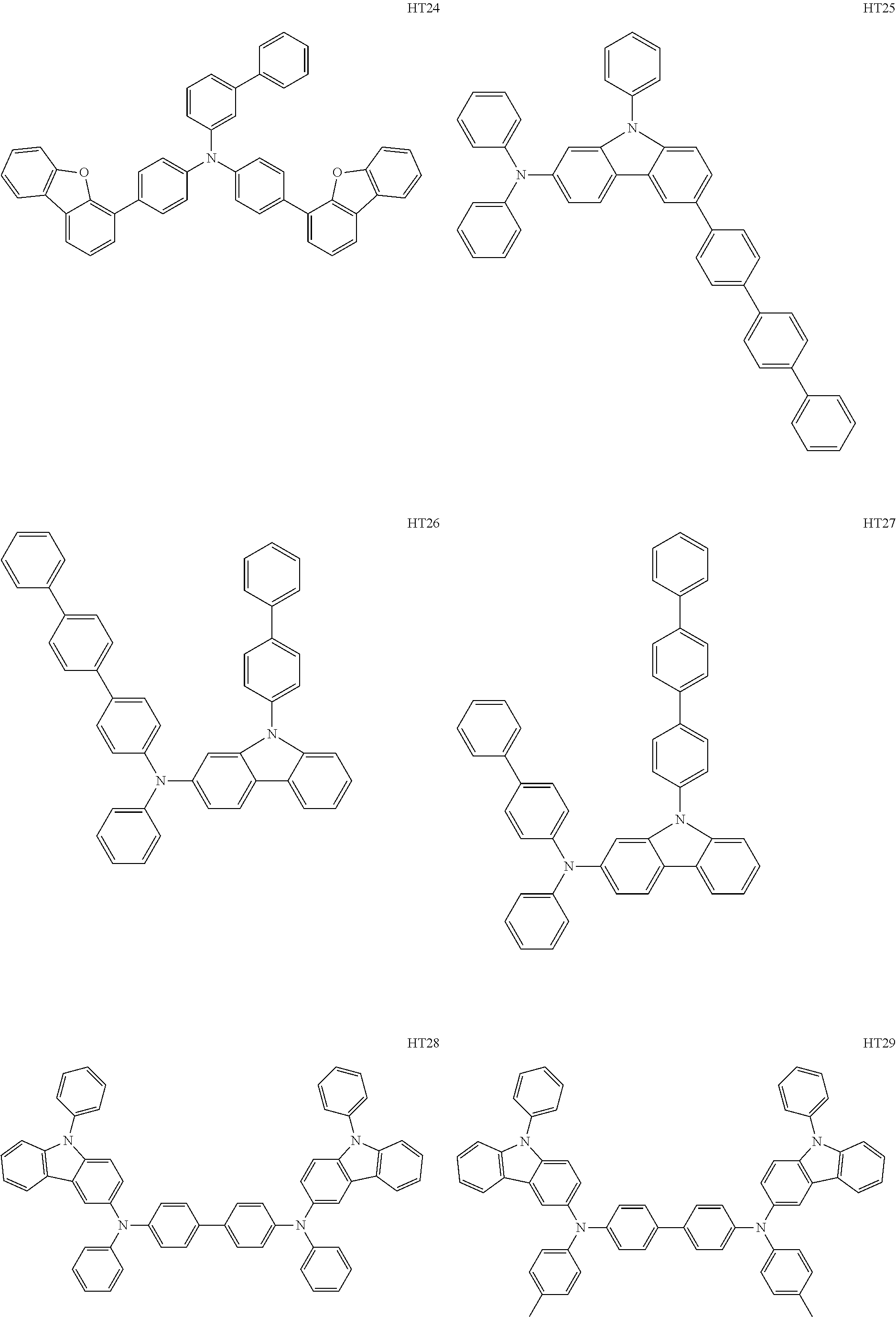

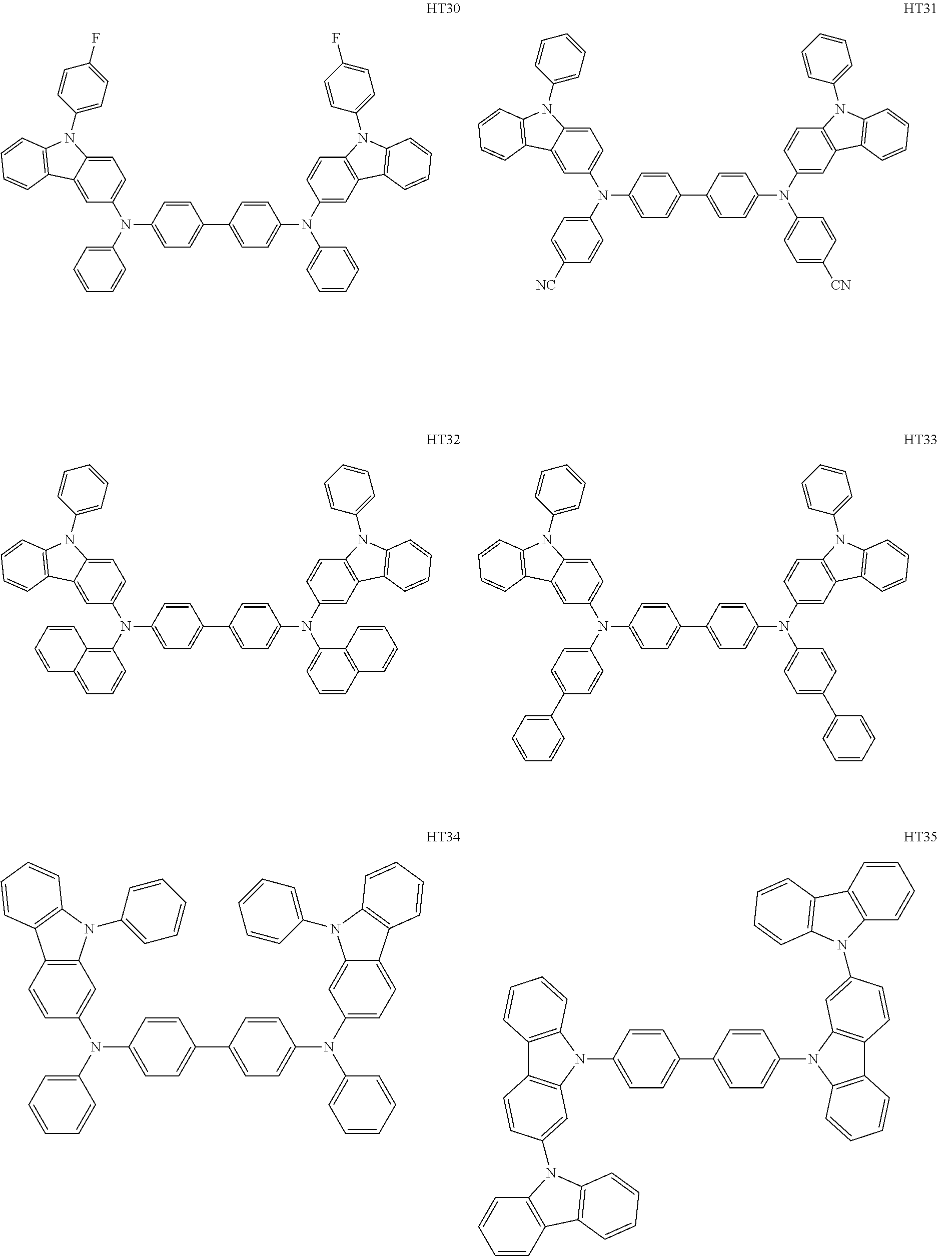

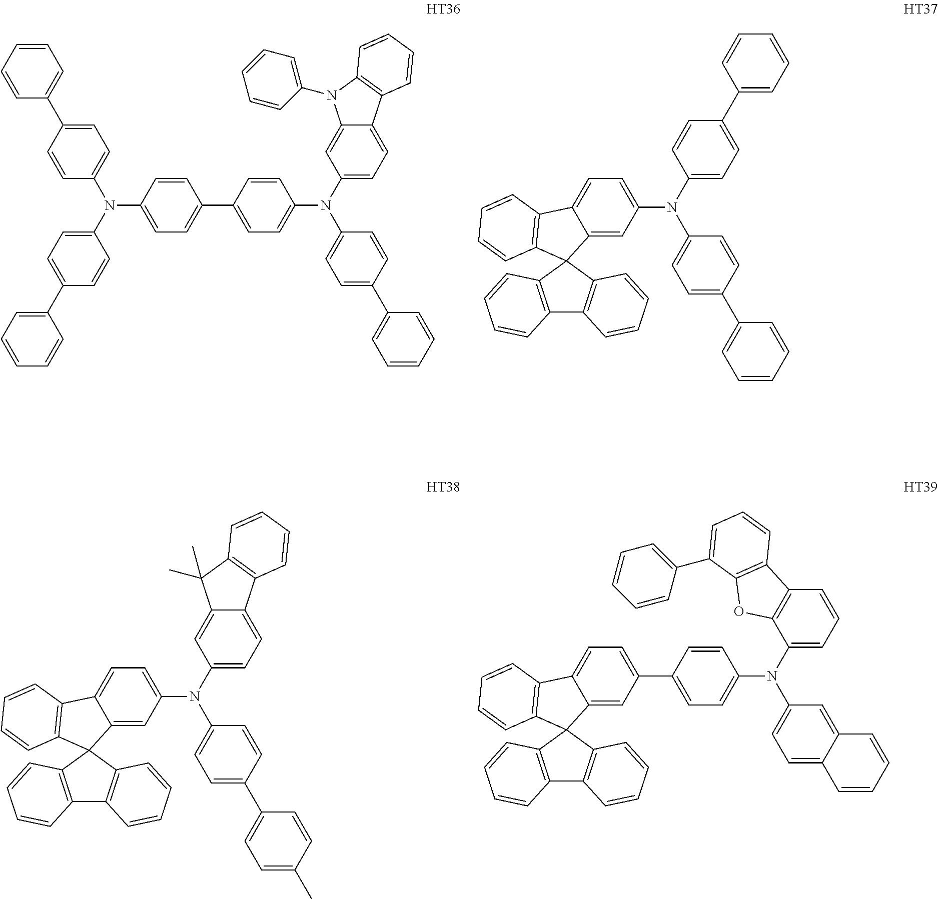 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

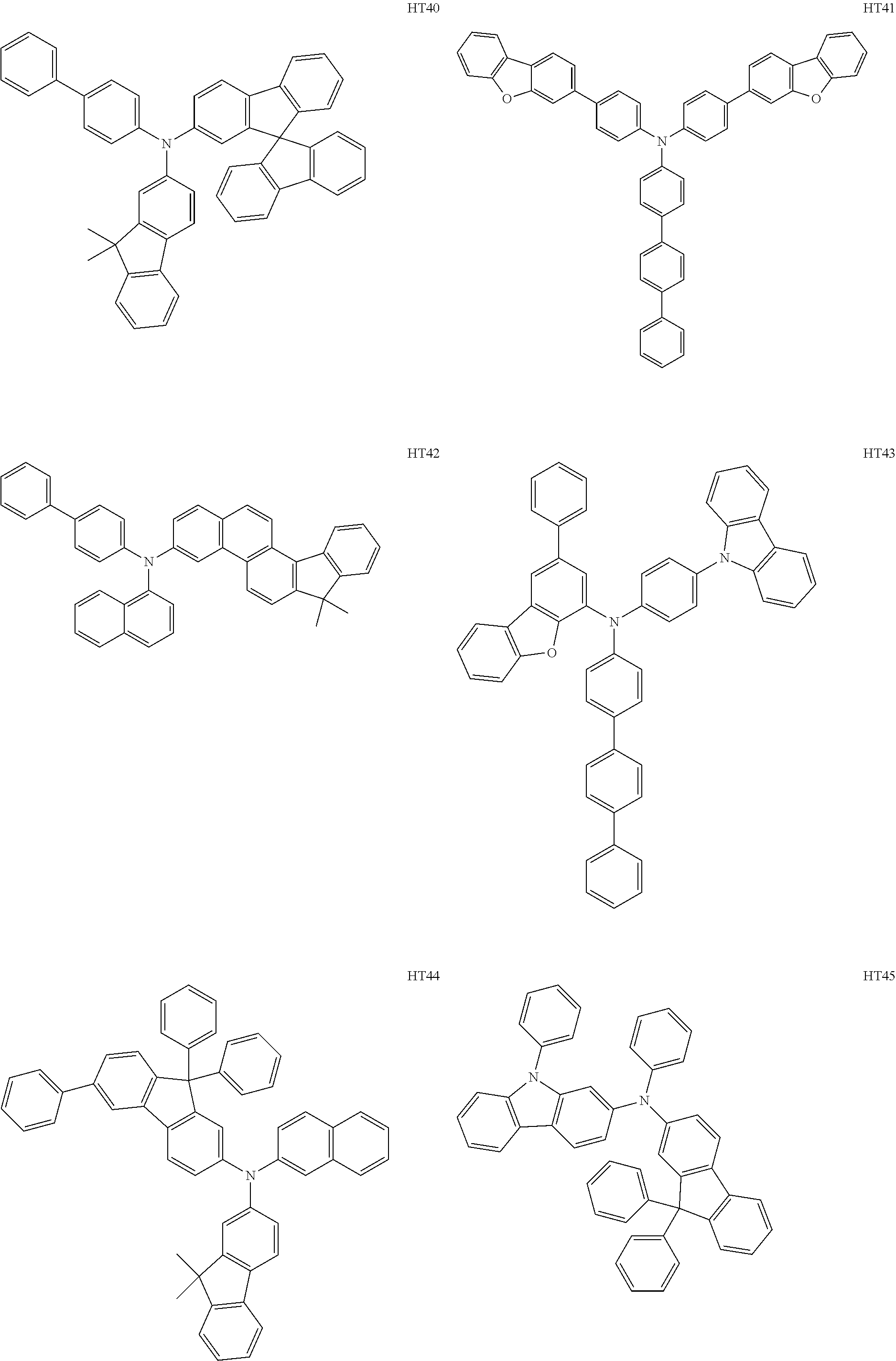

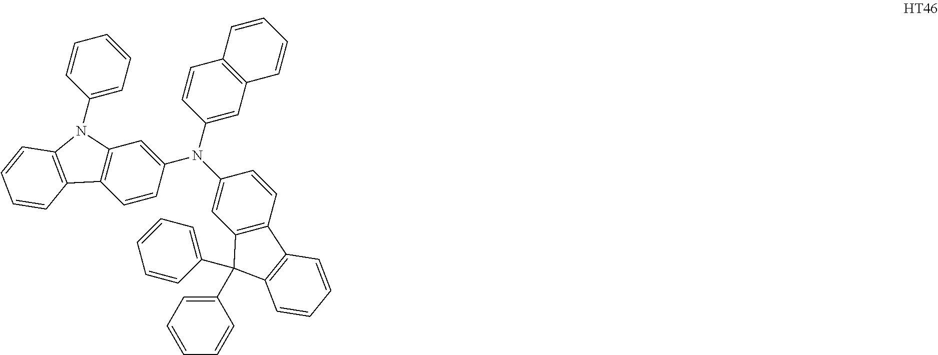 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

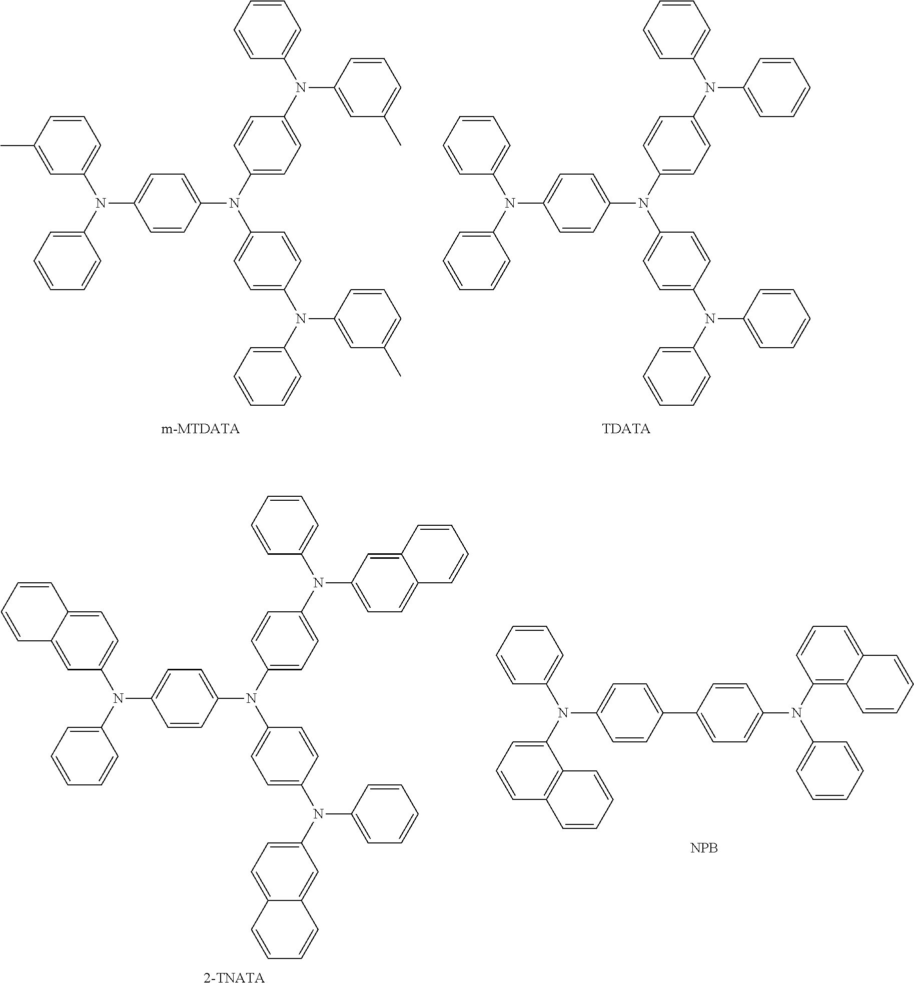

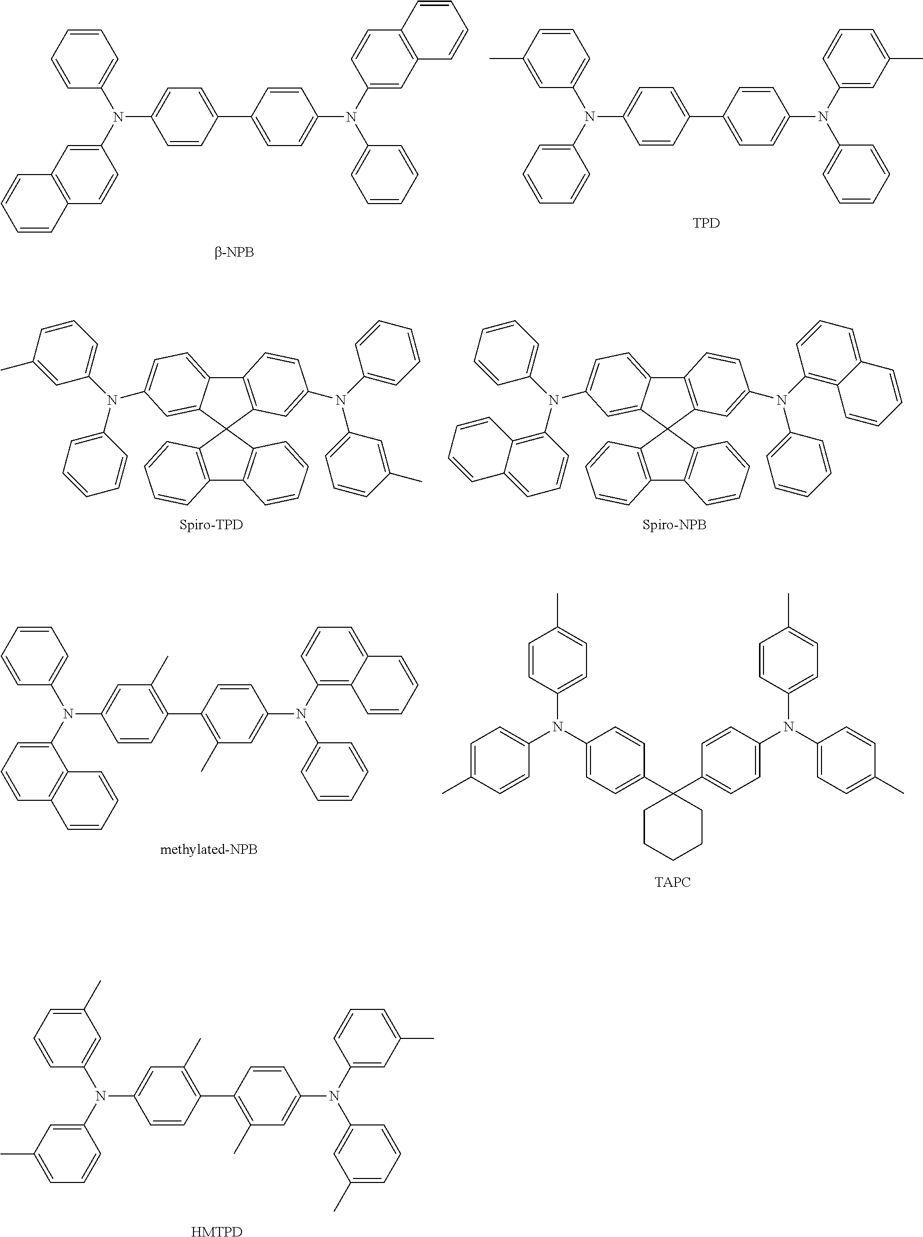

A thickness of the hole transport region may be about 50 Å to about 10000 Å, for example, about 100 Å to about 4000 Å. If (e.g., when) the hole transport region includes a hole injection layer, a hole transport layer, or any combination thereof, a thickness of the hole injection layer may be about 100 Å to about 9000 Å, for example, about 100 Å to about 1000 Å, and a thickness of the hole transport layer may be about 50 Å to about 2000 Å, for example, about 100 Å to about 1500 Å. If (e.g., when) the thicknesses of the hole transport region, the hole injection layer, and the hole transport layer are within the foregoing ranges, satisfactory or suitable hole transport characteristics may be obtained without a substantial increase in driving voltage.

The emission auxiliary layer may be a layer that increases or enhances light emission efficiency by compensating for optical resonance distance in accordance with the wavelength of light emitted from the emission layer. The electron blocking layer may be a layer that serves to prevent leakage of electrons from the emission layer to the hole transport region (or to reduce a degree or occurrence of leakage of electrons from the emission layer to the hole transport region). A material that may be contained in the hole transport region as described in one or more embodiments may be included in the emission auxiliary layer and the electron blocking layer.

### P-Dopant

The hole transport region may further include a charge generating material, in addition to the materials as described in one or more embodiments, to improve or enhance conductivity (e.g., electrical conductivity). The charge generating material may be uniformly (e.g., substantially uniformly) or non-uniformly dispersed in the hole transport region (e.g., in the form of a single layer consisting of (e.g., including) the charge generating material).

The charge generating material may be, for example, a p-dopant.

For example, a lowest unoccupied molecular orbitals (LUMO) energy level of the p-dopant may be about −3.5 eV or less.

According to one or more embodiments, the p-dopant may include a quinone derivative, a cyano group-containing compound, a compound containing element EL1 and element EL2, or any combination thereof.

Examples of the quinone derivative may include TCNQ, F4-TCNQ, and/or the like.

Examples of the cyano group-containing compound may include HAT-CN and/or a compound represented by Formula 221.

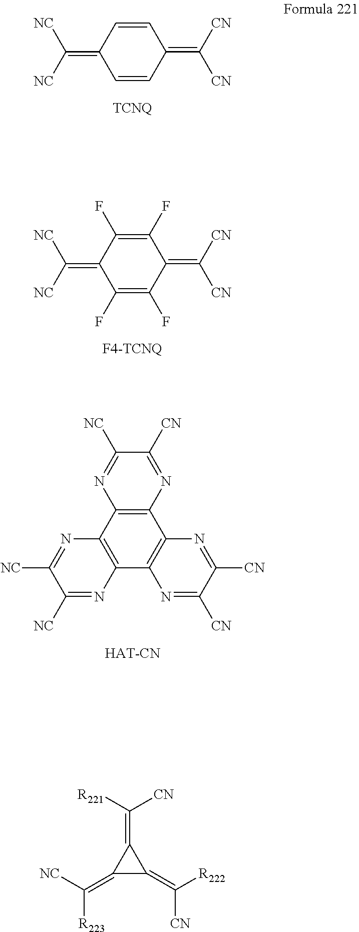

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one selected from among R₂₂₁ to R₂₂₃ may each independently be a cyano group; —F; —Cl; —Br; —I; a C₁-C₂₀ alkyl group unsubstituted or substituted with a cyano group, —F, —Cl, —Br, —I, or any combination thereof; or a C₃-C₆₀ carbocyclic group or a C₁-C₆₀ heterocyclic group, each substituted with any combination thereof.

In the compound containing element EL1 and element EL2, the element EL1 may be a metal, a metalloid, or any combination thereof, and the element EL2 may be a non-metal, a metalloid, or any combination thereof.

Examples of the metal may include an alkali metal (e.g., lithium (Li), sodium (Na), potassium (K), rubidium (Rb), and/or cesium (Cs)); an alkaline earth metal (e.g., beryllium (Be), magnesium (Mg), calcium (Ca), strontium (Sr), and/or barium (Ba)); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), and/or gold (Au)); a post-transition metal (e.g., zinc (Zn), indium (In), and/or tin (Sn)); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and/or lutetium (Lu)).

Examples of the metalloid may include silicon (Si), antimony (Sb), and/or tellurium (Te).

Examples of the nonmetal may include oxygen (O) and/or hydrogen (e.g., F, Cl, Br, and I).

For example, the compound containing element EL1 and element EL2 may include a metal oxide, a metal halide (e.g., metal fluoride, metal chloride, metal bromide, and/or metal iodide), a metalloid halide (e.g., metalloid fluoride, metalloid chloride, metalloid bromide, and/or metalloid iodide), a metal telluride, or any combination thereof.

Examples of the metal oxide may include a tungsten oxide (e.g., WO, W₂O₃, WO₂, WO₃, and/or W₂O₅), a vanadium oxide (e.g., VO, V₂O₃, VO₂, and/or V₂O₅), a molybdenum oxide (e.g., MoO, Mo₂O₃, MoO₂, MoO₃, and/or Mo₂O₅), and/or a rhenium oxide (e.g., ReO₃).

Examples of the metal halide may include alkali metal halides, alkaline earth metal halides, transition metal halides, post-transition metal halides, and/or lanthanide metal halides.

Examples of the alkali metal halides may include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Examples of the alkaline earth metal halides may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, Sr₁₂, and/or BaI₂.

Examples of the transition metal halides may include titanium halides (e.g., TiF₄, TiCl₄, TiBr₄, and/or TiI₄), zirconium halides (e.g., ZrF₄, ZrCl₄, ZrBr₄, and/or ZrI₄), hafnium halides (e.g., HfF₄, HfCl₄, HfBr₄, and/or HfI₄), vanadium halides (e.g., VF₃, VCl₃, VBr₃, and/or VI₃), niobium halides (e.g., NbF₃, NbCl₃, NbBr₃, and/or NbI₃), tantalum halides (e.g., TaF₃, TaCl₃, TaBr₃, and/or TaI₃), chromium halides (e.g., CrF₃, CrCl₃, CrBr₃, and/or CrI₃), molybdenum halides (e.g., MoF₃, MoCl₃, MoBr₃, and/or MoI₃), tungsten halides (e.g., WF₃, WCl₃, WBr₃, and/or WI₃), manganese halides (e.g., MnF₂, MnCl₂, MnBr₂, and/or MnI₂), technetium halides (e.g., TcF₂, TcCl₂, TcBr₂, and/or TcI₂), rhenium halides (e.g., ReF₂, ReCl₂, ReBr₂, and/or ReI₂), iron halides (e.g., FeF₂, FeCl₂, FeBr₂, and/or FeI₂), ruthenium halides (e.g., RuF₂, RuCl₂, RuBr₂, and/or RuI₂), osmium halides (e.g., OsF₂, OsCl₂, OsBr₂, and/or OsI₂), cobalt halides (e.g., CoF₂, CoCl₂, CoBr₂, and/or CoI₂), rhodium halides (e.g., RhF₂, RhCl₂, RhBr₂, and/or RhI₂), iridium halides (e.g., IrF₂, IrCl₂, IrBr₂, and/or Ir₂), nickel halides (e.g., NiF₂, NiCl₂, NiBr₂, and/or NiI₂), palladium halides (e.g., PdF₂, PdCl₂, PdBr₂, and/or PdI₂), platinum halides (e.g., PtF₂, PtCl₂, PtBr₂, and/or PtI₂), copper halides (e.g., CuF, CuCl, CuBr, and/or CuI), silver halides (e.g., AgF, AgCl, AgBr, and/or AgI), and/or gold halides (e.g., AuF, AuCl, AuBr, and/or AuI).

Examples of the post-transition metal halides may include zinc halides (e.g., ZnF₂, ZnCl₂, ZnBr₂, and/or ZnI₂), indium halides (e.g., InI₃), and/or tin halides (e.g., SnI₂).

Examples of the lanthanide metal halides may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and/or SmI₃.

Examples of the metalloid halides may include antimony halides (e.g., SbCl₅).

Examples of the metal tellurides may include alkali metal tellurides (e.g., Li₂Te, Na₂Te, K₂Te, Rb₂Te, and/or Cs₂Te), alkaline earth metal tellurides (e.g., BeTe, MgTe, CaTe, SrTe, and/or BaTe), transition metal tellurides (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), post-transition metal tellurides (e.g., ZnTe), and/or lanthanide metal tellurides (e.g., LaTe, CeTe, PrTe, NdTe, PmTe, EuTe, GdTe, TbTe, DyTe, HoTe, ErTe, TmTe, YbTe, and/or LuTe).

### Emission Layer

The emission layer may be disposed or provided on the hole transport region. If (e.g., when) the light-emitting element is a full-color light-emitting element, the emission layer may be patterned into a red emission layer, a green emission layer, and/or a blue emission layer for each individual sub-pixel. In one or more embodiments, the emission layer may have a structure where two or more layers selected from among a red emission layer, a green emission layer, and a blue emission layer are stacked in contact or spaced and/or apart (e.g., spaced apart or separated) or a structure where two or more materials selected from among a red light-emitting material, a green light-emitting material, and a blue light-emitting material are mixed without layer separation, thereby emitting white light.

The emission layer may include a host and a dopant. The dopant may include a phosphorescent dopant, a fluorescent dopant, or any combination thereof.

The content (e.g., amount) of the dopant in the emission layer may be about 0.01 parts by weight to about 15 parts by weight based on 100 parts by weight of the host.

According to one or more embodiments, the emission layer may include the quantum dot as described in one or more embodiments. For example, the emission layer may be a layer formed or provided by utilizing the quantum dot composition as described in one or more embodiments. In this case, the emission layer may be formed or provided by an inkjet process.

In one or more embodiments, the emission layer may include a delayed fluorescent material. The delayed fluorescent material may serve as a host or a dopant in the emission layer.

The emission layer may have a thickness of about 100 Å to about 1000 Å, for example, about 200 Å to about 600 Å. By satisfying the foregoing ranges of the thickness of the emission layer, excellent or suitable light-emitting characteristics may be obtained without a substantial increase in driving voltage.

### Host

The host may include a compound represented by Formula 301.

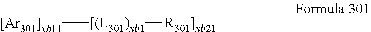

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 maybe 1, 2, or 3,
xb1 may be an integer of 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer of 1 to 5, and
for descriptions of Q₃₀₁ to Q₃₀₃, refer to the description of Q₁ in one or more embodiments.

For example, if (e.g., when) xb11 is 2 or more in Formula 301, two or more Ar₃₀₁s may be connected to each other by a single bond (e.g., a single covalent bond).

As another example, the host may include a compound represented by Formula 301-1, a compound represented by Formula 301-2, or any combination thereof.

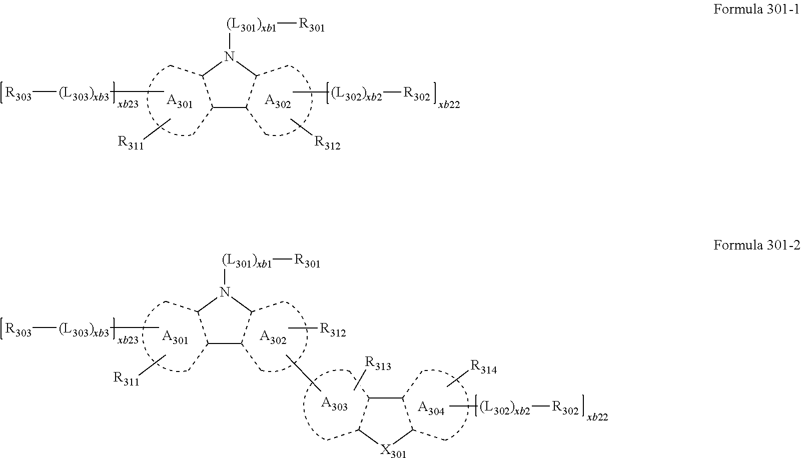

In Formulae 301-1 and 301-2,
Rings A₃₀₁ to A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
for descriptions of L₃₀₁, xb1, and R₃₀₁, refer to the descriptions in one or more embodiments, respectively,
for descriptions of L₃₀₂ to L₃₀₄, refer to the description of R₃₀₁ in one or more embodiments, respectively,
for descriptions of xb2 to xb4, refer to the description of xb1 in one or more embodiments, respectively, and
for descriptions of R₃₀₂ to R₃₀₅ and R₃₁₁ to R₃₁₄, refer to the description of R³⁰¹ in one or more embodiments.

As another example, the host may include an alkaline earth metal complex, a post-transition metal complex, or any combination thereof. For example, the host may include a Be complex (e.g., Compound H55), a Mg complex, a Zn complex, or any combination thereof.

As another example, the host may include one of Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di(carbazol-9-yl)benzene (mCP), 1,3,5-tri(carbazol-9-yl)benzene (TCP), or any combination thereof.

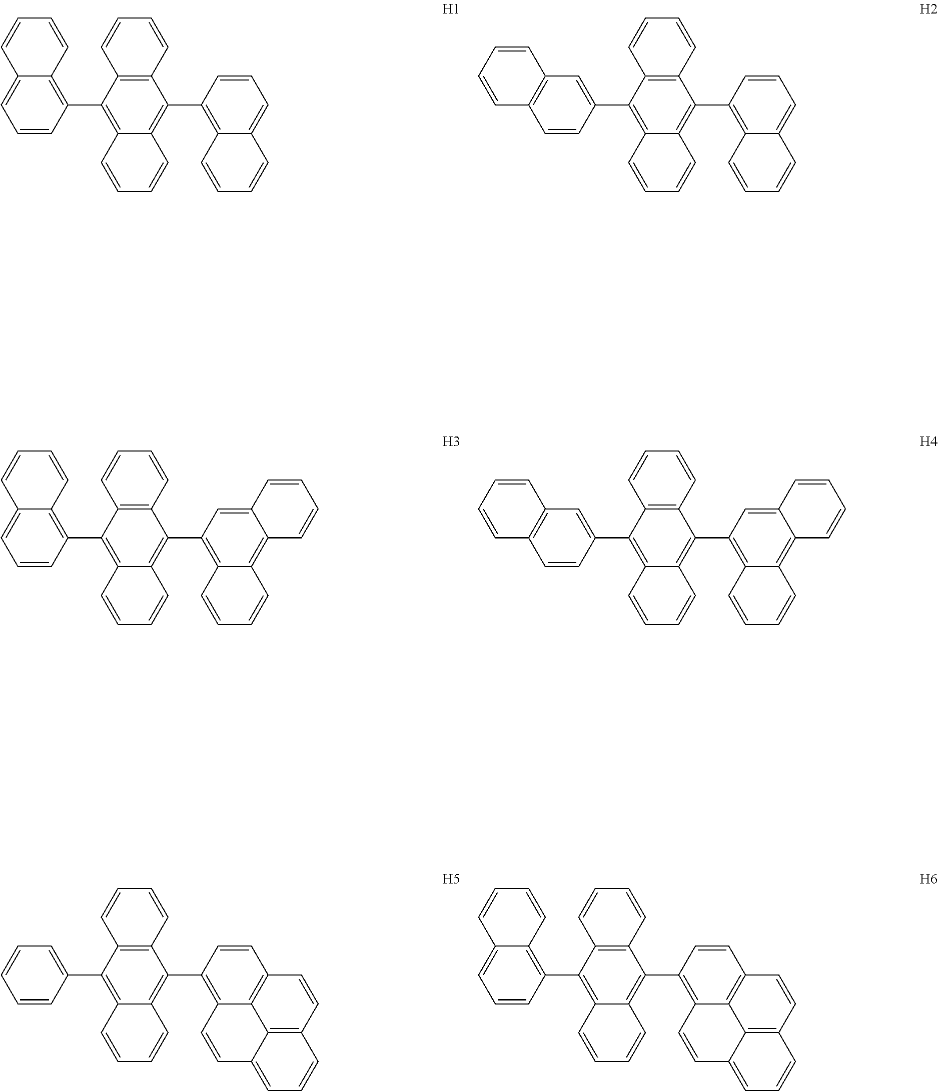

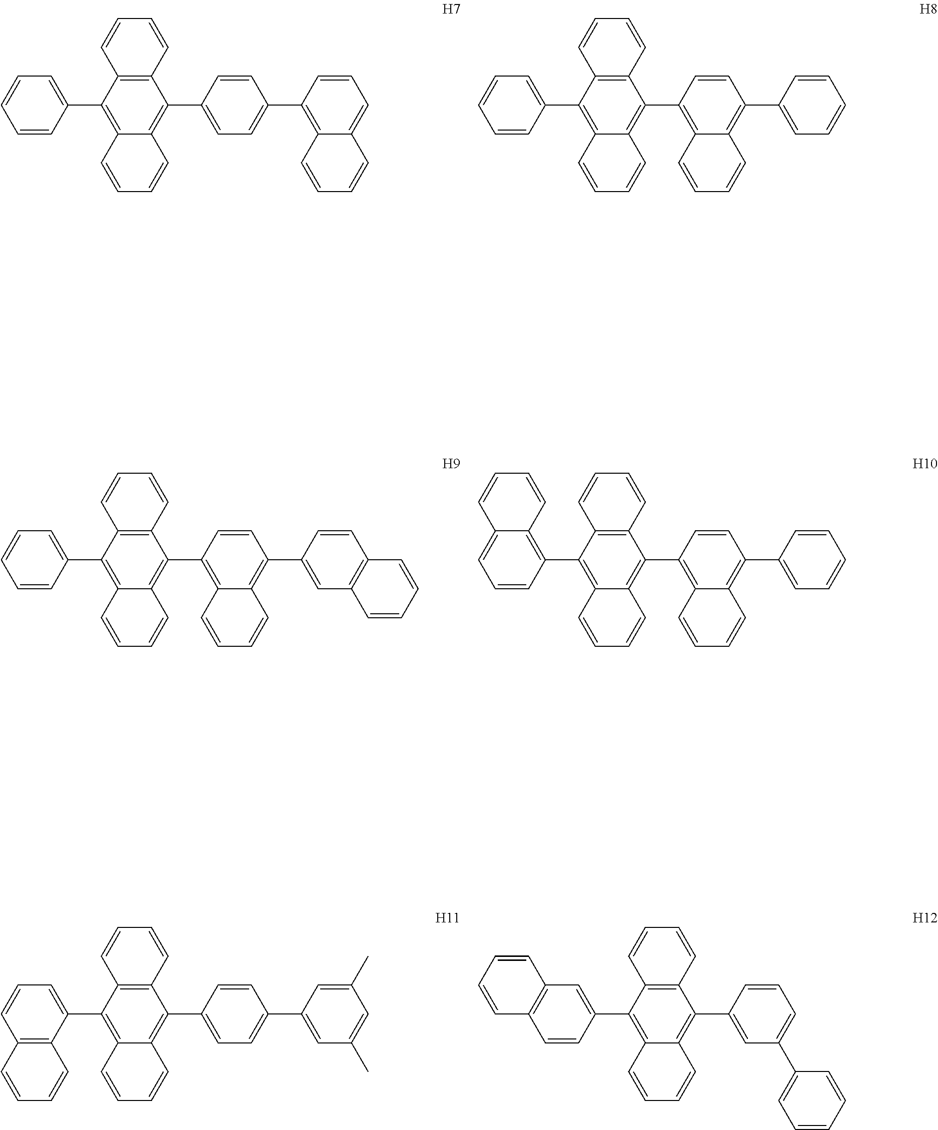

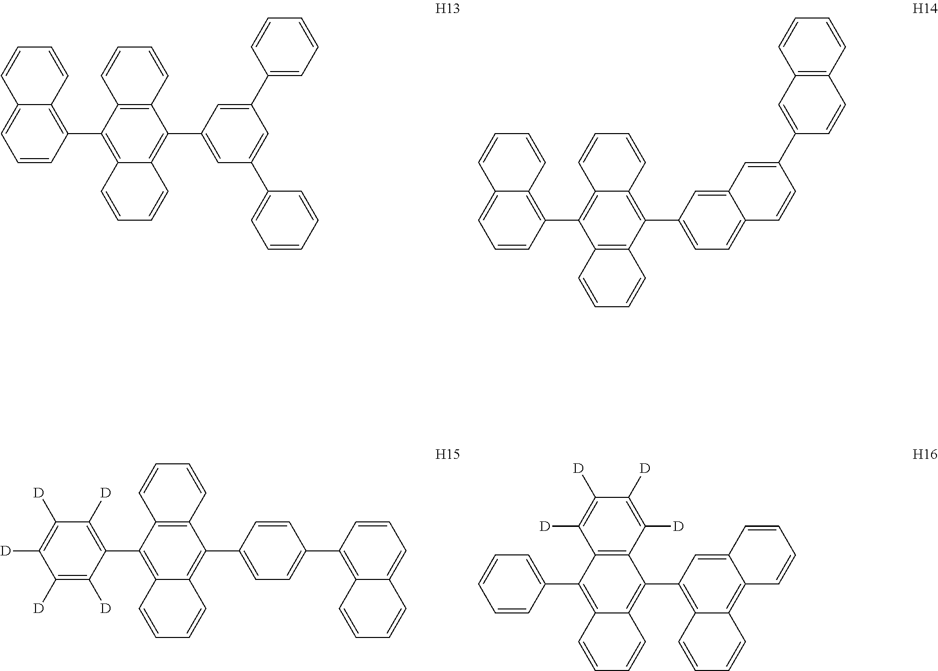

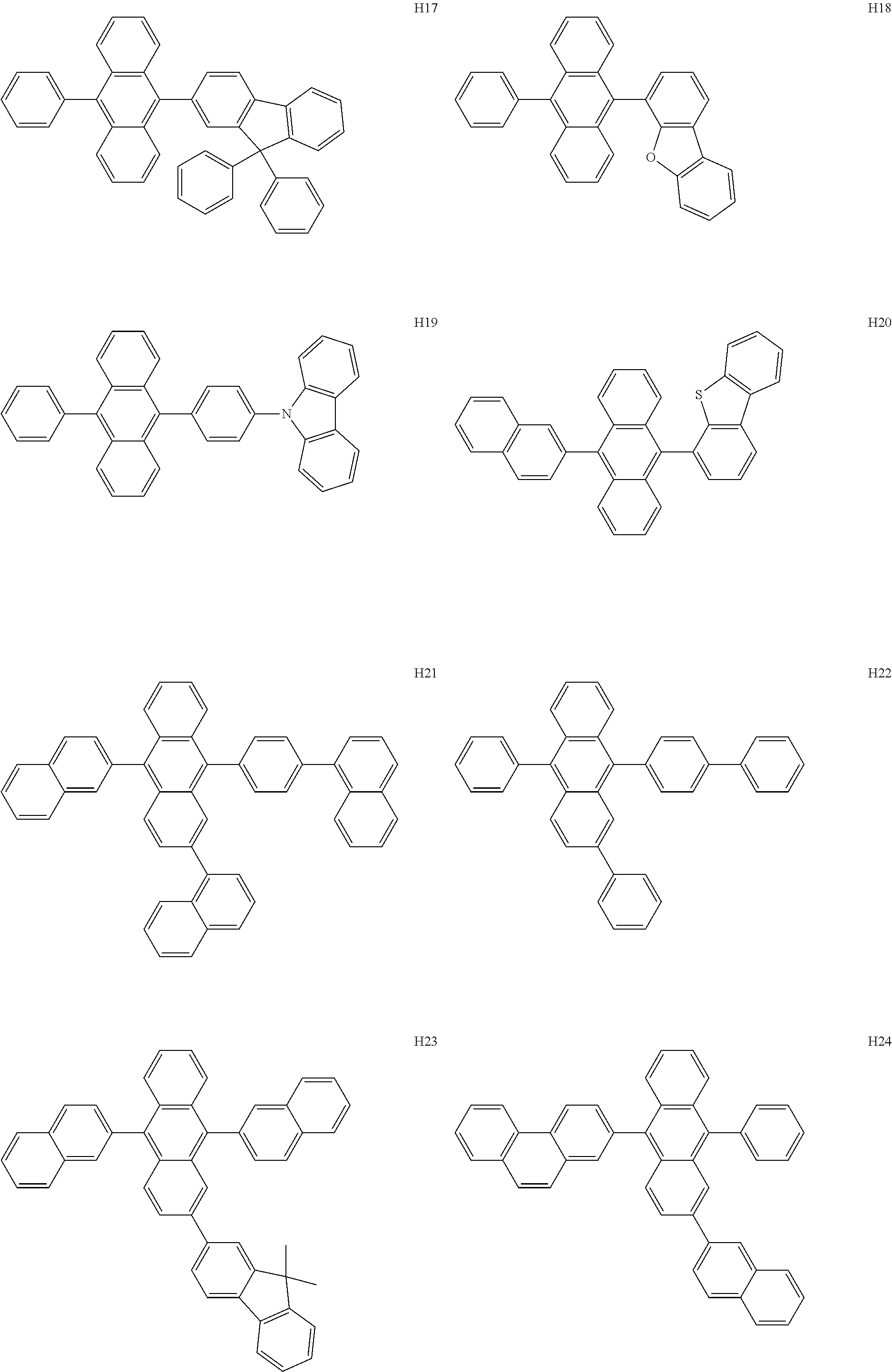

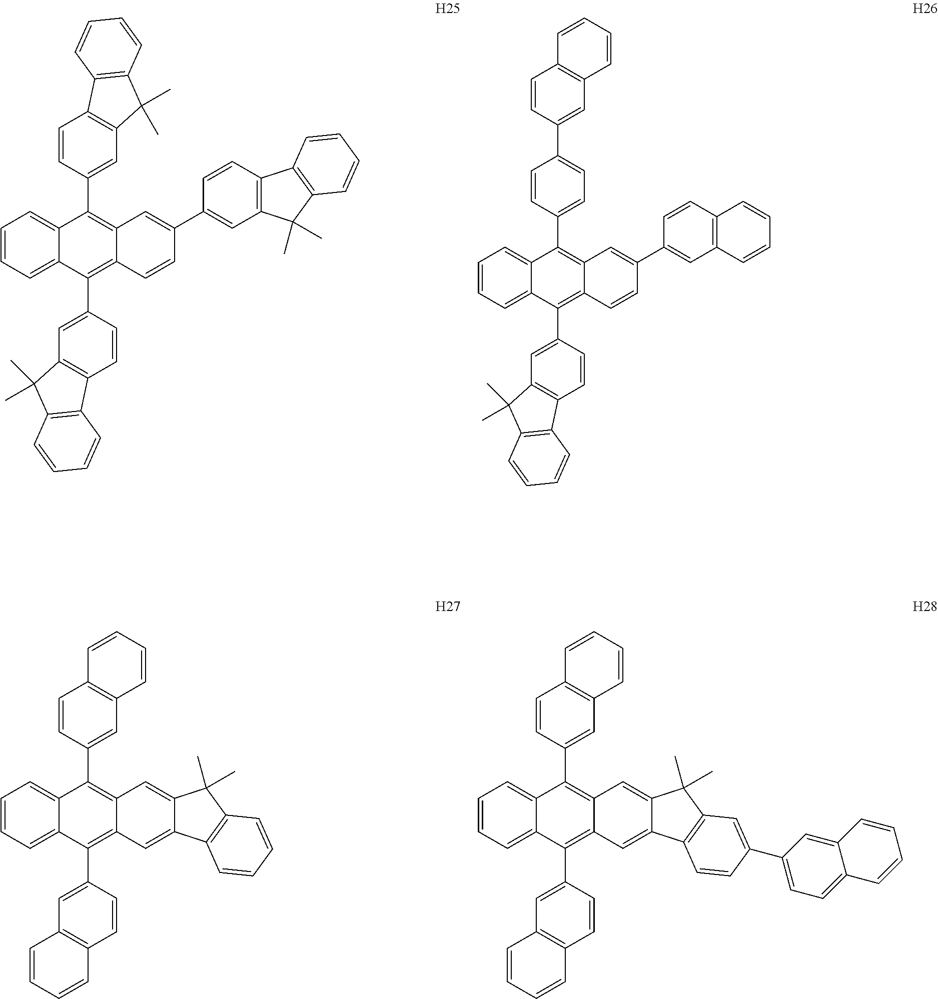

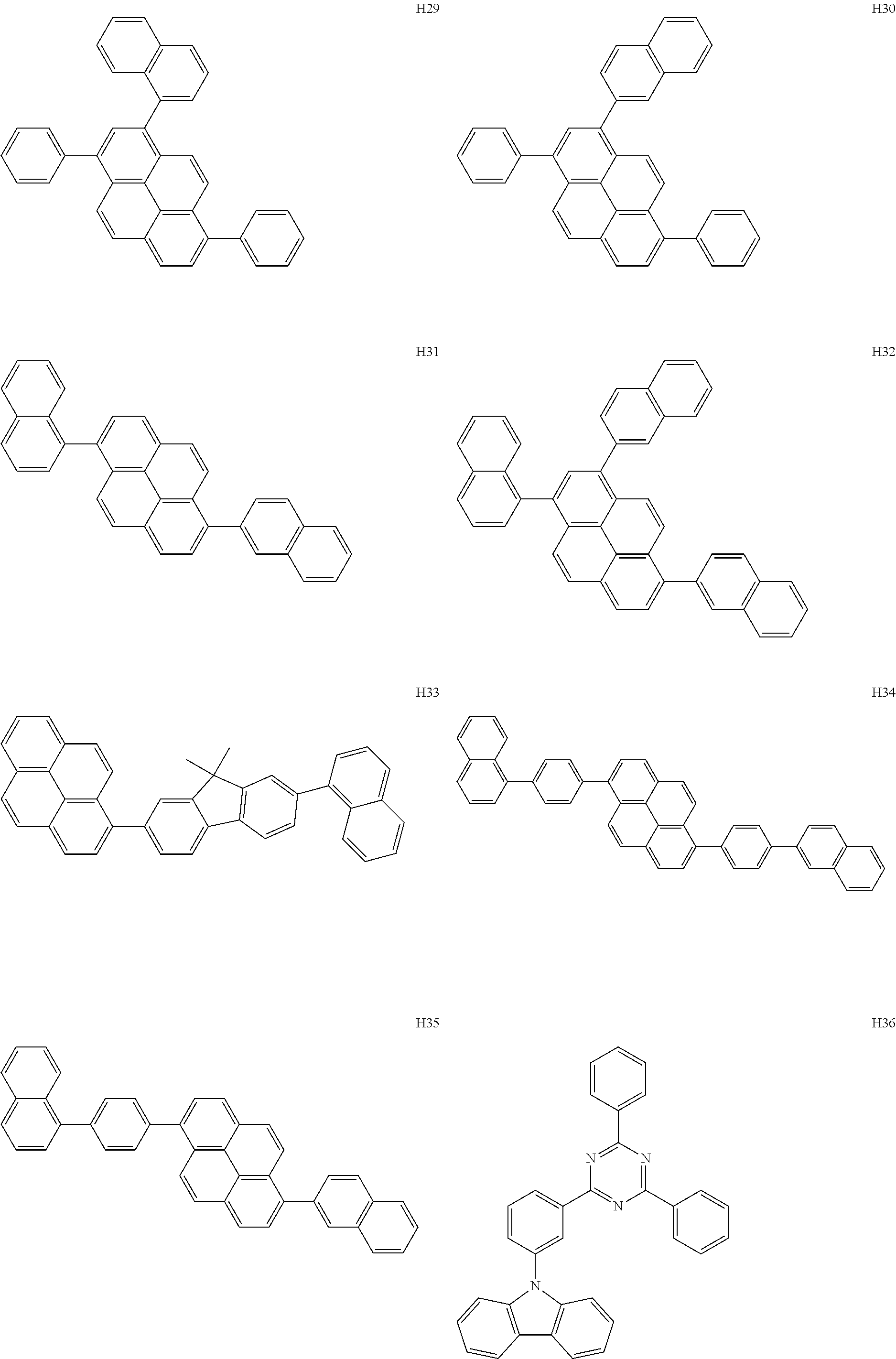

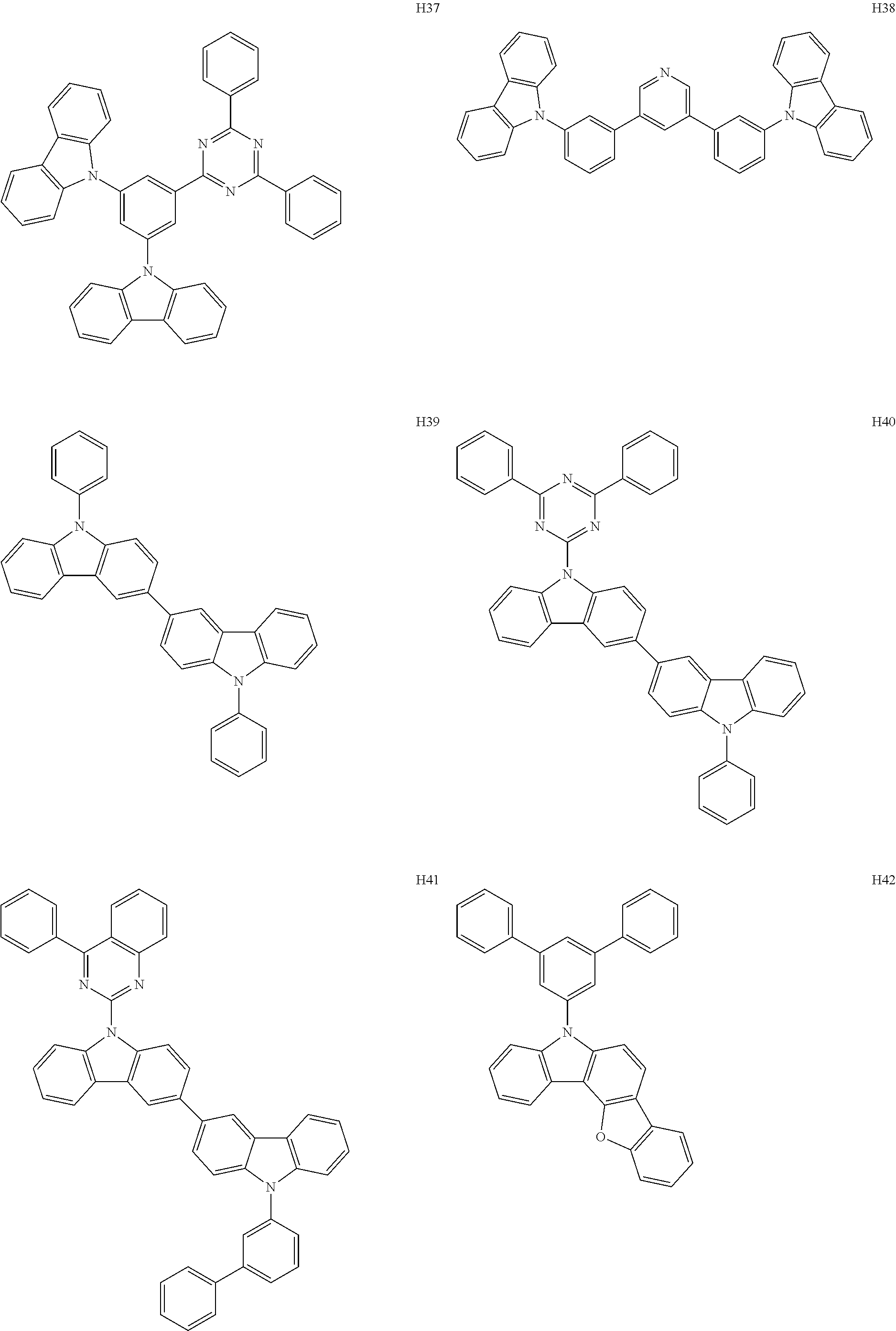 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

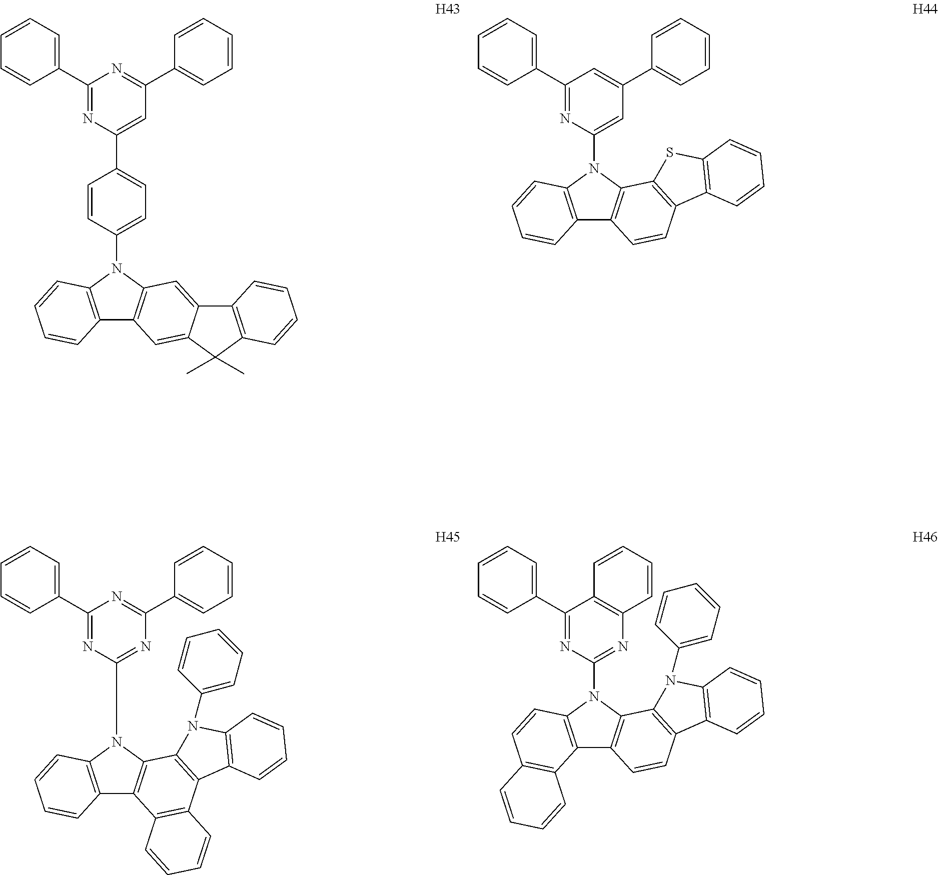 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

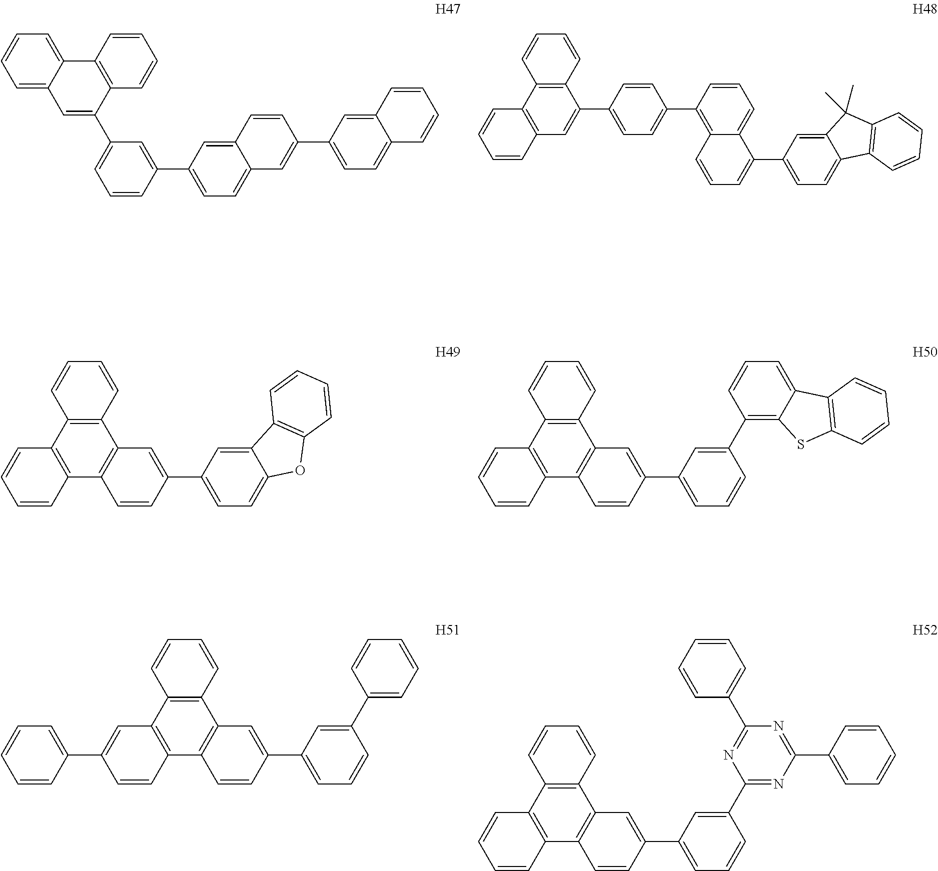

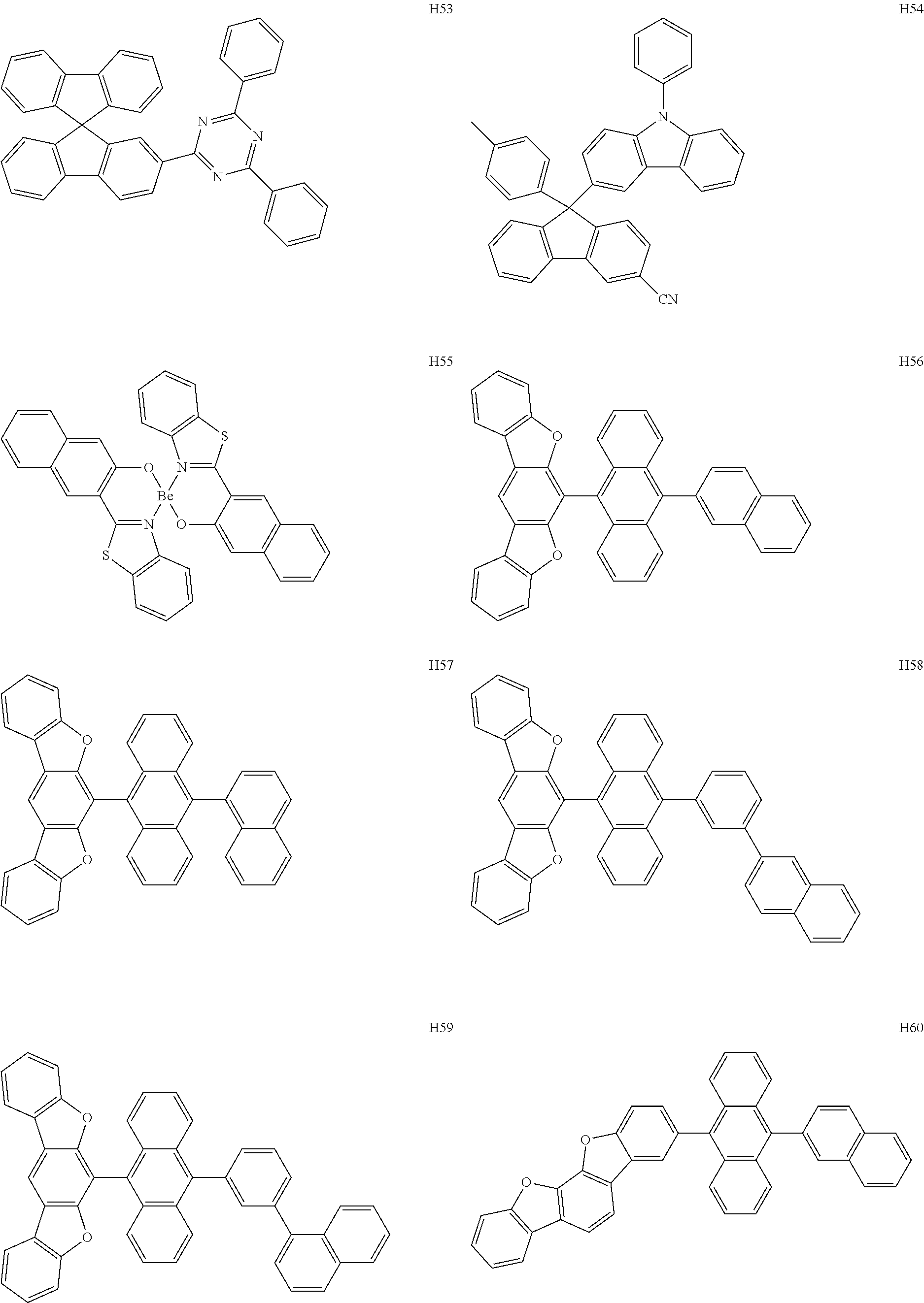

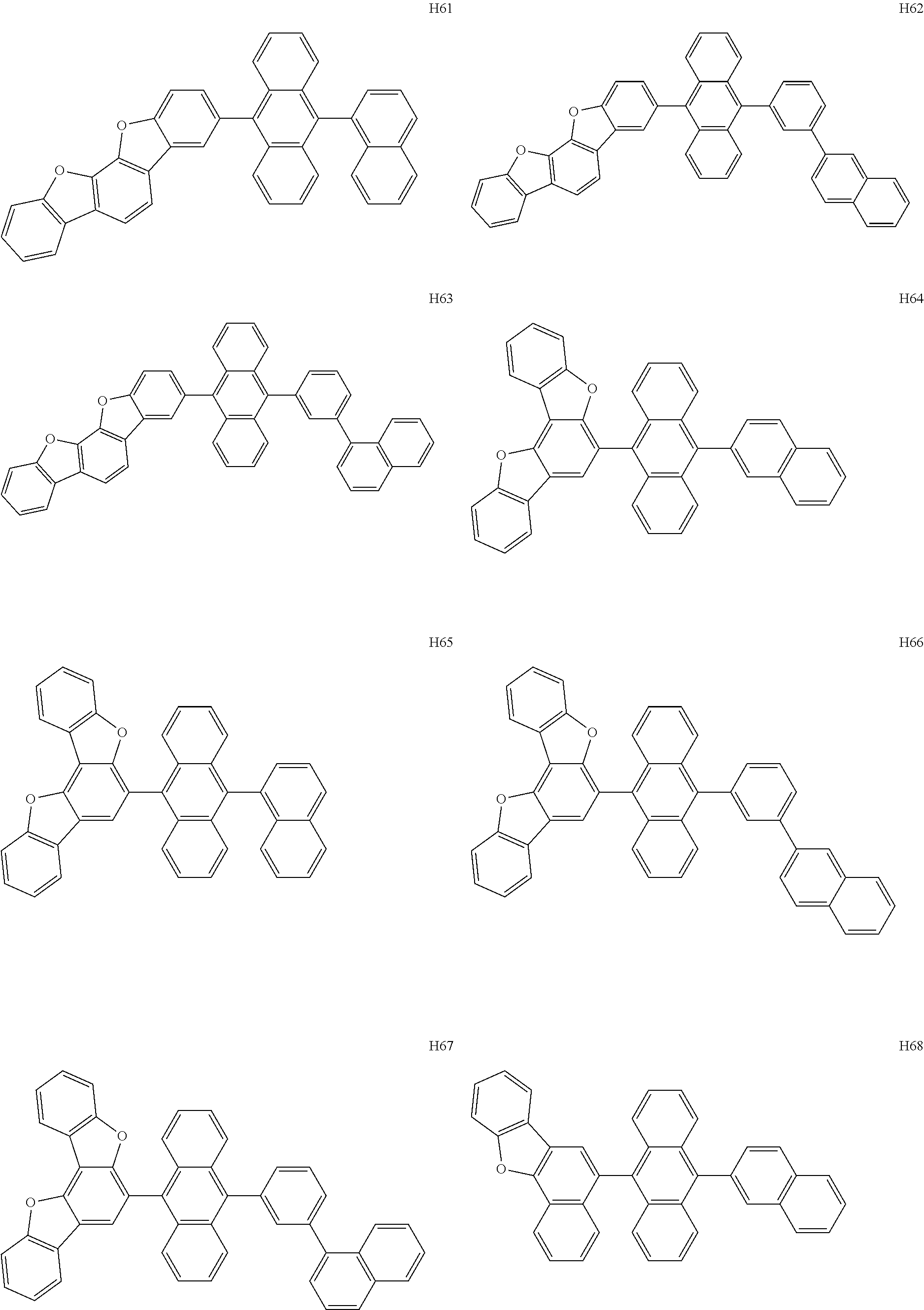

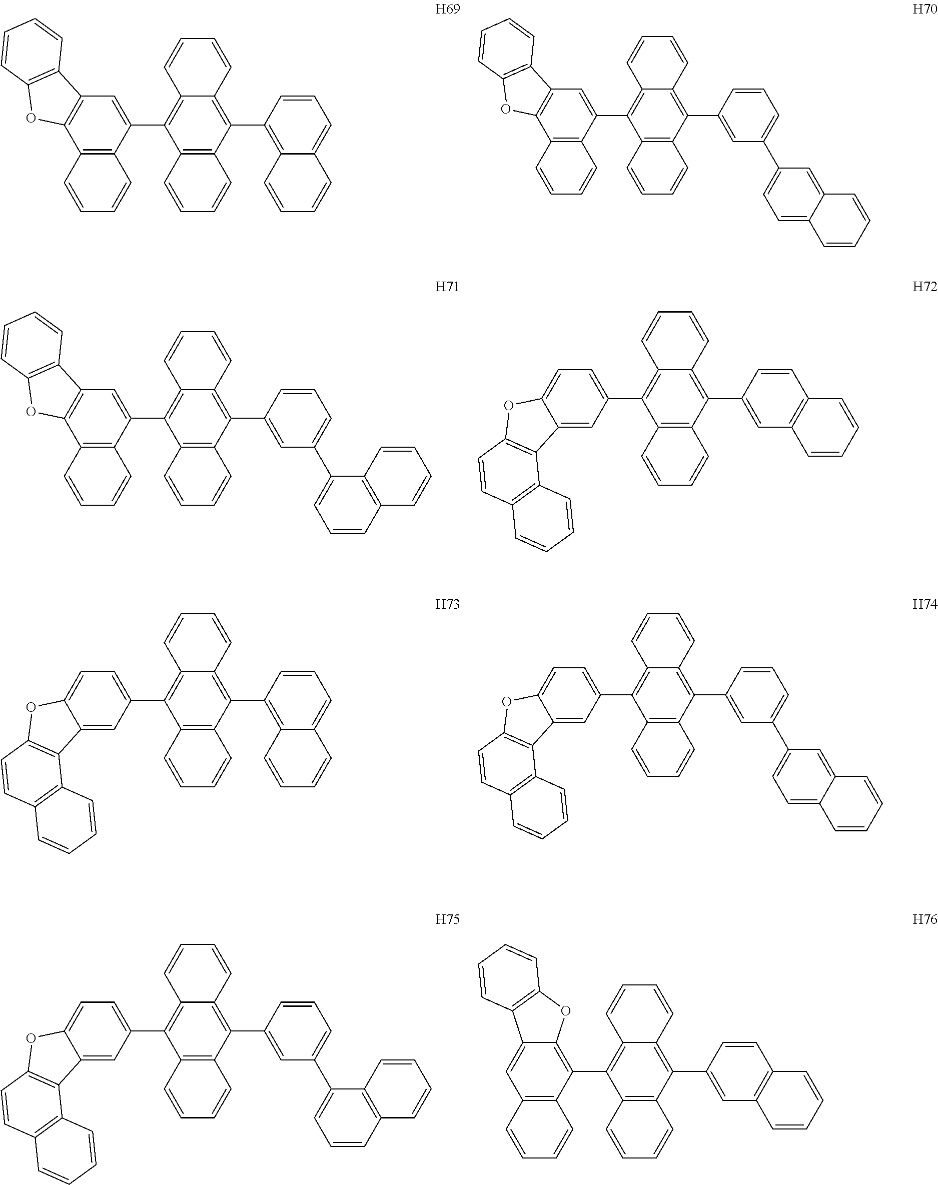

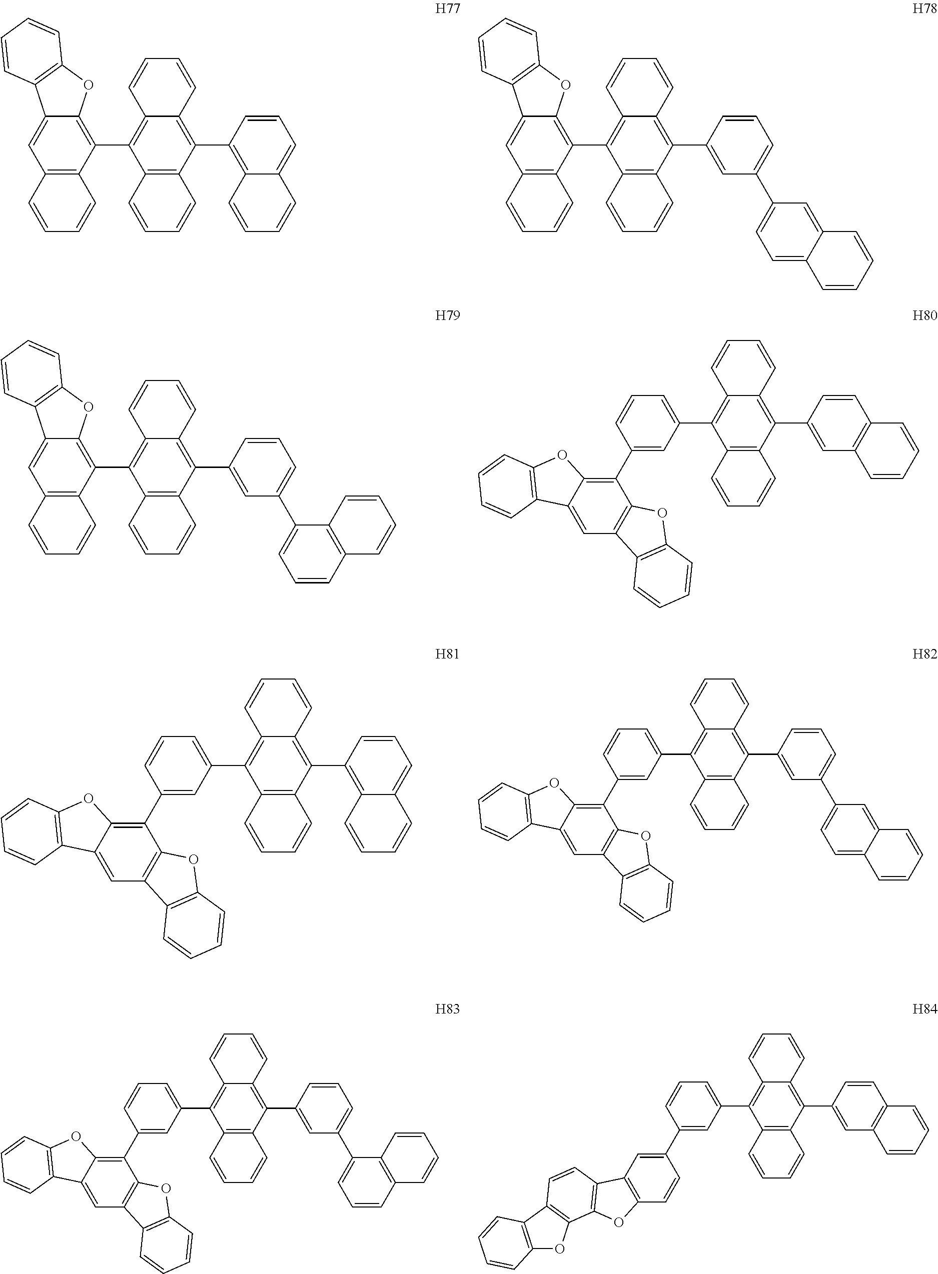

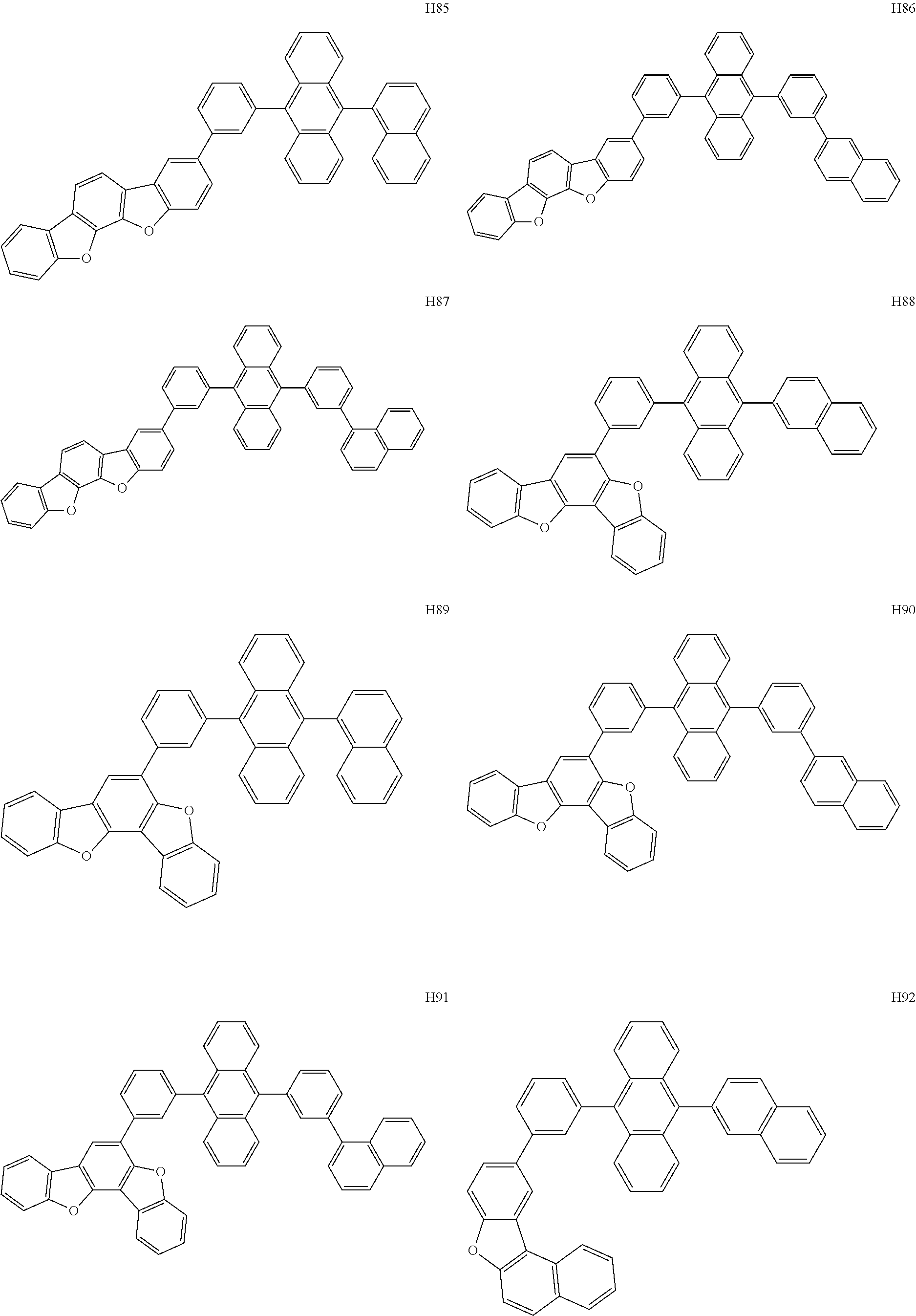

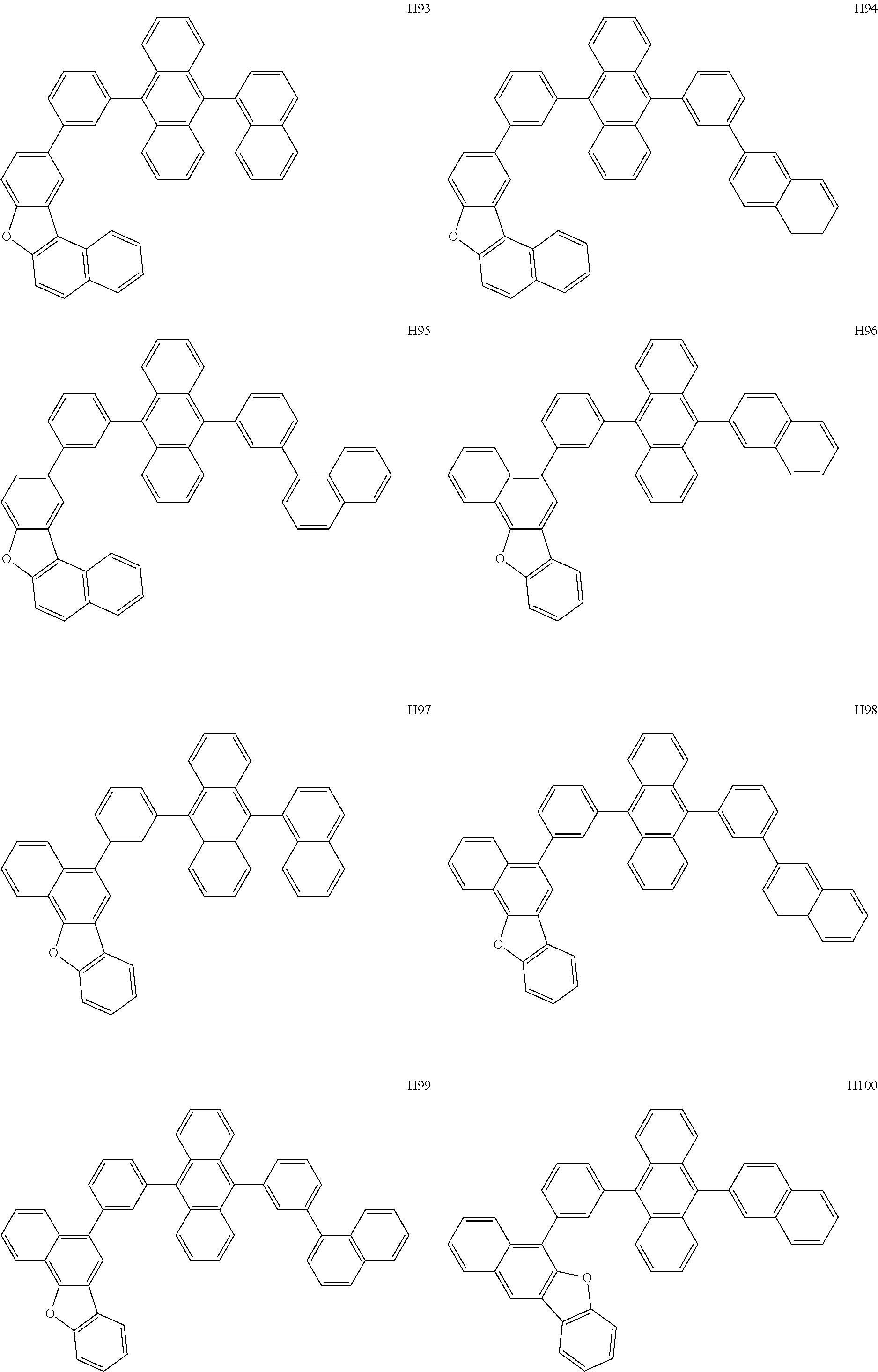

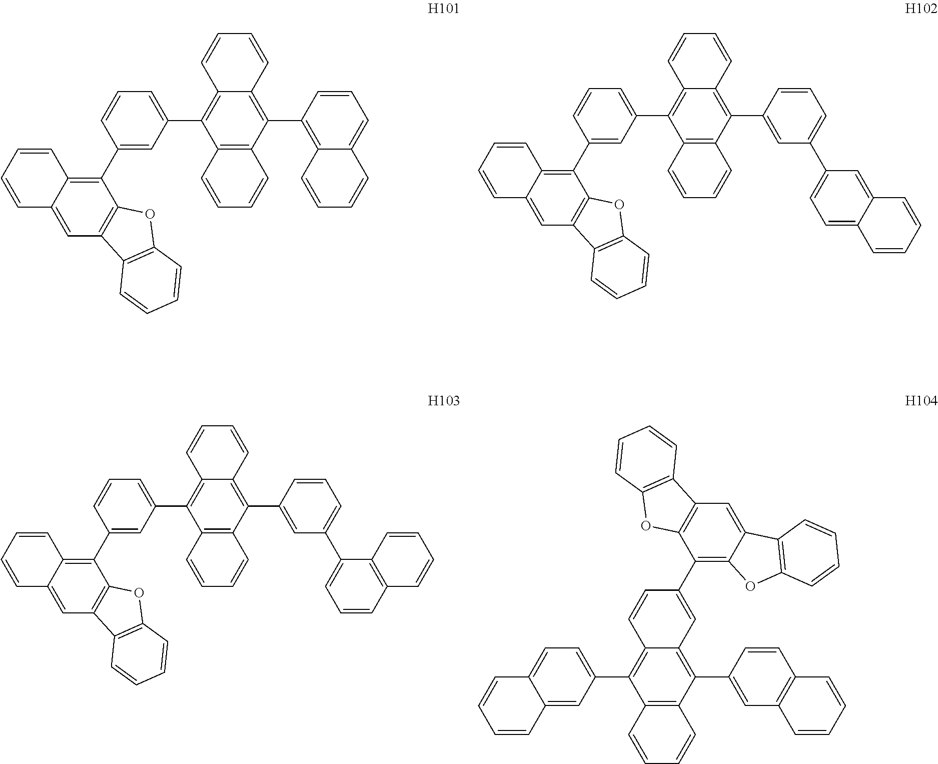 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

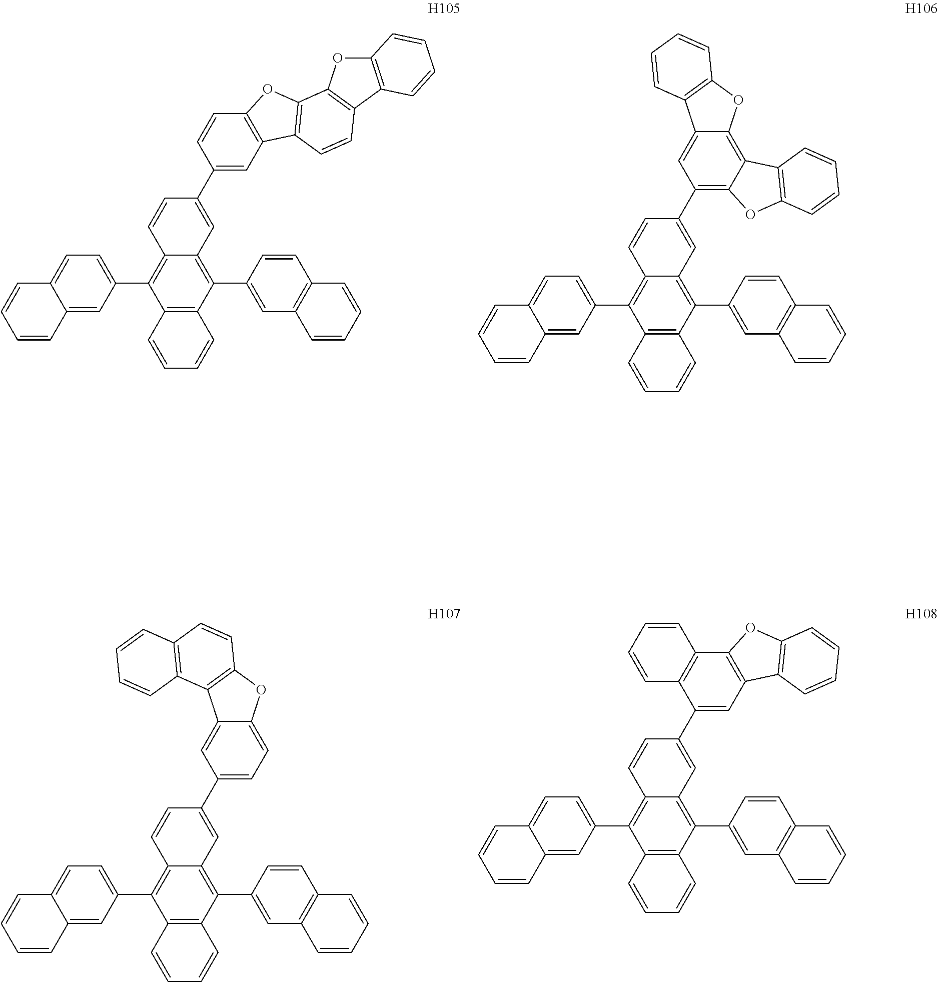 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1]

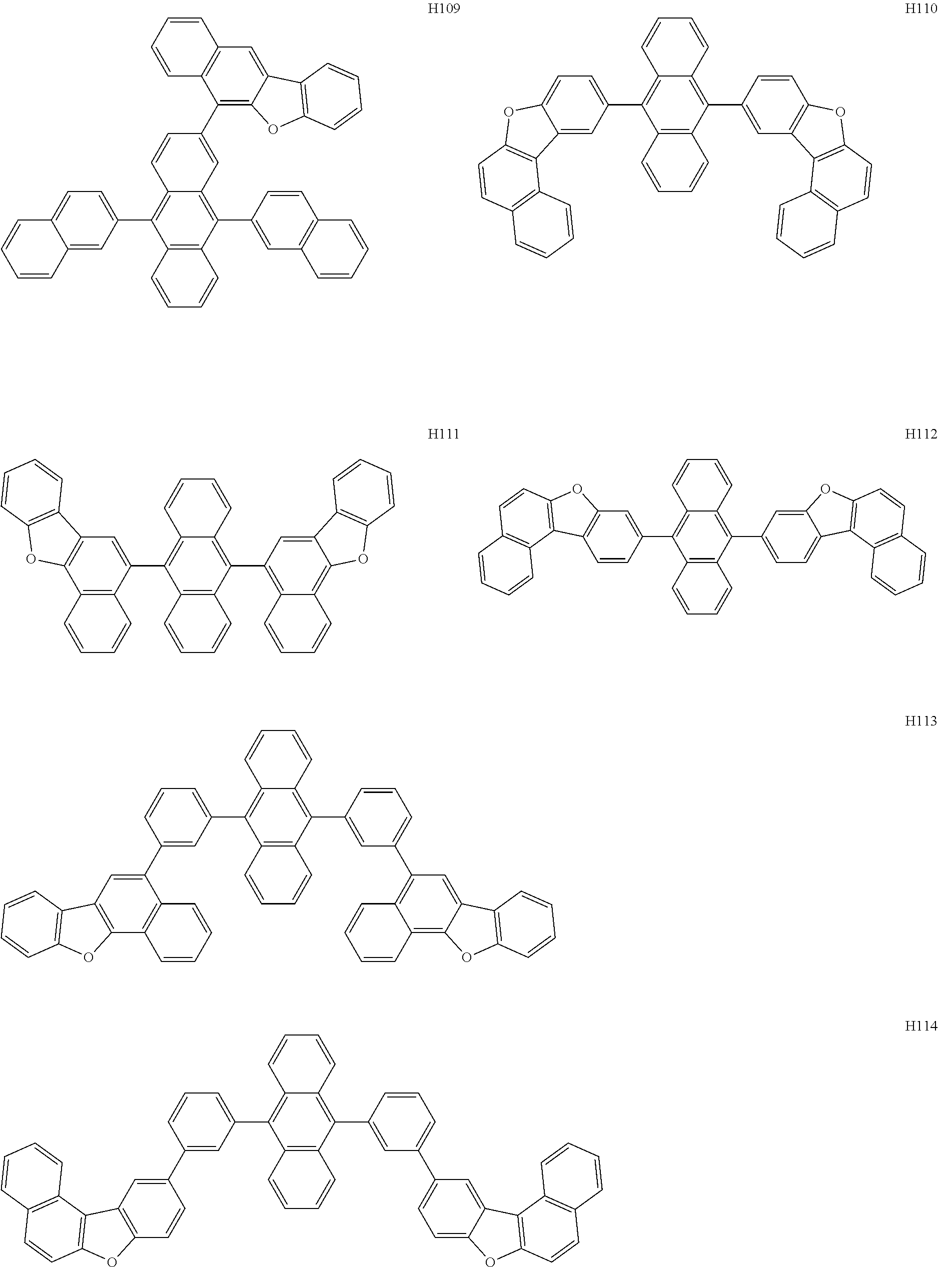

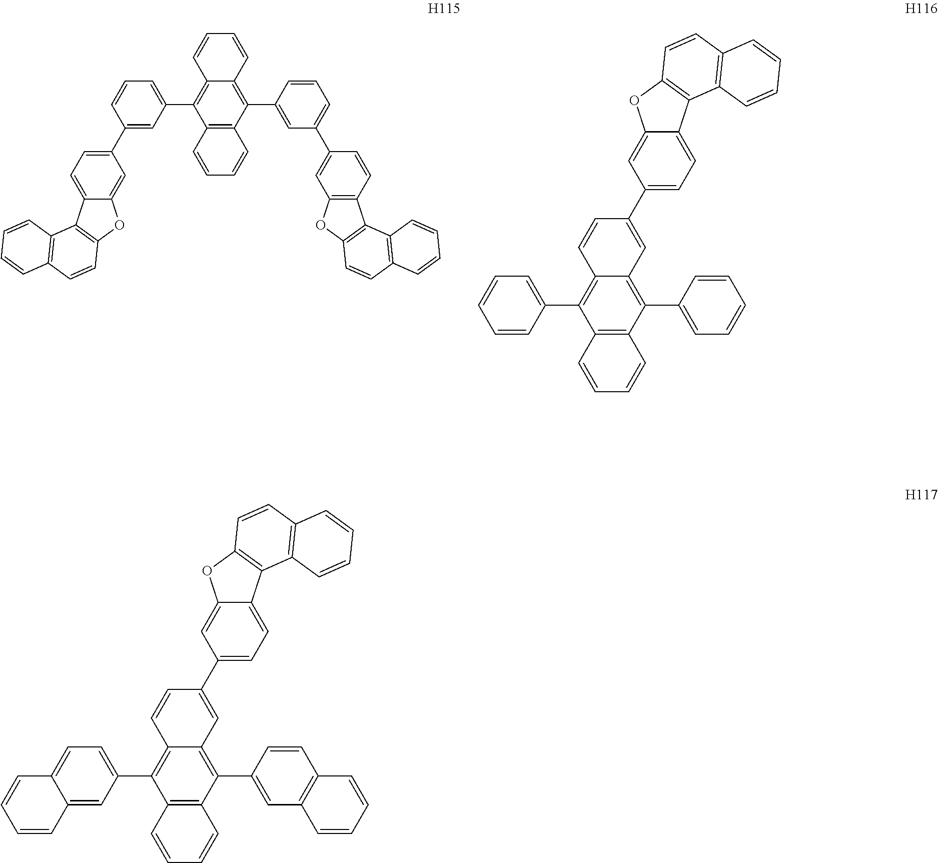 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

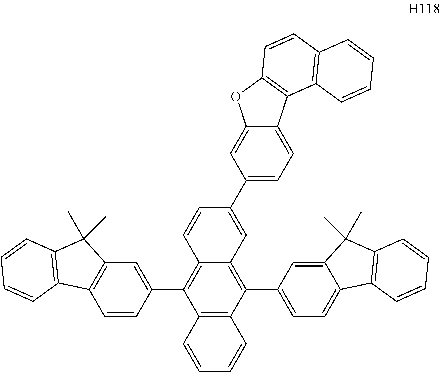 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

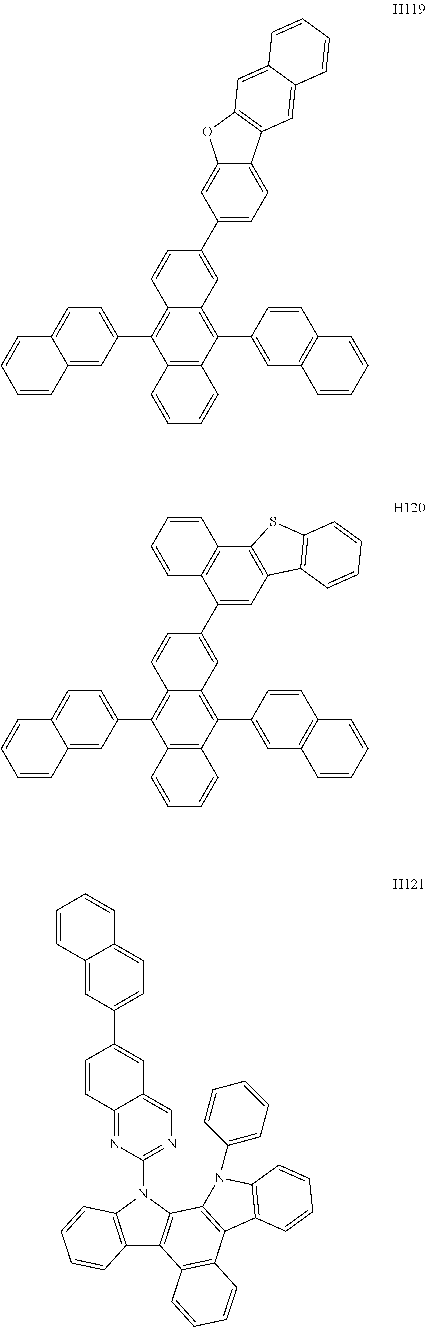 [SMILES: c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1]

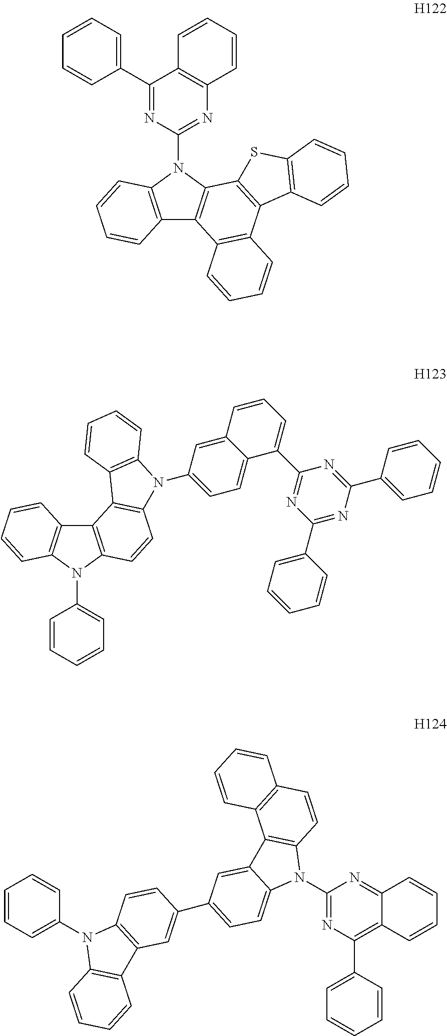 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

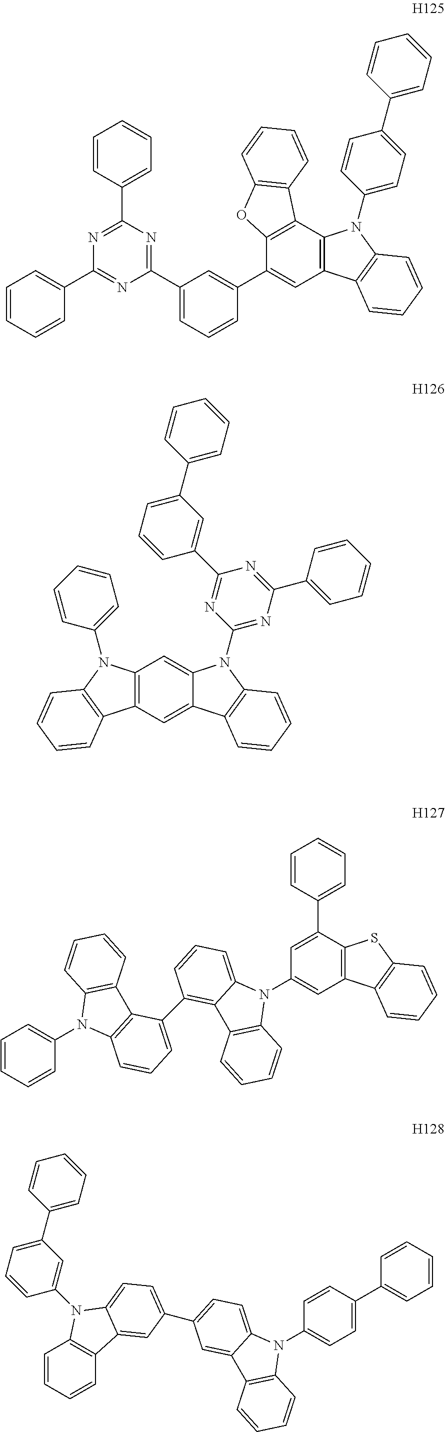 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

For example, the phosphorescent dopant may include an organometallic compound represented by Formula 401.

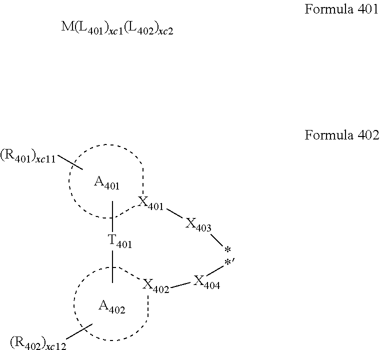

In Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), and/or thulium (Tm)),
L₄₀₁ may be a ligand represented by Formula 402, and xc1 may be 1, 2, or 3, and if (e.g., when) xc1 is 2 or more, two or more L₄₀₁s may be the same or different from each other,
L₄₀₂ may be an organic ligand, and xc2 may be 0, 1, 2, 3, or 4, and if (e.g., when) xc2 is 2 or more, two or more L₄₀₂s may be the same or different from each other,
X₄₀₁ and X₄₀₂ may each independently be nitrogen or carbon,
Rings A₄₀₁ and A₄₀₂ may each independently be a C₃-C₆₀ carbocyclic group or a C₁-C₆₀ heterocyclic group,
T₄₀₁ may be a single bond (e.g., a single covalent bond), *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (e.g., a covalent bond or a coordinate covalent bond), O, S, N(Q₄₁₃), B(Q₄₁₃), P(Q₄₁₃), C(Q₄₁₃)(Q₄₁₄), or Si(Q₄₁₃)(Q₄₁₄),
for descriptions of Q₄₁₁ to Q₄₁₄, refer to the description of Q₁ in one or more embodiments, respectively,
R⁴⁰¹ and R⁴⁰² may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
for descriptions of Q₄₀₁ to Q₄₀₃, refer to the description of Q₁ in one or more embodiments, respectively,
xc11 and xc12 may each independently be an integer of 0 to 10, and
in Formula 402, * and *′ may be binding sites with M of Formula 401.

For example, in Formula 402, i) X₄₀₁ may be nitrogen, X₄₀₂ may be carbon, or ii) both X₄₀₁ and X₄₀₂ may be nitrogen.

As another example, if (e.g., when) xc1 is 2 or more in Formula 401, two rings A₄₀₁s in the two or more L₄₀₁s may be optionally connected to each other via a linker T₄₀₂, or two rings A₄₀₂s may be optionally connected to each other via a linker T₄₀₃ (refer to Compounds PD1 to PD4 and PD7). For descriptions of T₄₀₂ and T₄₀₃, refer to the description of T₄₀₁ in one or more embodiments.

In Formula 401, L₄₀₂ may be an organic ligand. For example, L₄₀₂ may include a halogen group, a diketone group (e.g., an acetylacetonate group), a carboxylic acid group (e.g., a picolinate group), a —C(═O) group, an isonitrile group, a —CN group, a phosphorus-containing group (e.g., a phosphine group and a phosphite group), or any combination thereof.

The phosphorescent dopant may include one selected from among Compounds PD1 to PD39 or any combination thereof.

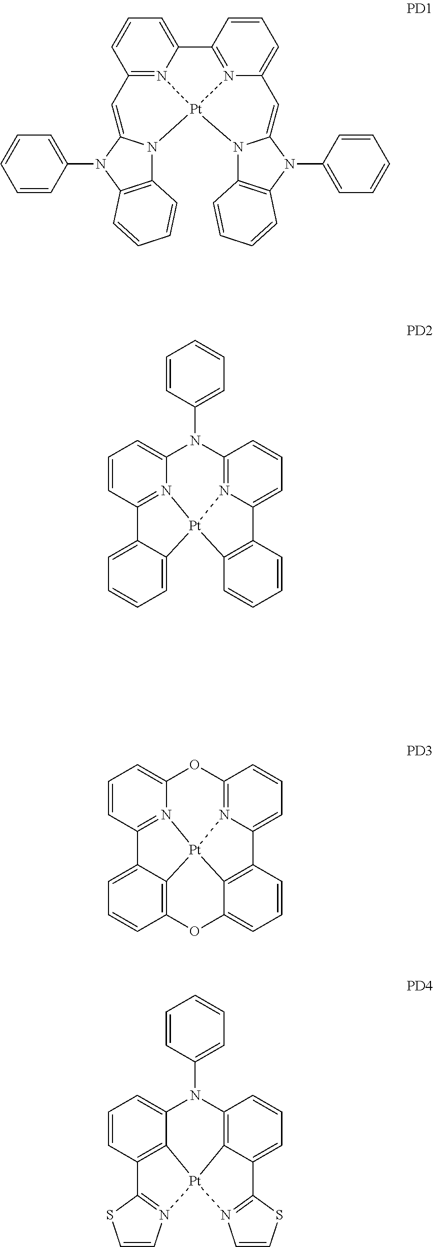

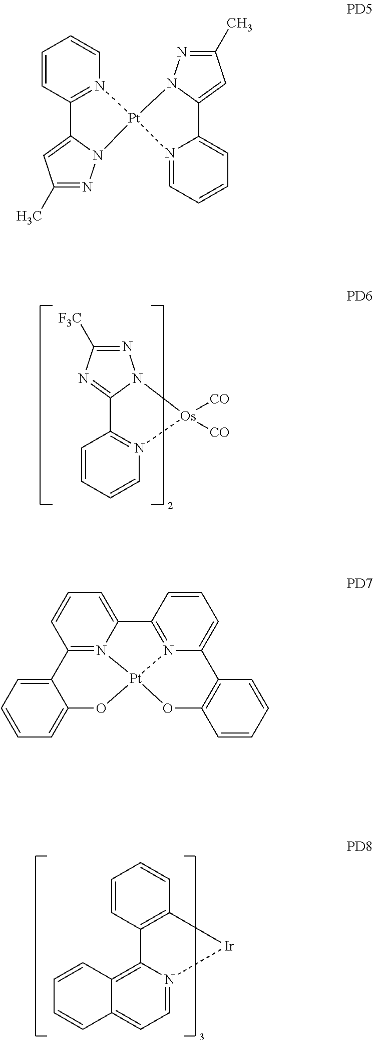

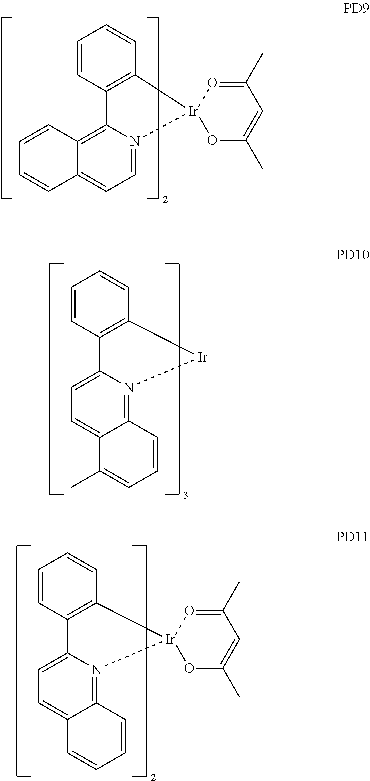

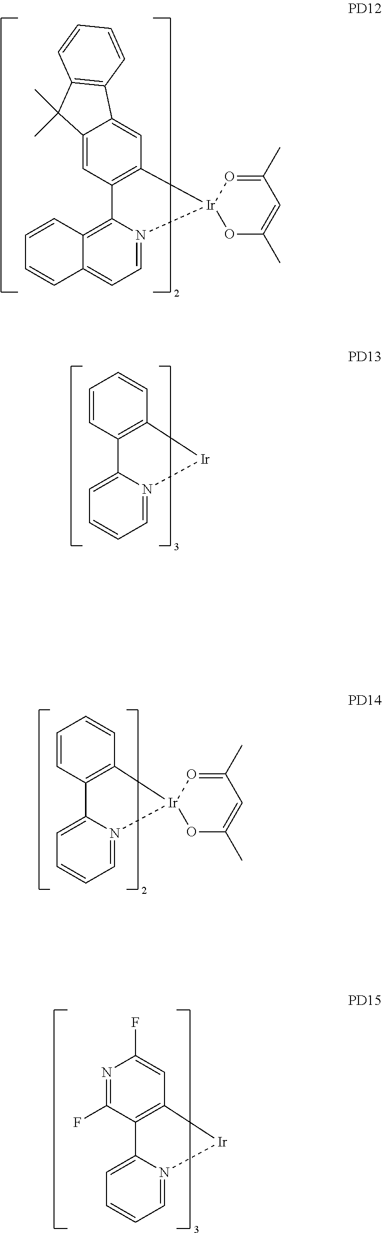

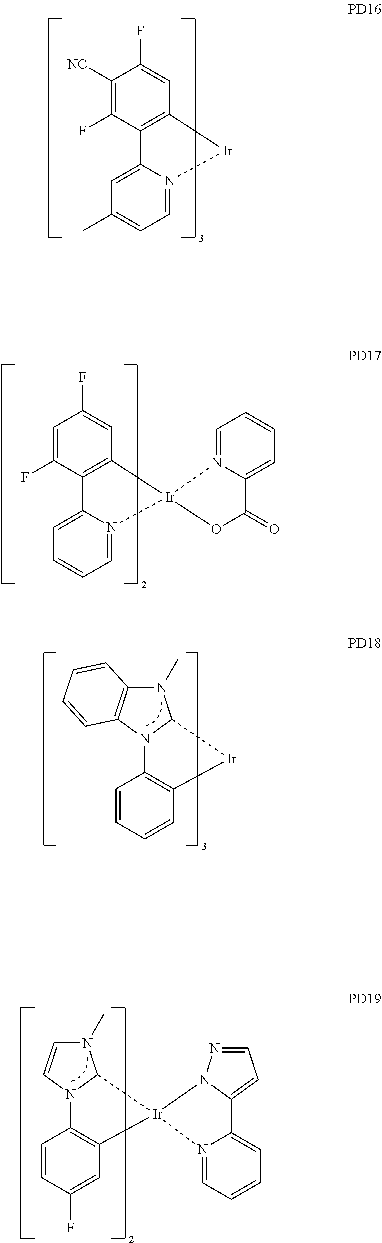

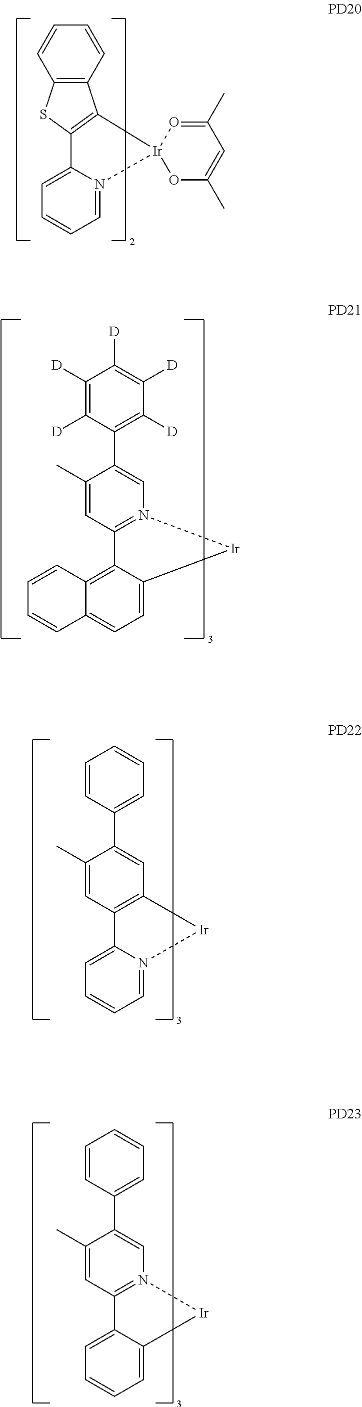

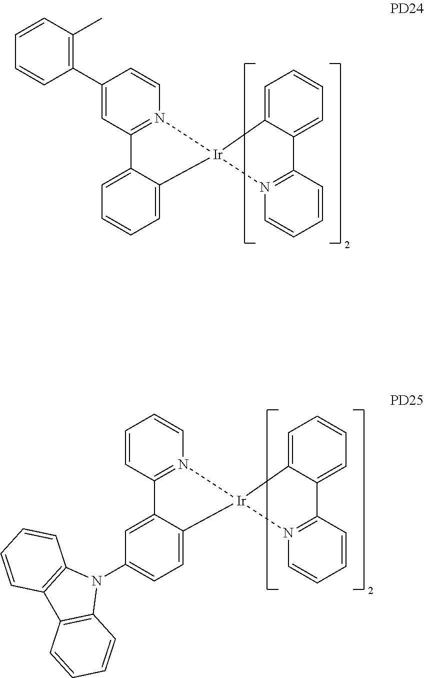

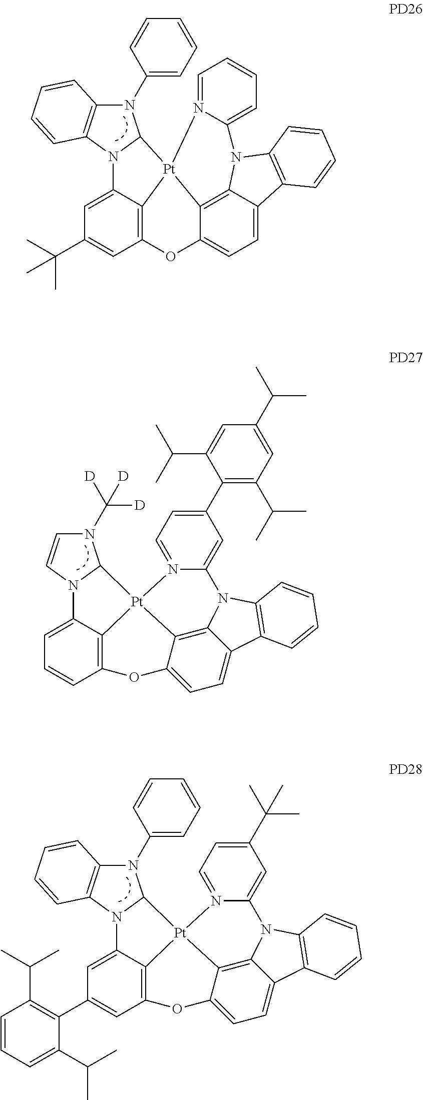

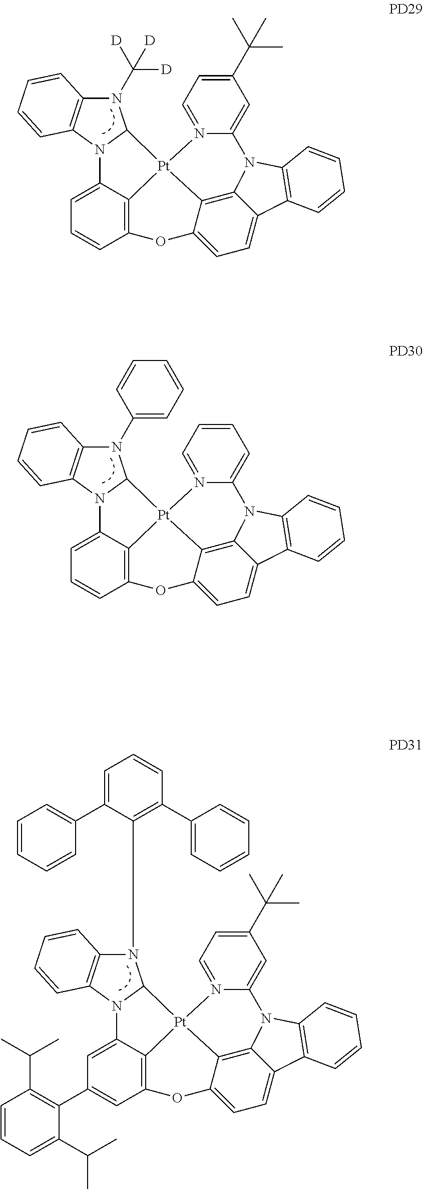

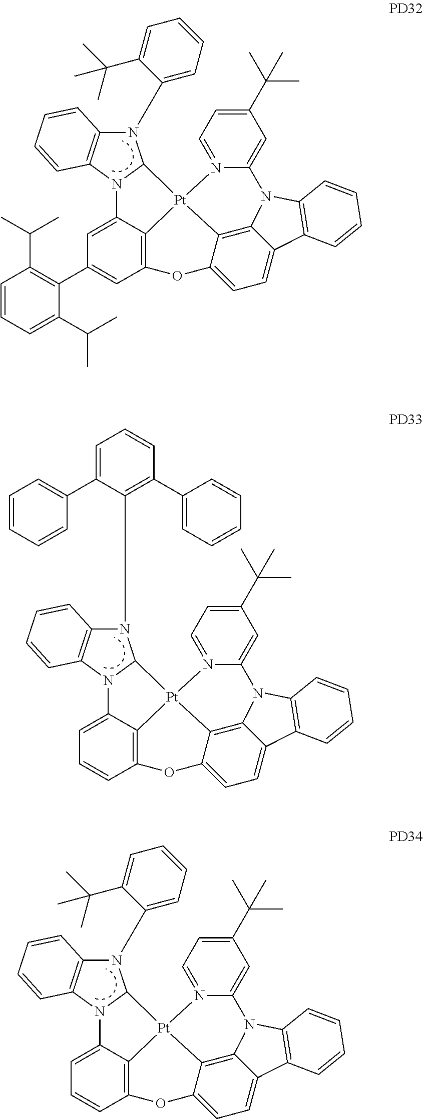

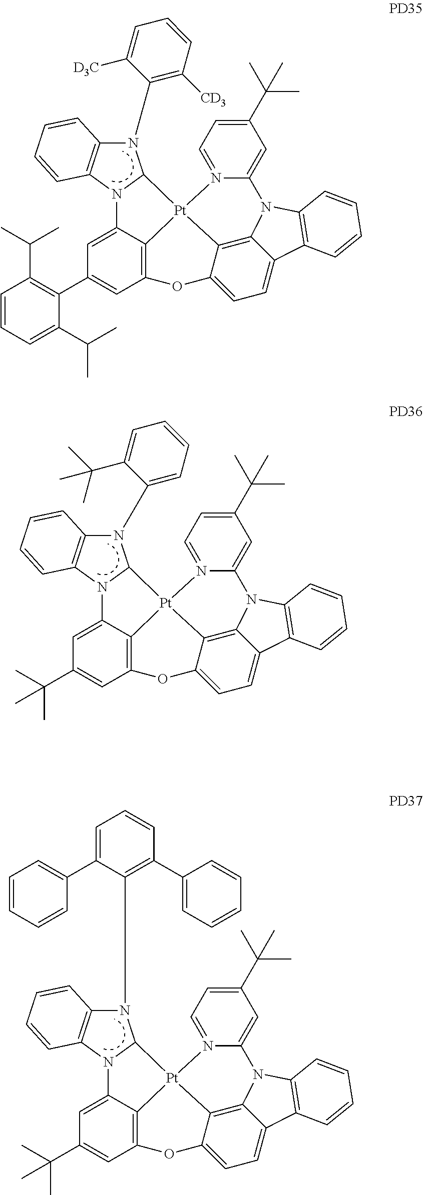

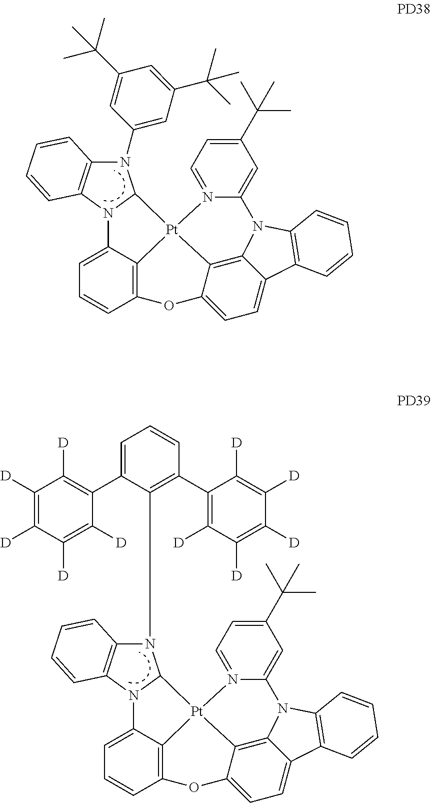

### Fluorescent Dopant

The fluorescent dopant may include an amine group-containing compound, a styryl group-containing compound, or any combination thereof.

For example, the fluorescent dopant may include a compound represented by Formula 501.

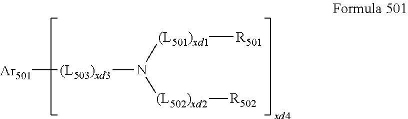

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

For example, Ar₅₀₁ in Formula 501 may include a condensed cyclic group in which three or more monocyclic groups are fused (e.g., an anthracene group, a chrysene group, and a pyrene group).

As another example, xd4 in Formula 501 may be 2.

For example, the fluorescent dopant may include one selected from among Compounds FD1 to FD37, DPVBi, DPAVBi, or ani combination thereof.

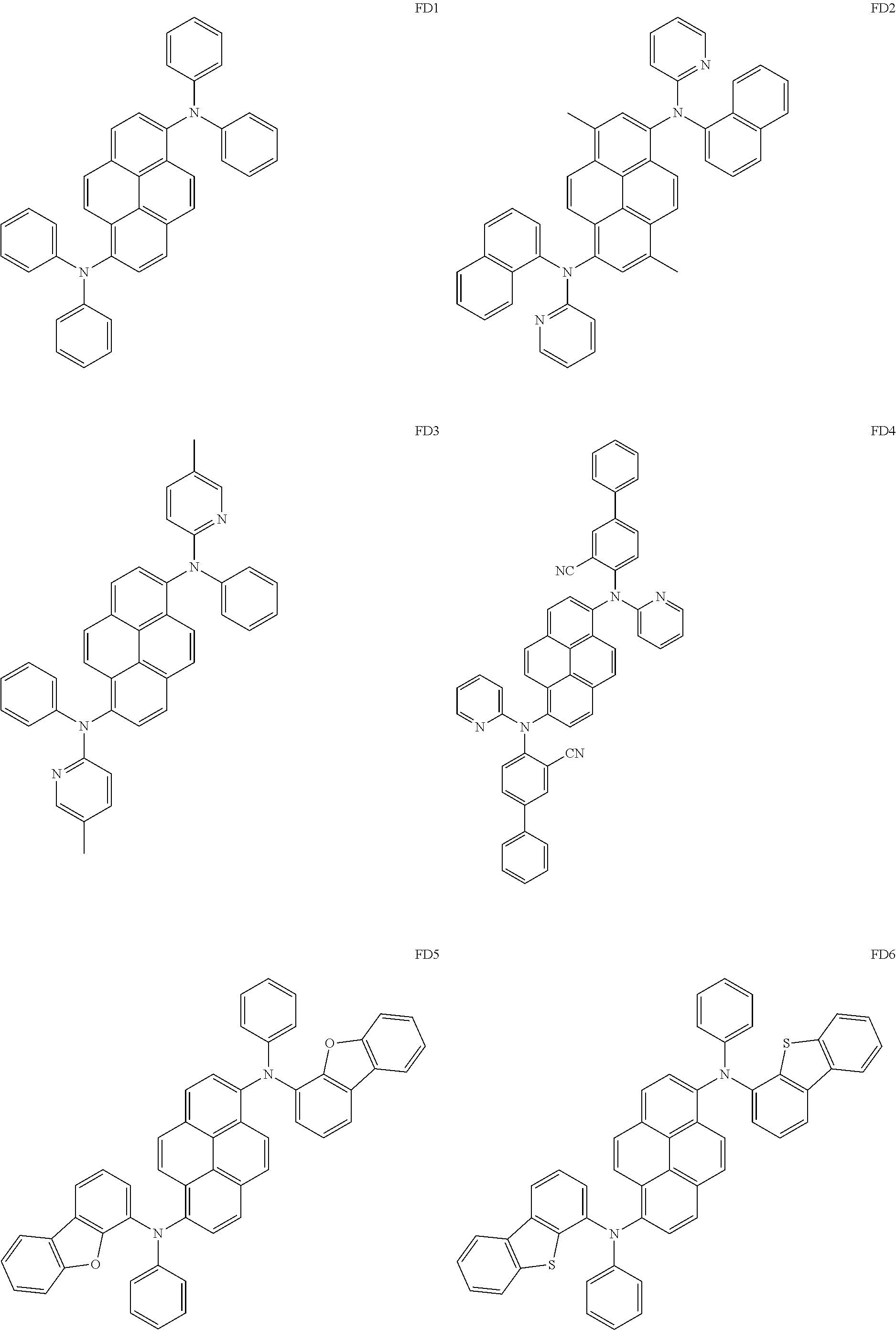

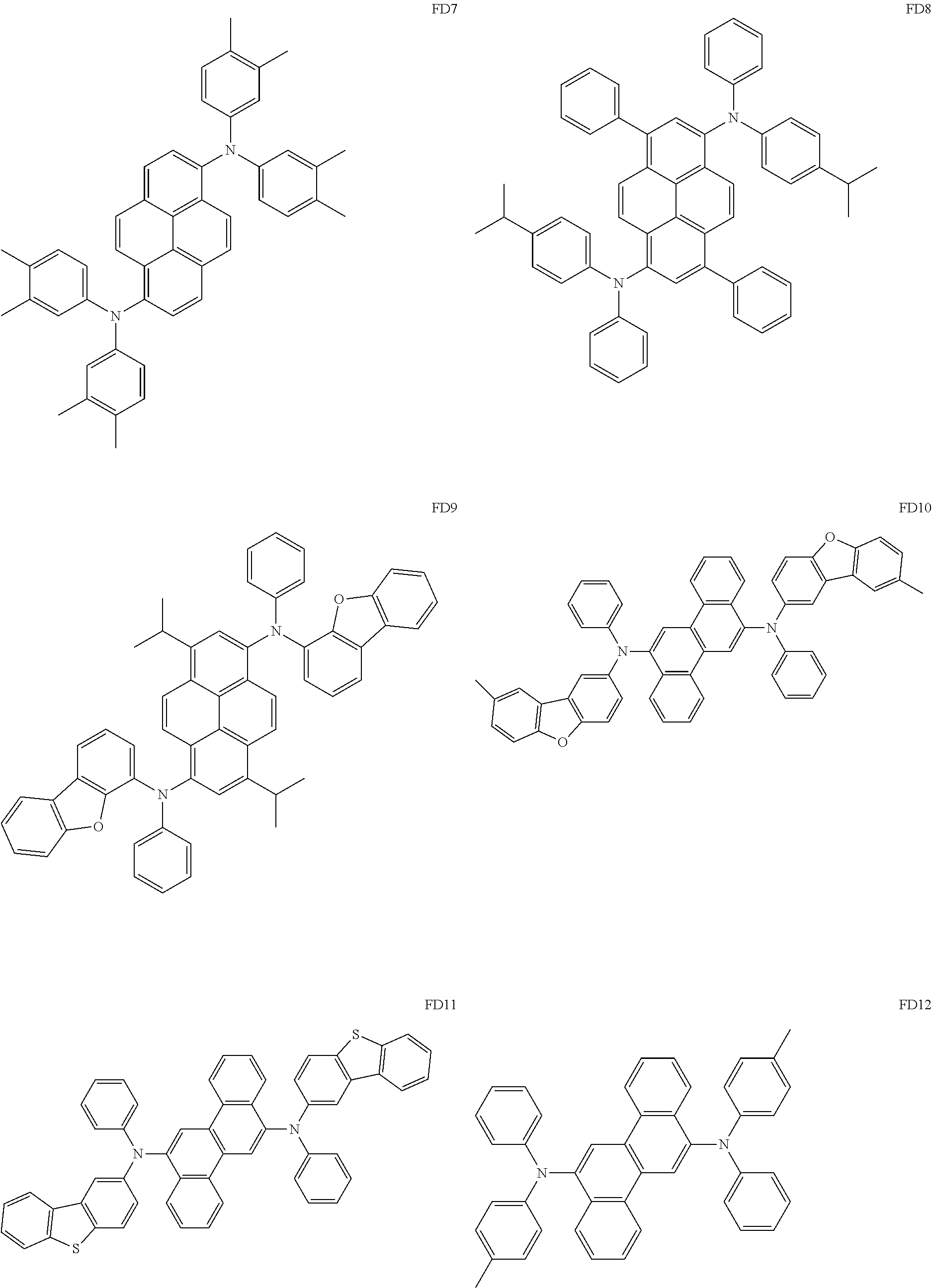

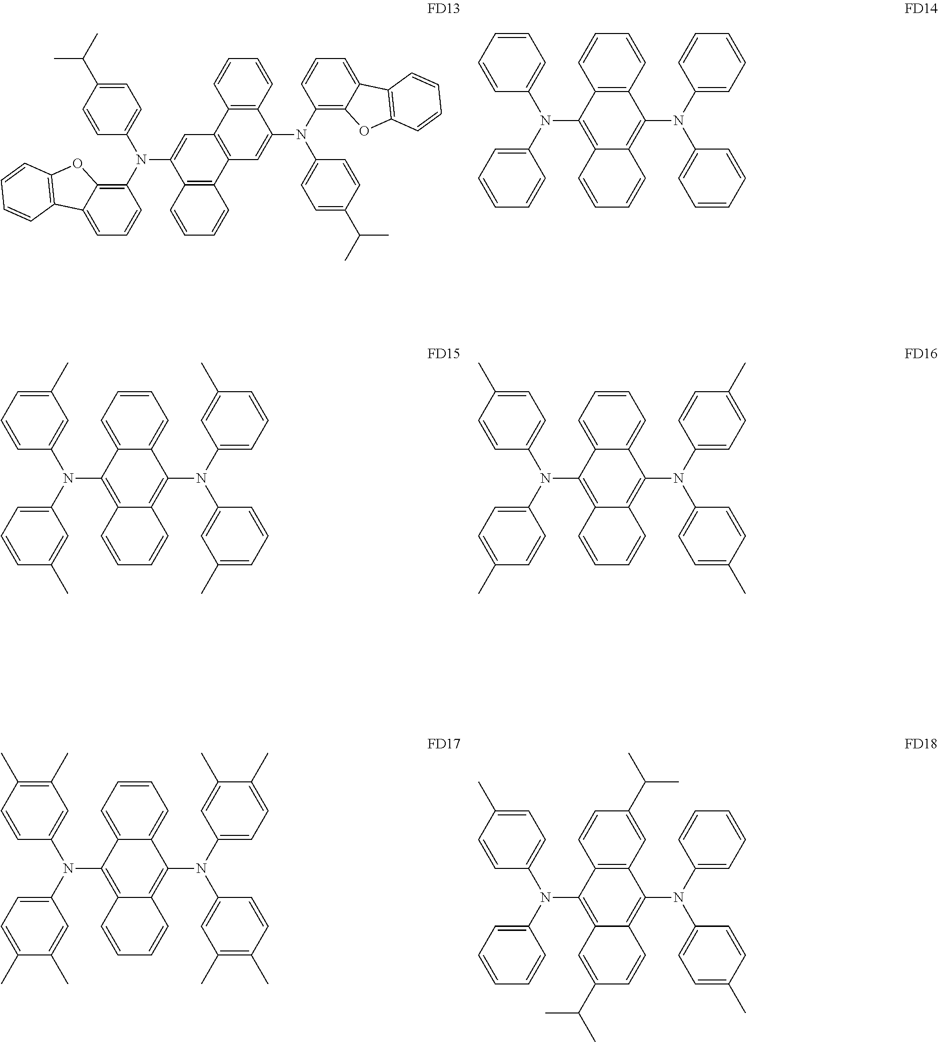

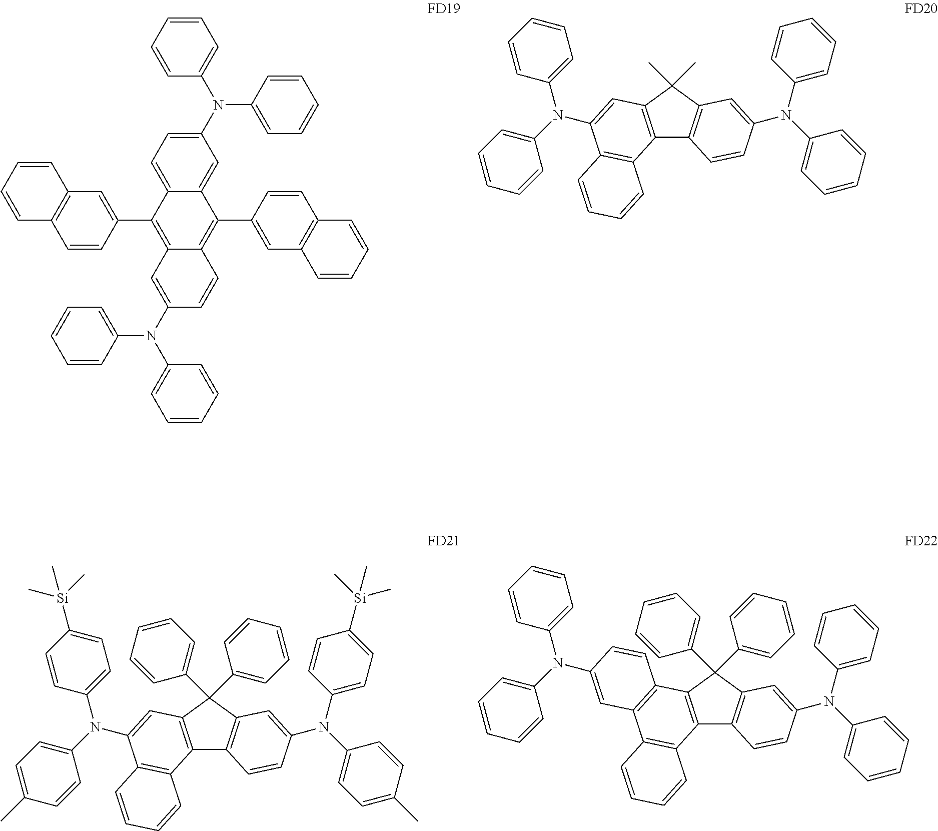

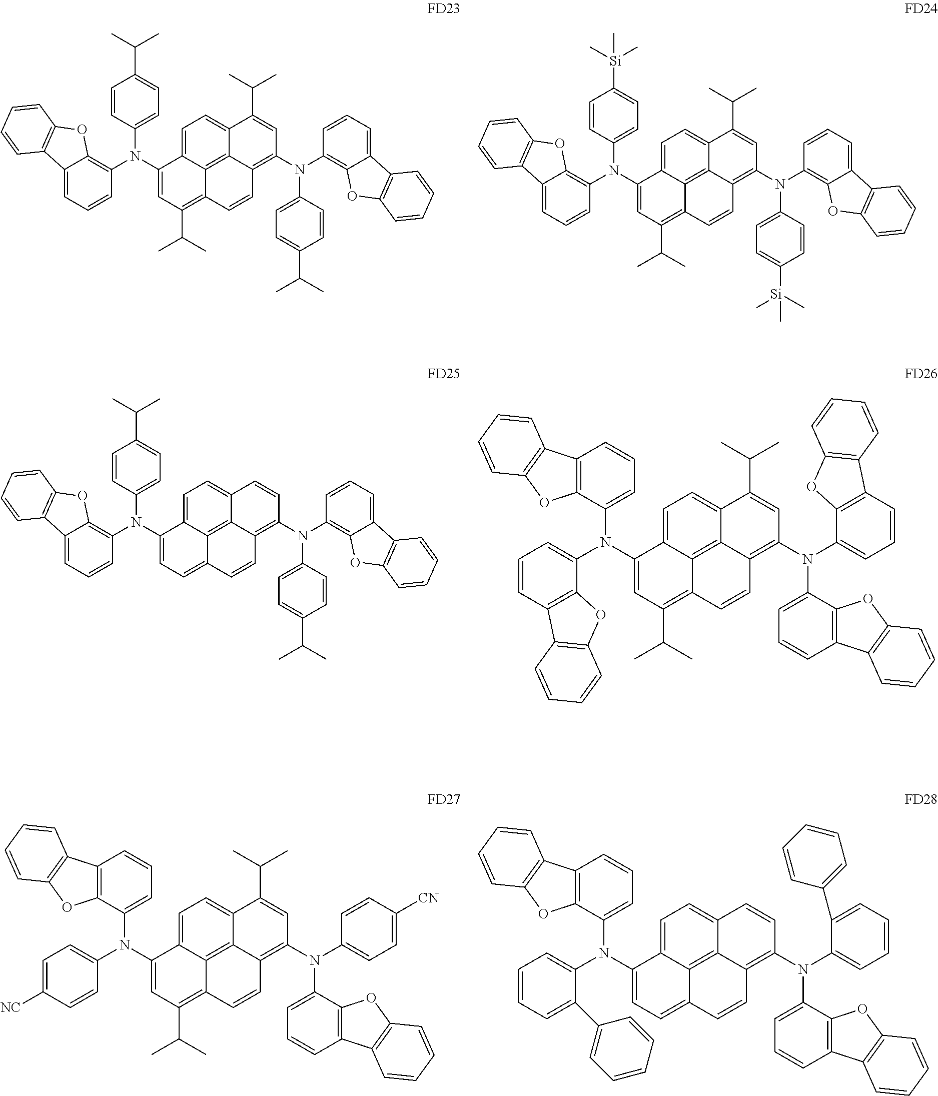

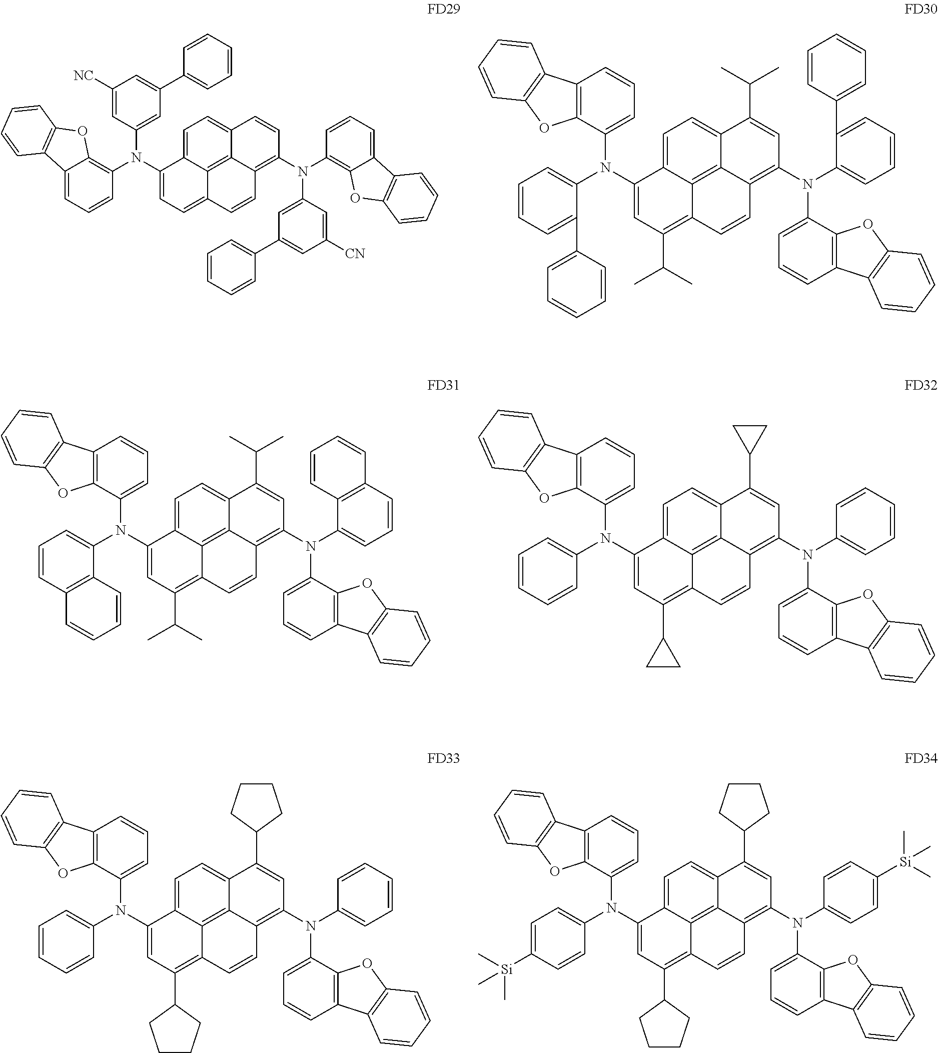

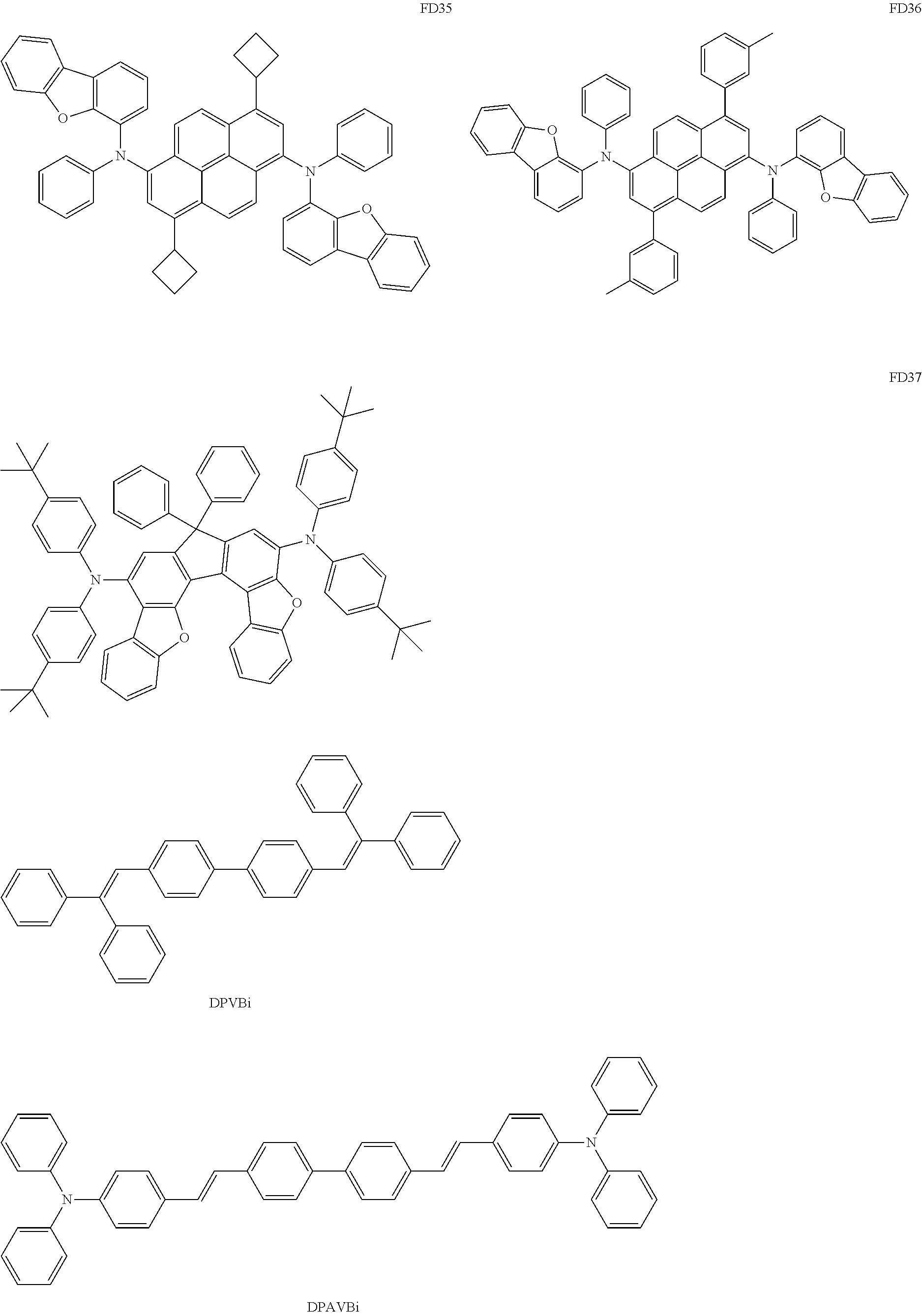

### Delayed Fluorescent Material

The emission layer may include a delayed fluorescent material.

Throughout the present disclosure, the delayed fluorescent material may be selected from any suitable compound that emits delayed fluorescence by a delayed fluorescence emission mechanism.

The delayed fluorescent material included in the emission layer may serve as a host or a dopant depending on types or kinds of other materials included in the emission layer.

According to one or more embodiments, a difference between a triplet energy level (eV) of the delayed fluorescent material and a singlet energy level (eV) of the delayed fluorescent material may be at least about 0 eV but not more than about 0.5 eV. By satisfying the foregoing range of the difference between the triplet energy level (eV) of the delayed fluorescent material and the singlet energy level (eV) of the delayed fluorescent material, reverse energy transfer (up-conversion) from the triplet state to the singlet state in the delayed fluorescent material may effectively or suitably occur, thereby improving or enhancing emission efficiency and other performance of the light-emitting element.

For example, the delayed fluorescent material may include i) a substance including at least one electron donor (e.g., a π electron-rich C₃-C₆₀ cyclic group, such as carbazole group) and at least one electron acceptor (e.g., a sulfoxide group, a cyano group, and/or a π electron-deficient nitrogen-containing C₁-C₆₀ heterocyclic group), ii) a C₈-C₆₀ polycyclic group including two or more cyclic groups condensed while sharing a boron (B) atom, and/or the like.

Examples of the delayed fluorescent material may include at least one selected from among Compounds DF1 to DF14.

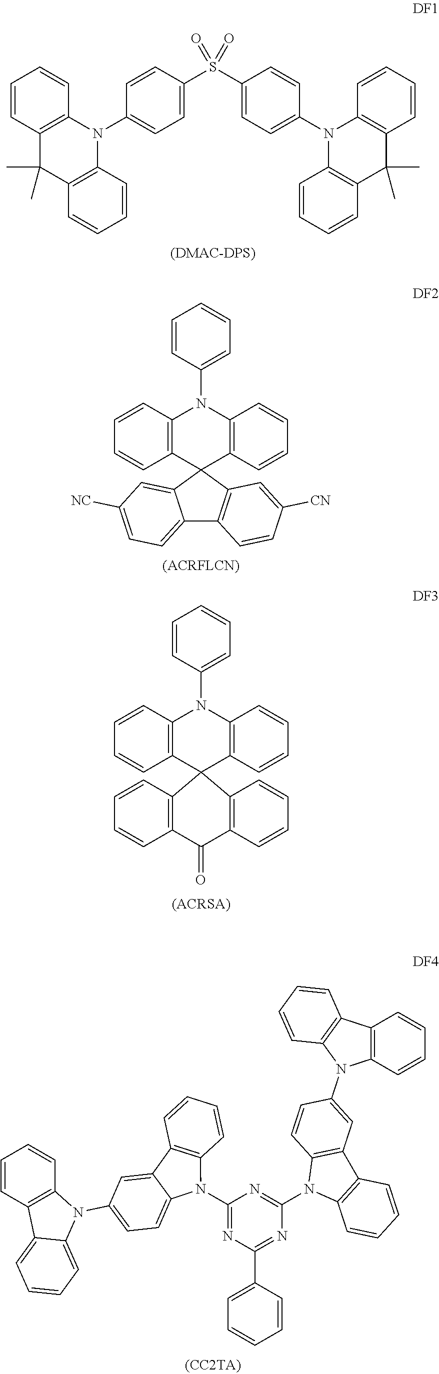

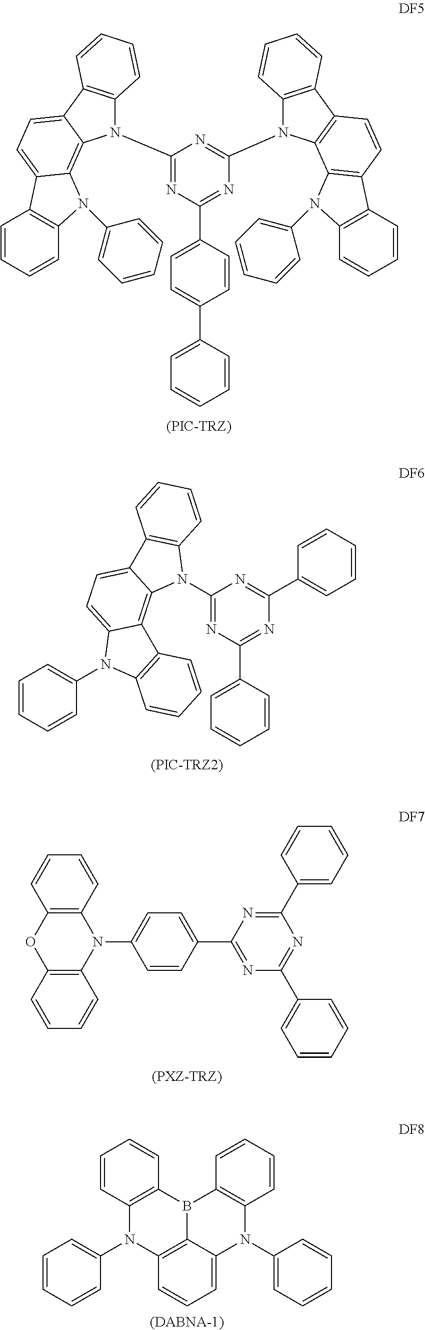

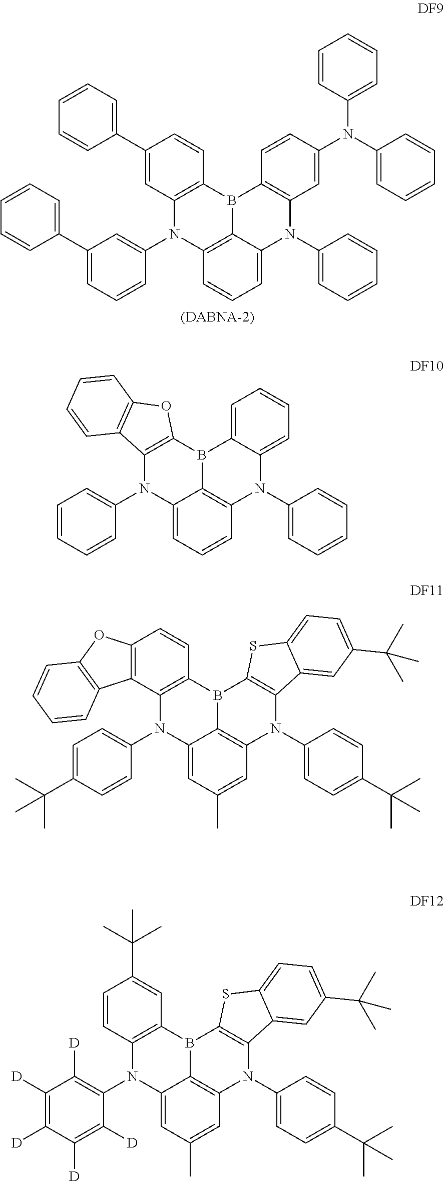

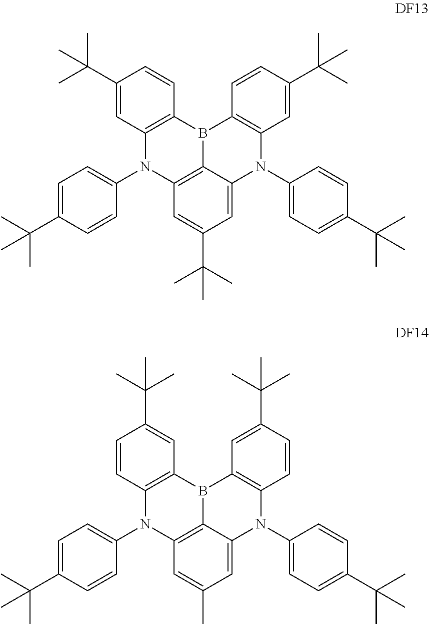

### Quantum Dot

According to one or more embodiments, the emission layer may include the quantum dot as described in one or more embodiments. The emission layer may further include other quantum dots different from the quantum dot as described in one or more embodiments in addition to the quantum dot as described in one or more embodiments.

Throughout the present disclosure, the quantum dot refers to a crystal of a semiconductor compound. Quantum dots may emit light of one or more suitable wavelengths depending on the size of the crystal. Quantum dots may emit light of one or more suitable wavelengths by adjusting or optimizing a composition ratio of elements constituting the quantum dots.

A diameter of the quantum dot may be, for example, about 1 nm to about 10 nm.

The quantum dot may be synthesized by a wet chemical process, metal organic chemical vapor deposition, molecular beam epitaxy, and/or similar processes.

The wet chemical process may be a method of growing quantum dot crystals after mixing precursor materials and an organic solvent. While the crystals are growing, the organic solvent may naturally act as a coordinating dispersant on the surface of the quantum dot crystals and control the growth of the crystals, so that (e.g., such that) the growth of the quantum dot crystals may be controlled more easily with lower costs compared to vapor deposition, such as metal organic chemical vapor deposition (MOCVD) and/or molecular beam epitaxy (MBE).

The quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV semiconductor compound; or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; and a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Examples of the Group III-V semiconductor compound may include: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. In one or more embodiments, the Group III-V semiconductor compound may further include a Group II element, such as InZnP, InGaZnP, and/or InAlZnP.

Examples of the Group III-VI semiconductor compound may include a binary compound, such as GaS, Ga₂S₃, GaSe, Ga₂Se₃, GaTe, InS, InSe, In₂S₃, In₂Se₃, and/or InTe; a ternary compound, such as InGaS₃ and/or InGaSe₃; or any combination thereof.

Examples of the Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂; a quaternary compound, such as CuInGaS, CuInGaS₂, AgInGaS, AgInGaS₂, AgInGaSe, and/or AgInGaSe₂; or any combination thereof.

Examples of the Group IV-VI semiconductor compound may include: a binary compound, such as SnS, SnSe, SnTe, PbS, PbSe, and/or PbTe; a ternary compound, such as SnSeS, SnSeTe, SnSTe, PbSeS, PbSeTe, PbSTe, SnPbS, SnPbSe, and/or SnPbTe; a quaternary compound, such as SnPbSSe, SnPbSeTe, and/or SnPbSTe; or any combination thereof.

The Group IV semiconductor compound may include: a single element, such as Si and/or Ge; a binary compound, such as SiC and/or SiGe; or any combination thereof.

Each element included in a multi-element compound, such as the binary compound, the ternary compound, and/or the quaternary compound, may be present in a substantially uniform concentration or non-uniform concentration in a particle. For example, the formulae refer to types or kinds of elements included in the compound, and the composition ratio of elements in the compound may vary. For example, AgInGaS₂ may refer to AgInₓGa₁₋ₓS₂ (where x is a real number from 0 to 1).

In one or more embodiments, the quantum dot may have a single structure in which the concentration of each element included in the quantum dot is uniform (e.g., substantially uniform) or a core-shell dual structure. For example, a substance included in the core may be different from the substance included in the shell.

The shell of the quantum dot may serve as a protective layer configured or provided to maintain semiconductor properties by preventing chemical degradation of the core and/or a charging layer (or by reducing a degree or occurrence of chemical degradation of the core and/or a charging layer) configured or provided to provide electrophoretic properties to the quantum dot. The shell may be formed or provided as a single layer or two or more layers. The interface between the core and the shell may have a concentration gradient in which the concentration of elements present in the shell decreases toward the center.

Examples of the shell of the quantum dot may include an oxide of a metal or a non-metal, a semiconductor compound, or any combination thereof. Examples of the oxide of a metal or a non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgAl₂O₄, CoFe₂O₄, NiFe₂O₄, and/or CoMn₂O₄; or any combination thereof. Examples of the semiconductor compound may include: the Group III-VI semiconductor compound; the Group II-VI semiconductor compound; the Group III-V semiconductor compound; the Group III-VI semiconductor compound; the Group I-III-VI semiconductor compound; the Group IV-VI semiconductor compound; or any combination thereof as described herein. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

The quantum dot may have a full width at half maximum (FWHM) of the emission wavelength spectrum of about 45 nm or less, for example, about 40 nm or less, and for example, about 30 nm or less. Within the foregoing ranges, color purity and color reproducibility may be improved or enhanced. In one or more embodiments, the light emitted from the quantum dots as described in one or more embodiments may be radiated in all directions, thereby enhancing a viewing angle of the light.

In one or more embodiments, for example, the quantum dot may have a spherical nanoparticle shape (e.g., a substantially spherical nanoparticle shape), a pyramidal nanoparticle shape (e.g., a substantially pyramidal nanoparticle shape), a multi-arm nanoparticle shape (e.g., a substantially multi-arm nanoparticle shape), or a cubic nanoparticle shape (e.g., a substantially cubic nanoparticle shape) or may have a nanotube-like particle shape (e.g., a substantially nanotube-like particle shape), a nanowire-like particle shape (e.g., a substantially nanowire-like particle shape), a nanofiber-like particle shape (e.g., a substantially nanofiber-like particle shape), or a nanoplate-like particle shape (e.g., a substantially nanoplate-like particle shape).

Because the energy band gap is controlled by adjusting or optimizing the size of the quantum dot and/or the composition ratio of elements within the quantum dot, emission of light having one or more suitable wavelengths may be obtained from the quantum dot emission layer. Accordingly, by utilizing the quantum dots as described in one or more embodiments (e.g., quantum dots having different sizes and having different composition ratios of elements in the quantum dot composition), light having one or more suitable wavelengths may be realized or provided. For example, the adjustment of the size of the quantum dots and the composition ratio of elements in the quantum dot compound may be made to allow emission of red, green, and/or blue light. In one or more embodiments, the quantum dots may be configured or provided such that lights of one or more suitable colors combine to emit white light.

### Electron Transport Region

The electron transport region may have i) a single-layer structure consisting of (e.g., including) a single layer consisting of (e.g., including) a single material, ii) a single-layer structure consisting of (e.g., including) a single layer including a plurality of different materials, or iii) a multi-layer structure including a plurality of layers including a plurality of different materials.

The electron transport region may include a buffer layer, a hole blocking layer, an electron control layer, an electron transport layer, an electron injection layer, or any combination thereof.

For example, the electron transport region may have a multi-layer structure of electron transport layer/electron injection layer, hole blocking layer/electron transport layer/electron injection layer, electron control layer/electron transport layer/electron injection layer, or buffer layer/electron transport layer/electron injection layer, each sequentially stacked on the emission layer.

The electron transport region (e.g., the buffer layer, the hole blocking layer, the electron control layer, and/or the electron transport layer in the electron transport region) may include a metal-free compound including at least one π electron-deficient nitrogen-containing C₁-C₆₀ heterocyclic group.

For example, the electron transport region may include a compound represented by Formula 601.

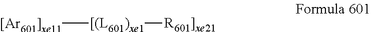

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
for descriptions of Q₆₀₁ to Q₆₀₃, refer to the description of Q₁ provided in one or more embodiments,
xe21 may be 1, 2, 3, 4, or 5, and
at least one selected from among Ar₆₀₁, L₆₀₁, and R₆₀₁ may each independently be a π electron-deficient nitrogen-containing C₁-C₆₀ heterocyclic group unsubstituted or substituted with at least one R₁₀ₐ.

For example, if (e.g., when) xe11 is 2 or more in Formula 601, two or more A₆₀₁s may be connected to each other by a single bond (e.g., a single covalent bond).

As another example, Ar₆₀₁ of Formula 601 may be an anthracene group unsubstituted or substituted with at least one R₁₀ₐ.

As another example, the electron transport region may include a compound represented by Formula 601-1.

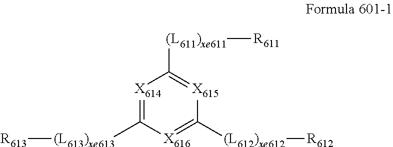

In Formula 601-1,
X₆₁₄ may be N or C(R₆₁₄), X₆₁₅ may be N or C(R₆₁₅), X₆₁₆ may be N or C(R₆₁₆), or at least one selected from among X₆₁₄ to X₆₁₆ may be N,
for descriptions of L₆₁₁ to L₆₁₃, refer to the description of L₆₀₁, respectively,
for descriptions of xe611 to xe613, refer to the description of xe1, respectively,
for descriptions of R⁶¹¹ to R⁶¹³, refer to the description of R₆₀₁, respectively, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, in Formula 601 and 601-1, xe1 and xe611 to xe613 may each independently be 0, 1, or 2.

The electron transport region may include one of Compounds ET1 to ET45, 2,9-dimethyl-4,7-diphenyl-1, 10-phenanthroline (BCP), 4,7-diphenyl-1,10-phenanthroline (Bphen), Alq₃, BAlq, TAZ, NTAZ, or any combination thereof.

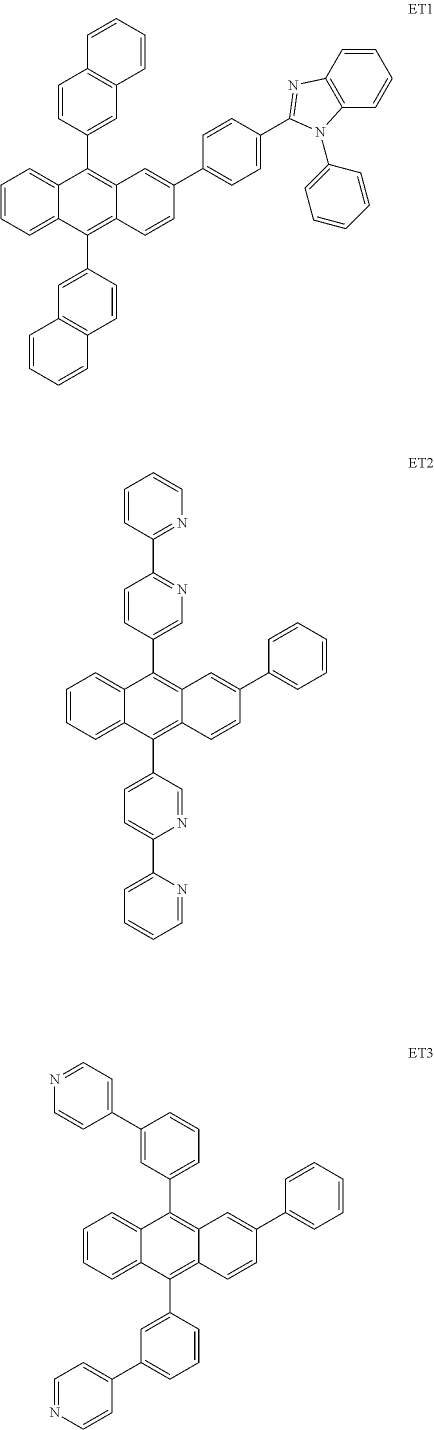 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

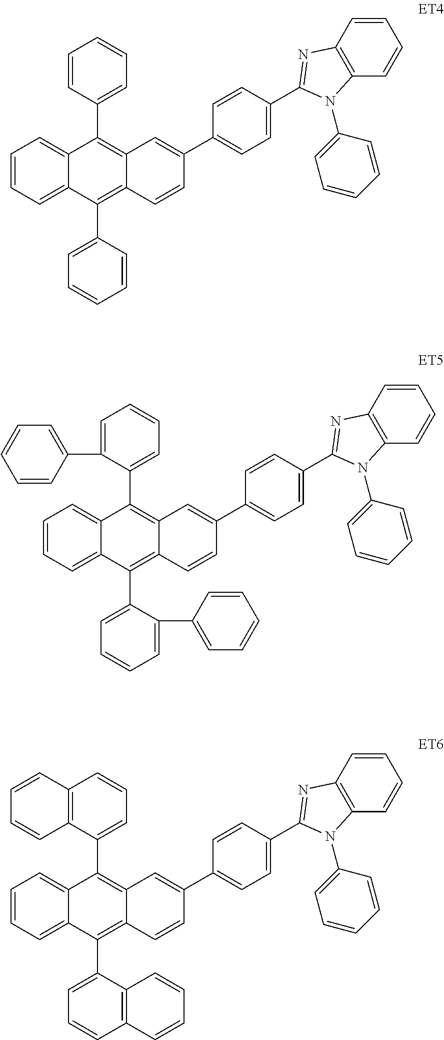 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

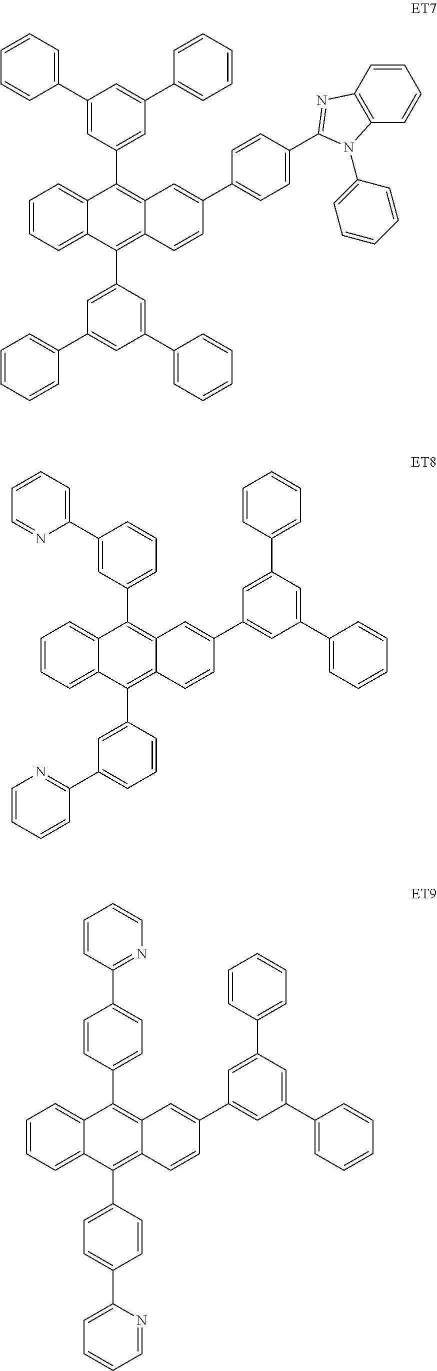 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

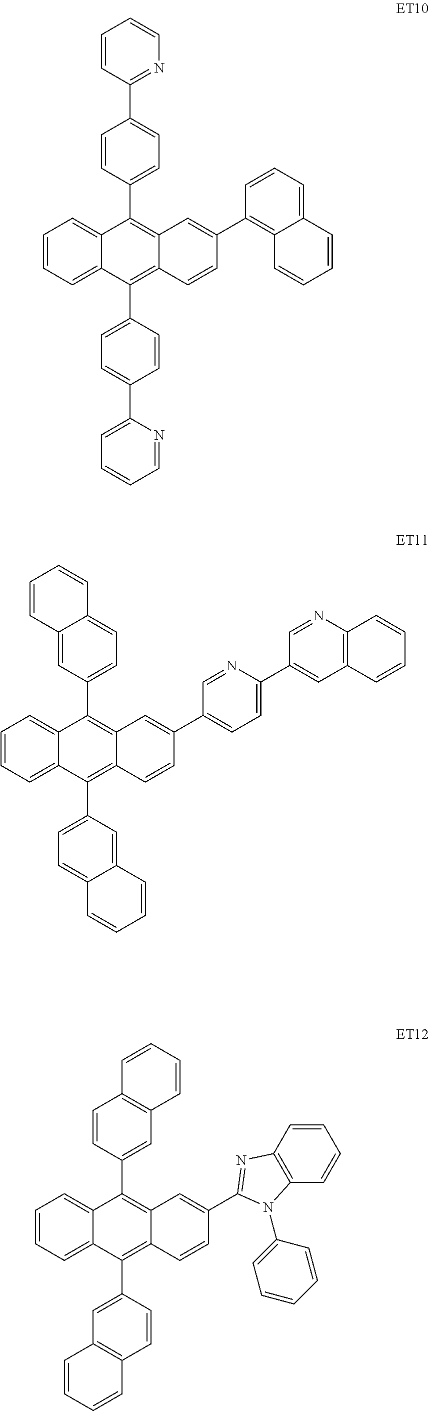 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

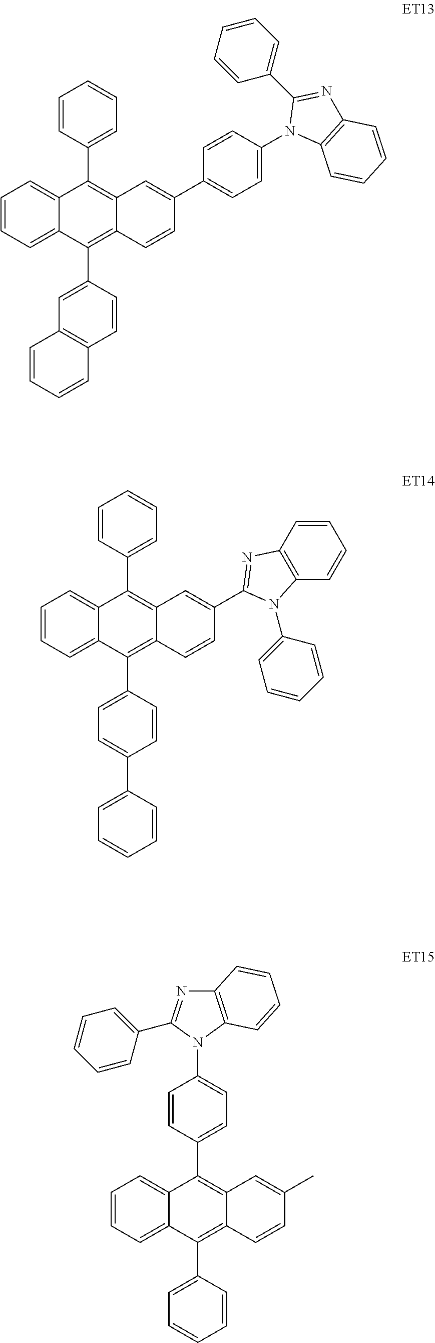 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

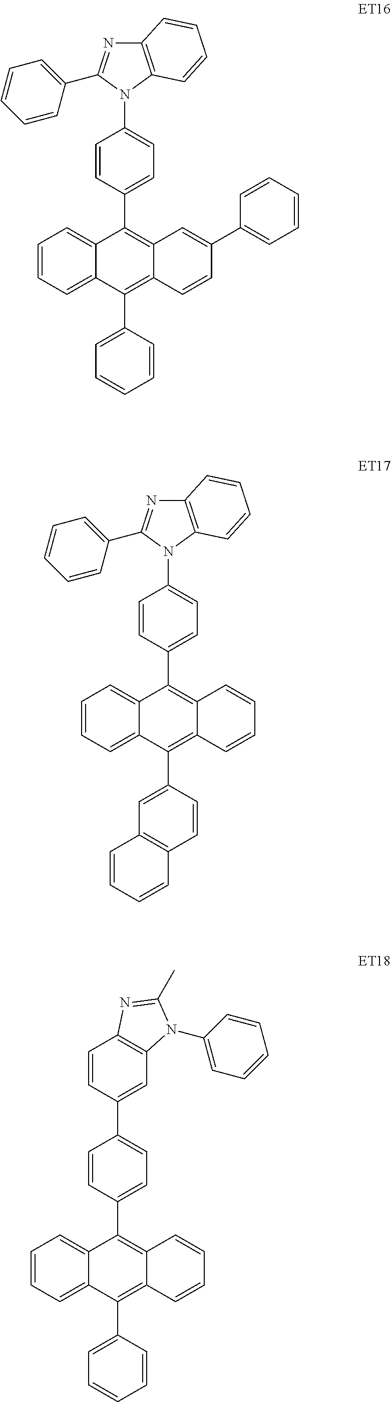 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

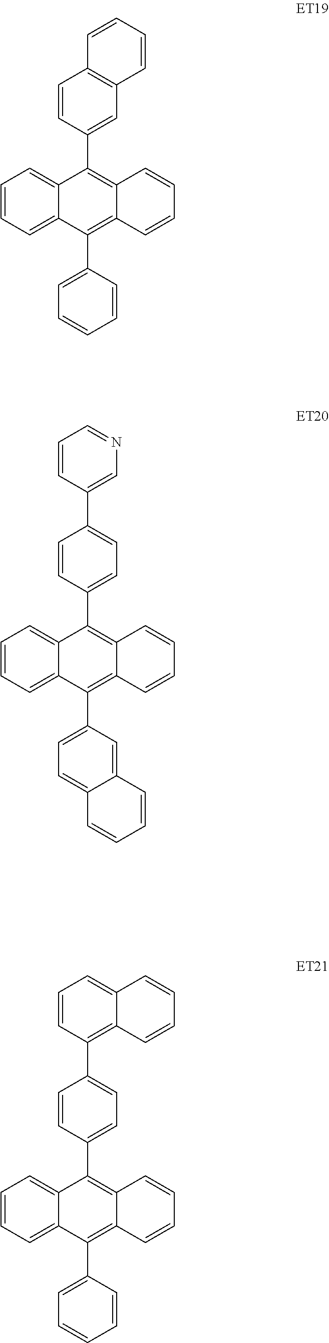

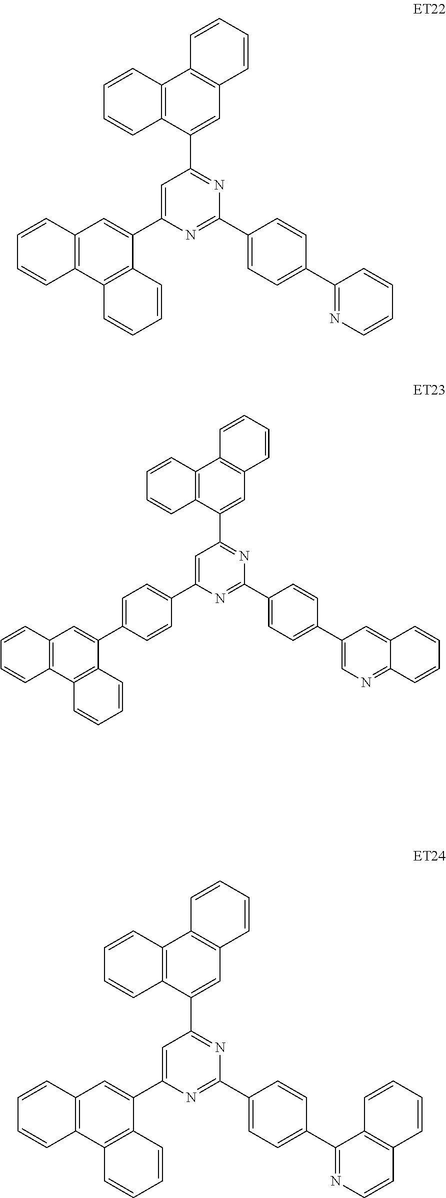 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

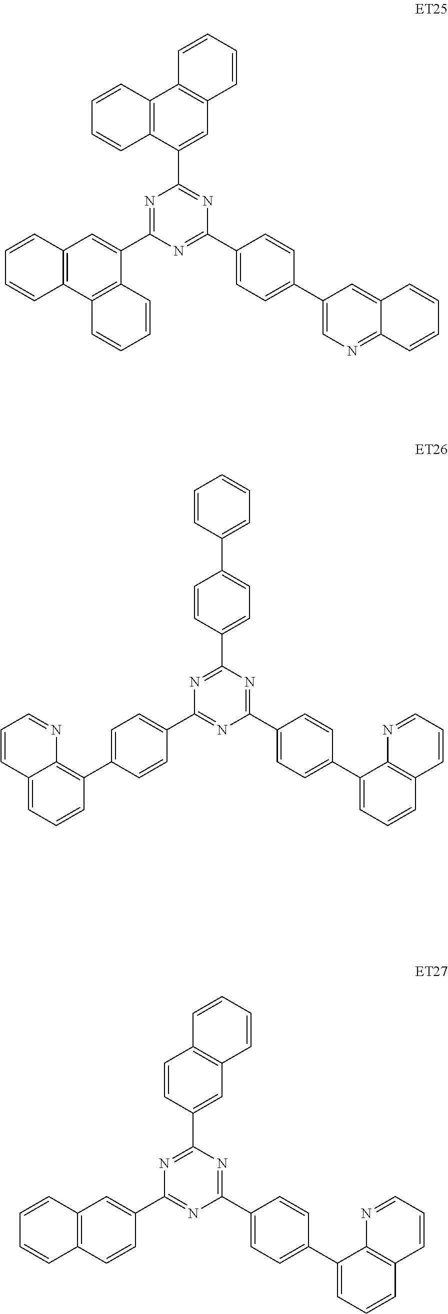 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

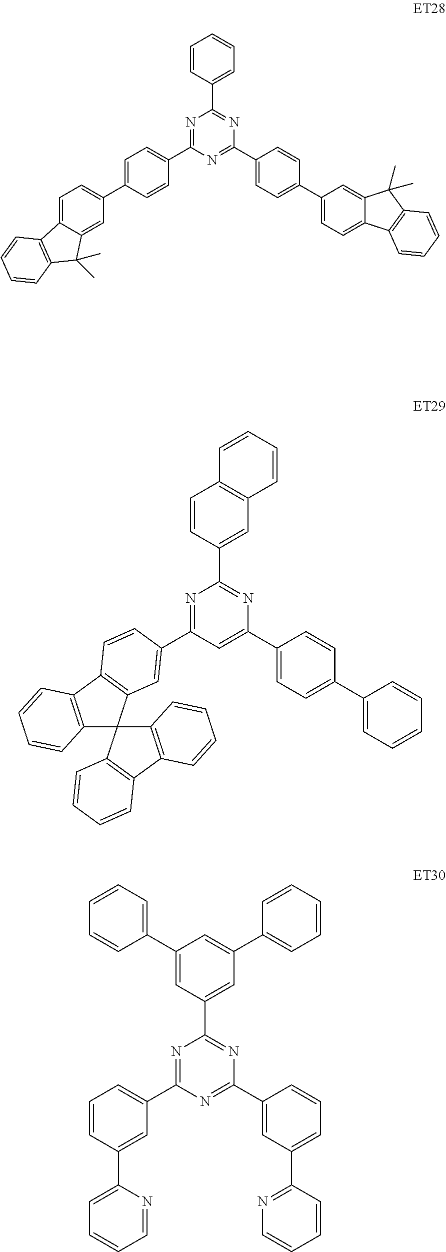 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

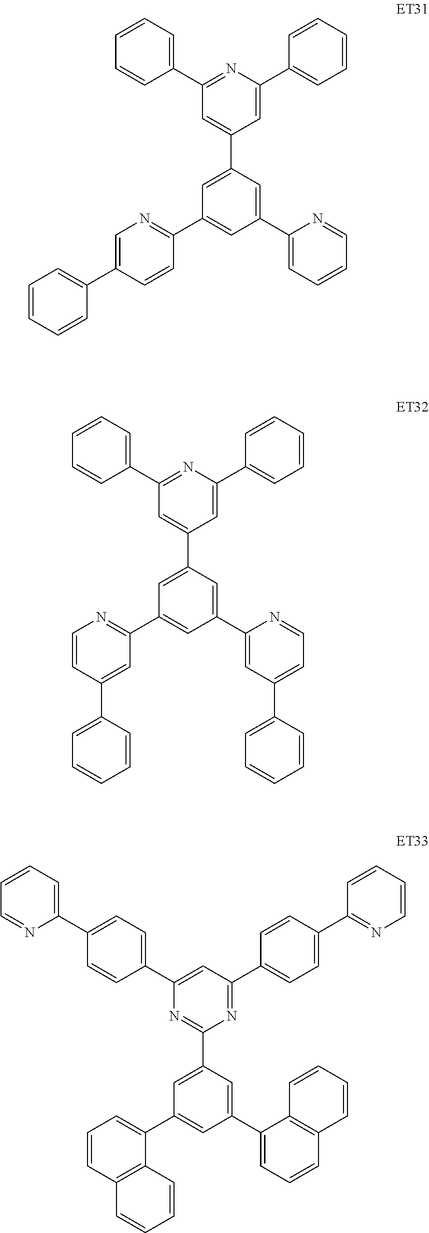 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

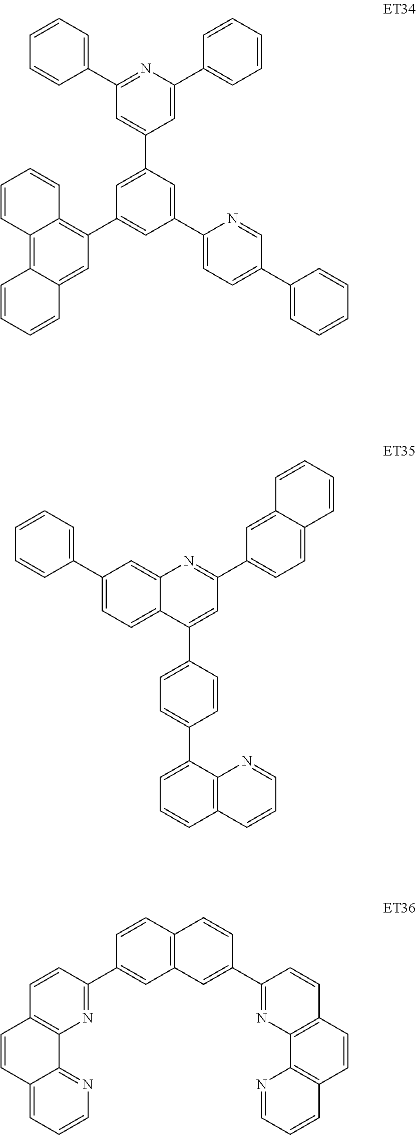 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

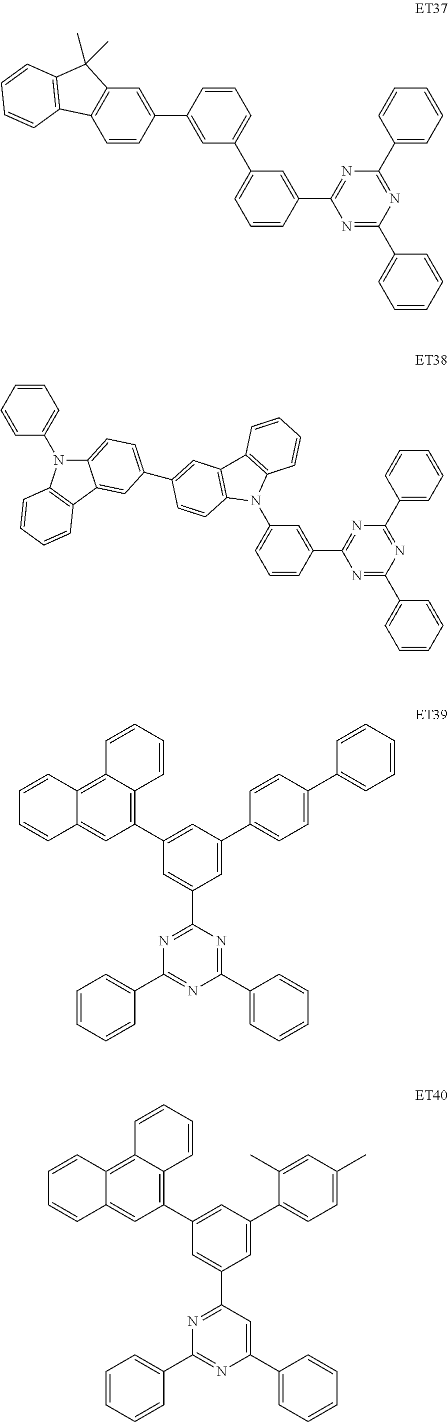 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

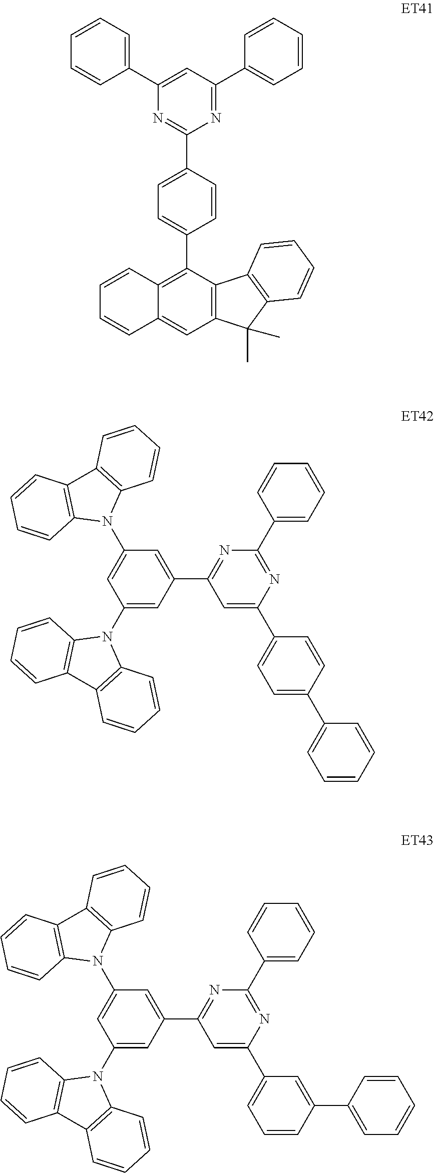 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

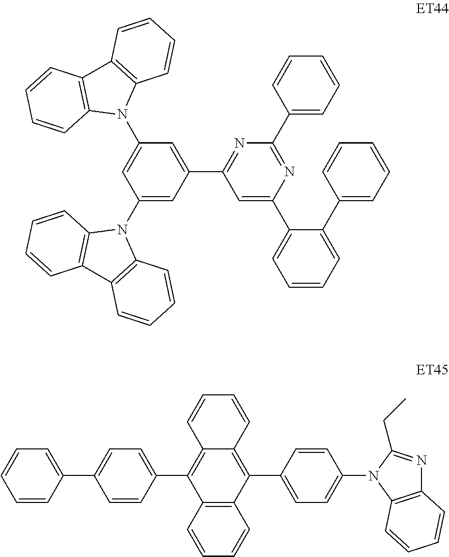 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

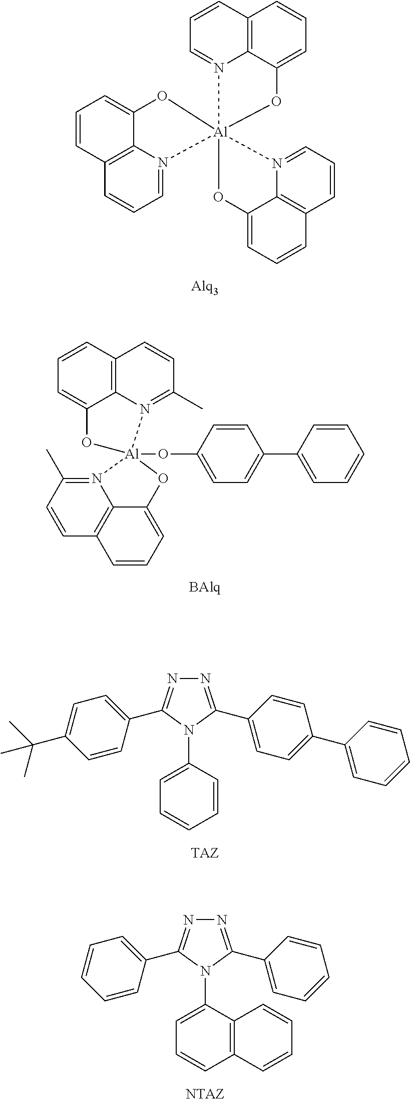

A thickness of the electron transport region may be about 100 Å to about 5000 Å, for example, about 160 Å to about 4000 Å. If (e.g., when) the electron transport region includes a buffer layer, a hole blocking layer, an electron control layer, an electron transport layer, or any combination thereof, a thickness of the buffer layer, the hole blocking layer, or the electron control layer may be about 20 Å to about 1000 Å, for example, about 30 Å to about 300 Å, respectively, and a thickness of the electron transport layer may be about 100 Å to about 1000 Å, for example, about 150 Å to about 500 Å. By adjusting or optimizing the thicknesses of the buffer layer, the hole blocking layer, the electron control layer, the electron transport layer, and/or the electron transport region to be within the foregoing ranges, satisfactory or suitable electron transport characteristics may be obtained without a substantial increase in driving voltage.

The electron transport region (e.g., the electron transport layer in the electron transport region) may further include a metal-containing material in addition to the materials as described in one or more embodiments.

The metal-containing material may include an alkali metal complex, an alkaline earth metal complex, or any combination thereof. Metal ions of the alkali metal complex may be a Li ion, a Na ion, a K ion, a Rb ion, or a Cs ion, and metal ions of the alkaline earth metal complex may be a Be ion, a Mg ion, a Ca ion, a Sr ion, or a Ba ion. Ligands coordinated to the metal ions of the alkali metal complex and the alkaline earth metal complex may each independently include hydroxyquinoline, hydroxyisoquinoline, hydroxybenzoquinoline, hydroxyacridine, hydroxylphenanthridine, hydroxyphenyl oxazole, hydroxyphenyl thiazole, hydroxyphenyl oxadiazole, hydroxyphenyl thiadiazole, hydroxyphenyl pyridine, hydroxyphenyl benzomidazole, hydroxyphenyl benzothiazole, bipyridine, phenanthroline, cyclopentadiene, or any combination thereof.

For example, the metal-containing material may include a Li complex. The Li complex may include, for example, Compounds ET-D1 (Liq) or ET-D2.

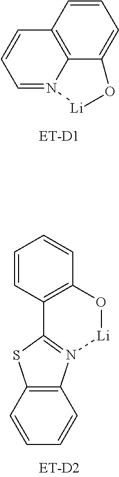

The electron transport region may include an electron injection layer facilitating injection of electrons from the second electrode 150. The electron injection layer may be in direct contact with the second electrode 150.

The electron injection layer may have i) a single-layer structure consisting of (e.g., including) a single layer consisting of (e.g., including) a single material, ii) a single-layer structure consisting of (e.g., including) a single layer including a plurality of different materials, or iii) a multi-layer structure including a plurality of layers including a plurality of different materials.

The electron injection layer may include an alkali metal, an alkaline earth metal, a rear earth metal, an alkali metal-containing compound, an alkaline earth metal-containing compound, a rear earth metal-containing compound, an alkali metal complex, an alkaline earth metal complex, a rear earth metal complex, or any combination thereof.

The alkali metal may include Li, Na, K, Rb, Cs, or any combination thereof. The alkaline earth metal may include, Mg, Ca, Sr, Ba, or any combination thereof. The rear earth metal may include Sc, Y, Ce, Tb, Yb, Gd, or any combination thereof.

The alkali metal-containing compound, the alkaline earth metal-containing compound, and the rear earth metal-containing compound may each include an oxide, halide (e.g., fluoride, chloride, bromide, and iodide), telluride, or any combination thereof of the alkali metal, alkaline earth metal, or rare earth metal, respectively.

The alkali metal-containing compound may include an alkali metal oxide, such as Li₂O, Cs₂O, and/or K₂O, an alkali metal halide, such as LiF, NaF, CsF, KF, LiI, NaI, CsI, and/or KI, or any combination thereof. The alkaline earth metal-containing compound may include an alkaline earth metal oxide, such as BaO, SrO, CaO, BaₓSr₁₋ₓO (where x is a real number satisfying 0<x<1), and/or BaₓCa₁₋ₓO (where x is a real number satisfying 0<x<1). The rear earth metal-containing compound may include YbF₃, ScF₃, Sc₂O₃, Y₂O₃, Ce₂O₃, GdF₃, TbF₃, YbI₃, ScI₃, TbI₃, or any combination thereof. In one or more embodiments, the rear earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth metal complex, and the rear earth metal complex may include i) one selected from among the ions of the alkali metal, the alkaline earth metal, and the rear earth metal as described in one or more embodiments, and ii) a ligand bound to the metal ion, such as hydroxyquinoline, hydroxyisoquinoline, hydroxybenzoquinoline, hydroxyacridine, hydroxylphenanthridine, hydroxyphenyl oxazole, hydroxyphenyl thiazole, hydroxyphenyl oxadiazole, hydroxyphenyl thiadiazole, hydroxyphenyl pyridine, hydroxyphenyl benzomidazole, hydroxyphenyl benzothiazole, bipyridine, phenanthroline, cyclopentadiene, or any combination thereof.

The electron injection layer may consist of (e.g., include) the alkali metal, the alkaline earth metal, the rear earth metal, the alkali metal-containing compound, the alkaline earth metal-containing compound, the rear earth metal-containing compound, the alkali metal complex, the alkaline earth metal complex, the rear earth metal complex, as described in one or more embodiments, or any combination thereof or may further include an organic material (e.g., the compound represented by Formula 601.

According to one or more embodiments, the electron injection layer may consist of (e.g., include) i) an alkali metal-containing compound (e.g., alkali metal halide), or ii) a) an alkali metal-containing compound (e.g., alkali metal halide); and b) an alkali metal, an alkaline earth metal, a rear earth metal, or any combination thereof. For example, the electron injection layer may be a co-deposited layer of KI:Yb, RbI:Yb, or LiF:Yb.

If (e.g., when) the electron injection layer further includes an organic compound, the alkali metal, alkaline earth metal, the rear earth metal, the alkali metal-containing compound, the alkaline earth metal-containing compound, the rear earth metal-containing compound, the alkali metal complex, the alkaline earth metal complex, the rear earth metal complex, or any combination thereof may be uniformly (e.g., substantially uniformly) or non-uniformly dispersed in a matrix including the organic material.

A thickness of the electron injection layer may be about 1 Å to about 100 Å, and for example, about 3 Å to about 90 Å. By adjusting or optimizing the thickness of the electron injection layer within the foregoing ranges, satisfactory or suitable electron injection characteristics may be obtained without a substantial increase in driving voltage.

### Second Electrode 150

The second electrode 150 may be disposed or provided on the electron transport region. The second electrode 150 may be a cathode serving as an electron injection electrode. In this regard, a material for the second electrode may be a metal, an alloy, or an electrically conductive compound having a low work function, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may include a transparent electrode, a semi-transparent electrode, or a reflective electrode.

The second electrode 150 may have a single-layer structure consisting of (e.g., including) a single layer or a multi-layer structure including a plurality of layers.

### Capping Layer

In one or more embodiments, the electronic device 10-1 may further include a capping layer disposed or provided on the outer side of the first electrode 110 and/or second electrode 150. The capping layer may include the quantum dot as described in one or more embodiments.

For example, the electronic device 10-1 may further include a first capping layer disposed or provided on the outer side of the first electrode 110. The first capping layer may include the quantum dot as described in one or more embodiments.

As another example, the electronic device 10-1 may further include a second capping layer disposed or provided on the outer side of the second electrode 150. The second capping layer may further include the quantum dot as described in one or more embodiments.

As another example, the electronic device 10-1 may further include the first capping layer disposed or provided on the outer side of the first electrode 110 and the second capping layer disposed or provided on the outer side of the second electrode 150. At least one selected from the first capping layer and the second capping layer may include the quantum dot as described in one or more embodiments.

Light generated in the emission layer of the electronic device 10-1 may be extracted to the outside through the first electrode 110, which is a semi-transparent electrode or a transparent electrode, and the first capping layer, and light generated in the emission layer of the electronic device 10-1 may be extracted to the outside through the second electrode 150, which is a semi-transparent electrode or a transparent electrode, and the second capping layer.

The first capping layer and the second capping layer may serve to enhance efficiency of light emission to the outside by the principle of constructive interference. As a result, light extraction efficiency of the electronic device 10-1 may be increased or enhanced, so that (e.g., such that) emission efficiency of the electronic device 10-1 may be improved or enhanced.

Each of the first capping layer and the second capping layer may include a material having a refractive index of about 1.2 or more (at 460 nm).

The first capping layer and the second capping layer may each independently be an organic capping layer including an organic material, an inorganic capping layer including an inorganic material, or an organic-inorganic composite capping layer including an organic material and an inorganic material.

At least one selected from the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. According to one or more embodiments, at least one selected from the first capping layer and the second capping layer may each independently include an amine group-containing compound.

For example, at least one selected from the first capping layer and the second capping layer may each independently include a compound represented by Formula 201, a compound represented by Formula 202, or any combination thereof.

According to one or more embodiments, at least one selected from the first capping layer and the second capping layer may each independently include one of Compounds HT28 to HT33, Compounds CP1 to CP6, β-NPB, or any combination thereof.

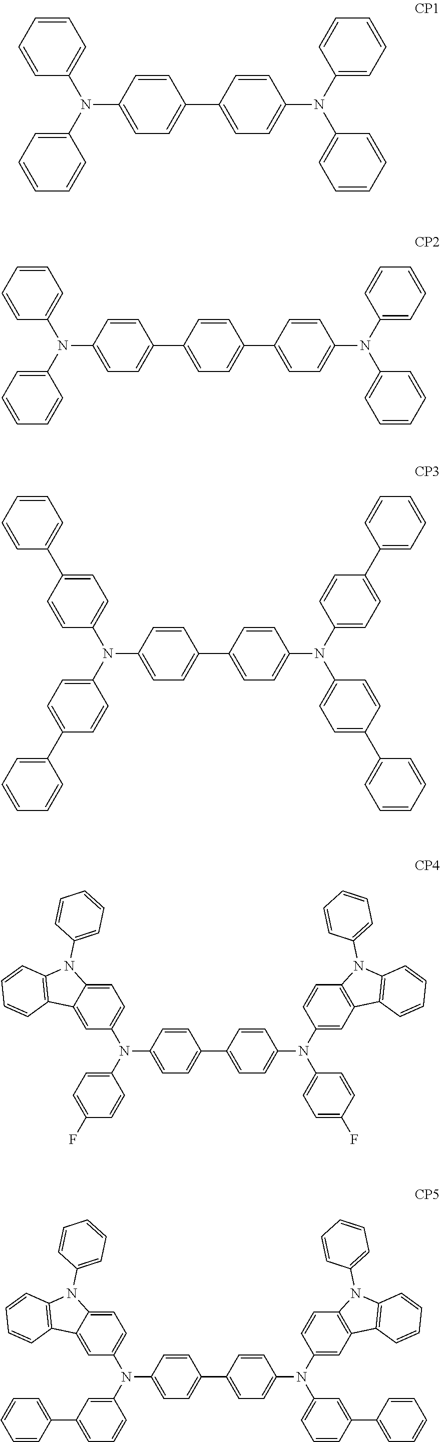 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

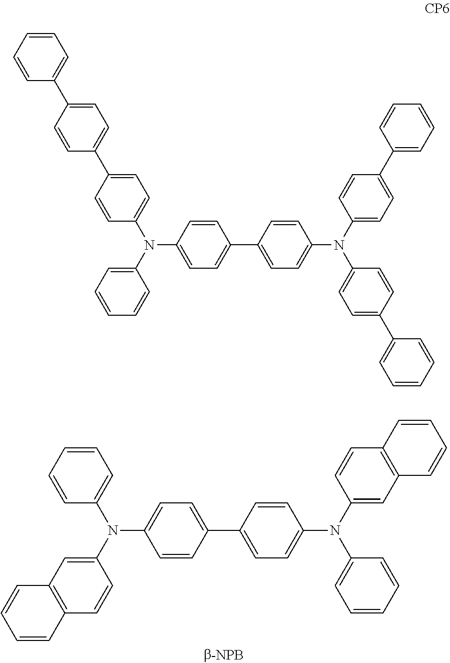

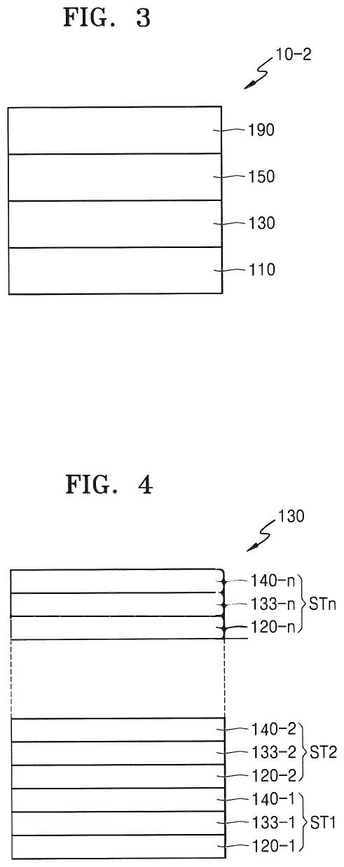

FIG. 3 is a schematic cross-sectional view of an electronic device 10-2 according to one or more embodiments.

Referring to FIG. 3, the electronic device 10-2 may further include a color conversion layer 190 in addition to the first electrode 110, the intermediate layer 130, and the second electrode 150. The first electrode 110, the intermediate layer 130, and the second electrode 150 are as described in one or more embodiments with reference to FIG. 2.

The color conversion layer 190 may be disposed or provided on the second electrode 150. For example, the color conversion layer 190 may be arranged or provided in at least one of progressing directions of light emitted from the emission layer as described in one or more embodiments. If (e.g., when) the electronic device 10-2 includes the second capping layer disposed or provided on the outer side of the second electrode 150 as described in one or more embodiments, the second capping layer may be disposed or provided between the second electrode 150 and the color conversion layer 190.

The color conversion layer 190 may absorb light emitted from the emission layer and emit light having a different wavelength from the wavelength of the absorbed light. For example, the color conversion layer 190 may convert the color of the absorbed light into the color of light to be emitted. For example, the color conversion layer 190 may absorb white light and emit color-converted red light, green light, or blue light.

In one or more embodiments, the electronic device 10-2 may further include a color filter, a touchscreen layer, a polarizing layer, or any combination thereof disposed or provided on the color conversion layer 190. According to one or more embodiments, the electronic device 10-2 may further include a color filter located or provided on the color conversion layer 190. If (e.g., when) the color conversion layer 190 converts a first color light into a second color light, the color filter may transmit the second color light among light incident on the color filter and may absorb or reflect light colors other than the second color light. For example, if (e.g., when) the color conversion layer 190 fails to convert one or more of the light of certain colors, the color filter may prevent colors from mixing (or reduce a degree to or occurrence of which colors mix) by blocking the unconverted light. If (e.g., when) the unconverted light is reflected to the color conversion layer 190, color conversion efficiency may be increased or enhanced.

According to one or more embodiments, the color conversion layer 190 may include the quantum dot as described in one or more embodiments. For example, the color conversion layer 190 may be a layer formed or provided by utilizing the quantum dot composition as described in one or more embodiments. In this case, the color conversion layer 190 maty be formed or provided by an inkjet process. The color conversion layer 190 may further include a scatterer (e.g., a light scatterer).

FIG. 4 is a cross-sectional view schematically illustrating an intermediate layer included in an electronic device according to one or more embodiments.

Referring to FIGS. 2 to 4, the intermediate layer 130 included in the electronic devices 10-1 and 10-2 may include a plurality of stacks, so that (e.g., such that) the light-emitting element as described in one or more embodiments may be the tandem light-emitting element as described in one or more embodiments. The plurality of stacks may include a first stack ST1, a second stack ST2, and a n^{th} stack STn. For example, if (e.g., when) n is 3, the electronic devices 10-1 and 10-2 may include three layers of stacks. As another example, if (e.g., when) n is 4, the electronic devices 10-1 and 10-2 may include four layers of stacks. As another example, if (e.g., when) n is 5, the electronic devices 10-1 and 10-2 may include five layers of stacks.

In one or more embodiments, a charge generation layer may be disposed or provided between the stacks. The charge generation layer may include a negative type or kind (n-type or kind) charge generation layer adjacent to the first electrode 110 and a positive type or kind (p-type or kind) charge generation layer adjacent to the second electrode 150.

Each of the stacks may include a hole transport region, an emissive layer, and an electron transport region that are sequentially disposed or provided on the first electrode 110. Referring to FIG. 4, the first stack ST1 may include a first hole transport region 120-1, a first emission layer 133-1, and a first electron transport region 140-1, disposed or provided in the order closer to the first electrode 110, the second stack ST2 may include a second hole transport region 120-2, a second emission layer 133-2, and second electron transport region 140-2, disposed or provided in the order closer to the first electrode 110, and the n^{th} stack STn may include an n^{th} hole transport region 120-n, an n^{th} emission layer 133-n, and an n^{th} electron transport region 140-n, disposed or provided in the order closer to the first electrode 110. For descriptions of the first hole transport region 120-1 to the n^{th} hole transport region 120-n, refer to the description of the hole transport region as described in one or more embodiments, respectively. For descriptions of each of the first emission layer 133-1 to the n^{th} emission layer 133-n, refer to the description of the emission layer as described in one or more embodiments. For descriptions of each of the first electron transport region 140-1 to the n^{th} electron transport region 140-n, refer to the description of the electron transport region as described in one or more embodiments.

For example, in FIG. 4, n may be 3, and each of the first emission layer 133-1 to a third emission layer 133-3 may emit blue light.

As another example, in FIG. 4, n may be 4, and the first emission layer 133-1 may emit blue light, the second emission layer 133-2 may emit blue light, a third emission layer 133-3 emit blue light, and a fourth emission layer 133-4 may emit green light.

As another example, in FIG. 4, n may be 5, and the first emission layer 133-1 may emit blue light, the second emission layer 133-2 may emit blue light, a third emission layer 133-3 emit green light, a fourth emission layer 133-4 may emit blue light, and a fifth emission layer 133-5 may emit green light.

Mixed light of the lights emitted from the first emission layer 133-1, the second emission layer 133-2, and the n^{th} emission layer 133-n may be incident on the color conversion layer 190.

The electronic device according to one or more embodiments may be a display device, an authentication device, and/or the like. The electronic device may include a plurality of light-emitting elements. For example, the electronic device may include a first substrate, and the first substrate may have a plurality of sub-pixel regions. The electronic device may include a first light-emitting element located or provided in a first sub-pixel region, a second light-emitting element located or provided in a second sub-pixel region, and a third light-emitting element located or provided in a third sub-pixel region, and the first light-emitting element to the third light-emitting element may each independently be the light-emitting element as described in one or more embodiments. A pixel-defining film may be arranged or provided between the plurality of sub-pixel regions to define each of the sub-pixel regions.

The first sub-pixel region may emit a first-1 color light, and the first-1 color light may be light emitted by the emission layer included in the first light-emitting element or light converted by the color conversion layer included in the first light-emitting element.

The second sub-pixel region may emit a first-2 color light, and the first-2 color light may be light emitted by the emission layer included in the second light-emitting element or light converted by the color conversion layer included in the second light-emitting element.

The third sub-pixel region may emit a first-3 color light, and the first-3 color light may be light emitted by the emission layer included in the third light-emitting element or light converted by the color conversion layer included in the third light-emitting element.

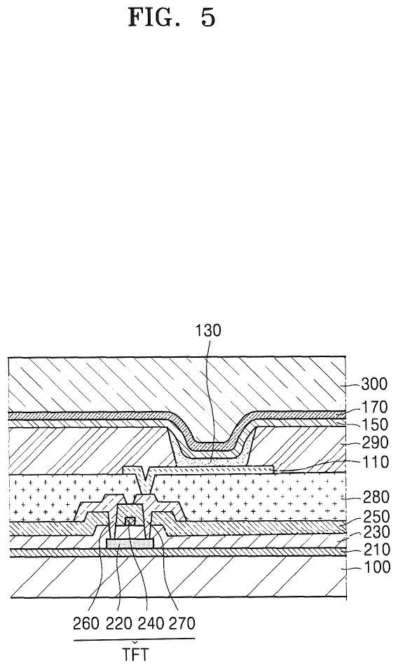

FIG. 5 is a cross-sectional view schematically illustrating an electronic device according to one or more embodiments.

Referring to FIG. 5, the electronic device may include a substrate 100, a thin film transistor TFT, a first electrode 110, an intermediate layer 130, a second electrode 150, and an encapsulation region 300.

The substrate 100 may be a flexible substrate, a glass substrate, and/or a metal substrate. A buffer layer 210 may be disposed or provided on the substrate 100. The buffer layer 210 may serve to prevent penetration of impurities through the substrate 100 (or to reduce a degree or occurrence of penetration of impurities through the substrate 100) and provide a planar surface on the upper side of the substrate 100.

A thin film transistor TFT may be disposed or provided on a buffer layer 210. The thin film transistor TFT may include an active layer 220, a gate electrode 240, a source electrode 260, and a drain electrode 270.

The active layer 220 may include an inorganic semiconductor, such as silicon and/or polysilicon, an organic semiconductor, and/or an oxide semiconductor, and may include a source region, a drain region, and a channel region.

A gate insulating layer 230 may be disposed or provided on top of the active layer 220 to insulate (e.g., to electrically insulate) the active layer 220 from the gate electrode 240, and the gate electrode 240 may be disposed or provided on the gate insulating layer 230.

An interlayer insulating layer 250 may be disposed or provided on the gate electrode 240. The interlayer insulating layer 250 may be located or provided between the gate electrode 240 and the source electrode 260 and between the gate electrode 240 and the drain electrode 270, serving to insulate (e.g., to electrically insulate) them from each other.

The source electrode 260 and the drain electrode 270 may be disposed or provided on the interlayer insulating layer 250. The interlayer insulating layer 250 and the gate insulating layer 230 may be formed or provided to expose the source region and the drain region of the active layer 220, and the source electrode 260 and the drain electrode 270 may be disposed or provided to contact the exposed source region and drain region of the active layer 220.

The thin film transistor TFT may be electrically connected to the first electrode 110 and transmit signals thereto and may be protected by a passivation layer 280. The passivation layer 280 may include an inorganic insulating (e.g., electrically insulating) film, an organic insulating (e.g., electrically insulating) film, or any combination thereof 10. The first electrode 110 may be disposed or provided on the passivation layer 280.

According to one or more embodiments, the electronic device may further include: a backlight disposed or provided below the thin film transistor TFT; and a performance improvement layer disposed or provided between the backlight and the thin film transistor TFT. For example, the backlight may be disposed or provided below the substrate 100 and the performance improvement layer may be disposed or provided between the backlight and the substrate 100. If (e.g., when) the electronic device includes the backlight, the intermediate layer 130 as described in one or more embodiments may also be referred to as a liquid crystal layer including liquid crystals.

The backlight may emit light toward the substrate 100. The backlight may emit blue light.

The performance improvement layer may improve or enhance color purity of light emitted by the backlight. For example, the performance improvement layer may emit light of a specific (e.g., set or predetermined) wavelength by absorbing light emitted from the backlight.

According to one or more embodiments, the performance improvement layer may include the quantum dot as described in one or more embodiments.

The first electrode 110 may be disposed or provided on the passivation layer 280. The passivation layer 280 may be arranged or provided not to cover the entire area of the drain electrode 270 but to expose a certain (e.g., set or predetermined) area, and the first electrode 110 may be arranged or provided to be connected to the exposed drain electrode 270.

A pixel-defining film 290 including an insulating (e.g., electrically insulating) material may be disposed or provided on the first electrode 110. The pixel-defining film 290 may expose a certain (e.g., set or predetermined) area of the first electrode 110, and an intermediate layer 130 may be formed or provided in the exposed area. The pixel-defining film 290 may be an organic film formed or composed of polyimide and/or polyacrylate. In one or more embodiments, at least one or more layers of the intermediate layer 130 may extend over the pixel-defining film 290 to be arranged or provided in the form of a common layer.

A second electrode 150 may be disposed or provided on the intermediate layer 130, and a capping layer 170 may further be formed or provided on the second electrode 150. The capping layer 170 may be formed or provided to cover the second electrode 150.

An encapsulation region 300 may be disposed or provided on the capping layer 170. The encapsulation region 300 may be disposed or provided on the second electrode 150, serving to protect components disposed or provided under the encapsulation region 300 from moisture and/or oxygen. The encapsulation region 300 may include an inorganic layer including silicon nitride (e.g., SiNₓ, wherein 0<x≤2; e.g., Si₃N₄), silicon oxide (e.g., SiO_{X}, wherein 0<x≤2; e.g., SiO₂), indium tin oxide, indium zinc oxide, or any combination thereof, an organic layer including polyethylene terephthalate, polyethylene naphthalate, polycarbonate, polyimide, polyethylene sulfonate, polyoxymethylene, polyarylate, hexamethyldisiloxane, and/or an acrylic resin (e.g., polymethyl methacrylate and/or polyacrylic acid), an epoxy resin (e.g., aliphatic glycidyl ether (AGE)), or any combination thereof, or a combination of the inorganic layer and the organic layer.

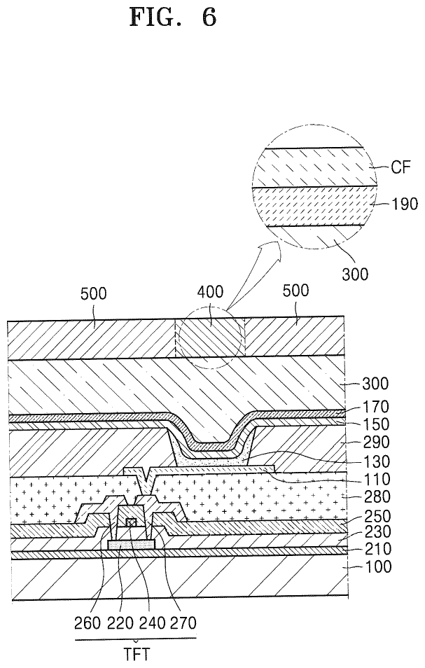

FIG. 6 is a cross-sectional view schematically illustrating an electronic device according to one or more embodiments.

The electronic device of FIG. 6 may be substantially the same electronic device as illustrated in FIG. 5, except that a functional region 400 and a light-shielding pattern 500 are additionally disposed or provided on the encapsulation region 300. The functional region 400 may include a color conversion layer 190 and a color filter CF. According to one or more embodiments, the color conversion layer 190 may be disposed or provided on the encapsulation region 300, and the color filter CF may be disposed or provided on the color conversion layer 190. The electronic device of FIG. 6 may include the tandem light-emitting element as described in one or more embodiments.

The light-shielding pattern 500 may prevent transmission of light (or reduce a degree or occurrence of transmission of light). For example, the light-shielding pattern 500 may absorb or reflect light emitted from the emission layer or converted by the color conversion layer.

In the electronic device of FIG. 6, the quantum dot according to one or more embodiments may be included in the color conversion layer 190. The color conversion layer 190 may be a layer formed or provided by utilizing the quantum dot composition as described in one or more embodiments. The quantum dot included in the color conversion layer 190 may absorb light emitted from the emission layer included in the intermediate layer 130, convert wavelength of the light, and emit the converted light. For example, the quantum dot included in the color conversion layer 190 may absorb mixed light of lights respectively emitted from the first emission layer 133-1 to the n^{th} emission layer 133-n, convert the color of the mixed light, and emit the converted light.

The light-shielding pattern 500 may prevent transmission of mixed light (or unconverted light) (or reduce a degree or occurrence of transmission of mixed light (or unconverted light)). The color filter CF may transmit only light whose color has been converted from the mixed light, while absorbing or reflecting the mixed light (or unconverted light). For example, the mixed light of lights emitted by the first emission layer 133-1 to the n^{th} emission layer 133-n, respectively, may be the first color light, the quantum dot included in the color conversion layer 190 may absorb the first color light and convert the first color light into the second color light having a different maximum emission wavelength from the maximum emission wavelength of the first color light, the light-shielding pattern 500 may prevent transmission of the first color light (or reduce a degree or occurrence of transmission of the first color light), and the color filter CF may transmit only the second color light while absorbing or blocking light other than the second color light.

### Manufacturing Method

Each of layers included in the hole transport regions 120-1, 120-2, and 120-n, the emission layers 133-1, 133-2, and 133-n, the electron transport regions 140-1, 140-2, 140-n, the performance improvement layer, and the color conversion layer 190 may be formed or provided in certain (e.g., set or predetermined) areas by utilizing one or more suitable methods, such as vacuum deposition, spin coating, casting, Langmuir-Blodgett (LB) method, inkjet printing, laser printing, and/or laser induced thermal imaging (LITI).

If (e.g., when) each of layers included in the hole transport regions 120-1, 120-2, and 120-n, the emission layers 133-1, 133-2, and 133-n, the electron transport regions 140-1, 140-2, 140-n, the performance improvement layer, and the color conversion layer 190 is formed or provided by vacuum deposition, deposition conditions may be selected from, for examples, deposition temperature of about 100° C. to about 500° C., vacuum pressure of about 10⁻⁸ torr to about 10⁻³ torr, and deposition speed of about 0.01 Å/sec to about 100 Å/sec, in consideration of materials included in layers to be formed or provided and structures of layers to be formed or provided.

For example, the layers including the quantum dot as described in one or more embodiments (e.g., emission layer, performance improvement layer, or color conversion layer) may be formed or provided by inkjet printing.

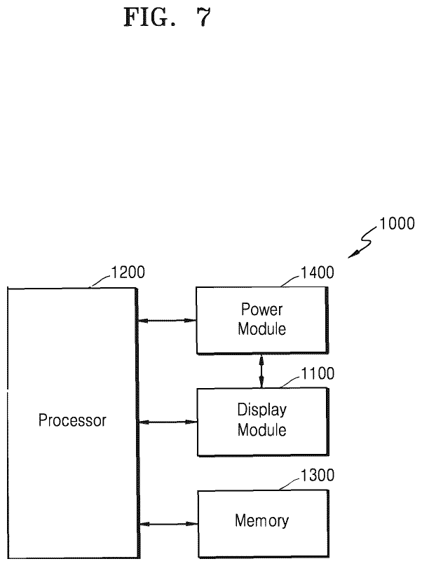

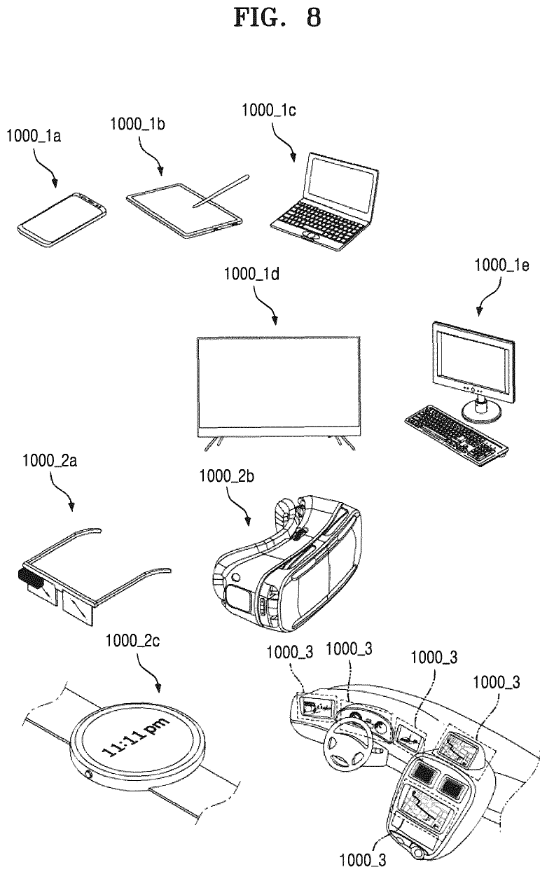

### Descriptions for FIGS. 7 and 8

FIG. 7 is a block diagram of an electronic apparatus including an electronic device according to one or more embodiments.

The electronic devices 10-1 and 10-2 according to one or more embodiments may be applied to one or more suitable electronic apparatuses 1000. The electronic apparatus 1000 according to one or more embodiments may include the electronic device as described in one or more embodiments and may further include a module or a device having other additional functions in addition to the electronic device. For example, the electronic apparatus 1000 may further include at least one selected from among a processor, a memory, and a power module, in addition to the electronic device as described in one or more embodiments.

Referring to FIG. 7, the electronic apparatus 1000 according to one or more embodiments may include a display module 1100, a processor 1200, a memory 1300, and a power module 1400.

The display module 1100 may display an image, such as a moving image and/or a still image, by emitting light and may include, for example, the electronic device as described in one or more embodiments.

The processor 1200 may transmit a signal required or desired for operation of the electronic device as described in one or more embodiments. The processor 1200 may include at least one selected from among a central processing unit (CPU), an application processor (AP), a graphic processing unit (GPU), a communication processor (CP), an image signal processor (ISP), and a controller.

The memory 1300 may store data information required or desired for operation of the processor 1200 or the display module 1100. Upon execution of an application stored in the memory 1300 by the processor 1200, image data signals and/or input control signals may be transmitted to the display module 1100, and the display module 1100 may be configured or provided to process the received signals and output image information via a display screen.

The power module 1400 may supply power required or desired for operation of the electronic device as described in one or more embodiments. The power module 1400 may include a power supply module, such as a power adapter and/or a battery device, and a power conversion module configured or provided to convert the power supplied by the power supply module to generate power required or desired for the operation of the electronic apparatus 1000.

At least one selected from among the components of the electronic apparatus 1000 as described in one or more embodiments may be included in the electronic device according to one or more embodiments described herein. In one or more embodiments, one or more of the individual modules functionally included in a single module may be included in the electronic device, and others may be provided separately from the electronic device. For example, the electronic device may include the display module 1100, and the processor 1200, the memory 1300, and the power module 1400 may be provided in the form of other devices in the electronic apparatus 1000 other than the electronic device.

According to one or more embodiments, the electronic apparatus 1000 may be one selected from among a flat panel display, a curved display, a computer monitor, a medical monitor, a television, a billboard, indoor lighting, outdoor lighting, signaling lights, a head-up display, a fully transparent display, a partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle instrument cluster, a vehicle center information display (CID), a vehicle head-up display, a room mirror display, a video wall, theater screen or stadium screen including one or more displays tiled together, a light therapy device, and a signage.

FIG. 8 is a schematic diagram of electronic apparatuses 1000 according to one or more embodiments.

Referring to FIG. 8, one or more suitable types or kinds of electronic apparatuses 1000 to which the electronic device according to one or more embodiments is applied may include not only image display electronic apparatuses, such as smartphones 1000_1a, tablet PCs 1000_1b, laptop computers 1000_1c, TVs 1000_1d, and/or desktop monitors 1000_1e, but also wearable electronic apparatuses including a display module, such as smart glasses 1000_2a, head-mounted displays 1000_2b, and/or smartwatches 1000_2c, and vehicle electronic apparatuses 1000_3 including a display module, such as instrument clusters, information displays (CID) placed or provided in the center fascia and dashboard, and/or room mirror displays.

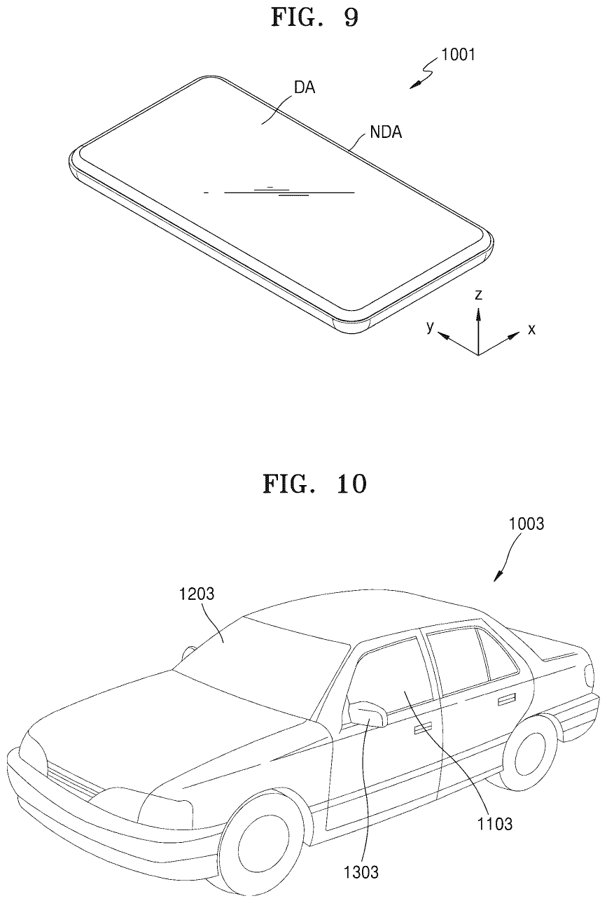

### Descriptions of FIG. 9

FIG. 9 is a schematic perspective view of an electronic apparatus 1001 including the electronic device 10-1 or 10-2 according to one or more embodiments. The electronic apparatus 1001, as an apparatus utilized to display moving images and/or still image, may be utilized not only as portable electronic apparatuses, such as mobile phones, smart phones, tablet personal computers (PCs), mobile communication terminals, electronic notebooks, electronic books, portable multimedia players (PMPs), navigation devices, and/or ultra mobile PCs (UMPCs), but also as one or more suitable products, such as televisions, laptops, monitors, billboards, and/or internet of things (IOT), or a part thereof. In one or more embodiments, the electronic apparatus 1001 may be a wearable device, such as a smart watch, a watch phone, a glasses type or kind display, and/or a head mounted display (HMD), or a part thereof. However, embodiments of the present disclosure are not limited thereto. For example, the electronic apparatus 1001 may be instrument panels, a center information display disposed or provided on center fascia or dashboards of vehicles, a room mirror display that replaces side mirrors, a device for entertainment of backseats of vehicles, a display disposed or provided on the rear surface of front seats, a head-up display (HUD) installed at the front of a vehicle or projected onto the front windshield glass, or a computer-generated hologram augmented reality head-up display (CGH AR HUD). FIG. 9 illustrates a case where the electronic apparatus 1001 is a smartphone for the convenience of description.

The electronic apparatus 1001 may have a display area DA and a non-display area NDA disposed or provided outside the display area DA. The electronic apparatus 1001 may realize an image by an array of a plurality of pixels two-dimensionally arranged or provided in the display area DA.

The non-display area NDA may be an area that does not display an image and may be around (e.g., surround) the entire display area DA. A driver and other components configured or provided to provide electrical signals or power to the display elements arranged or provided in the display area DA may be arranged or provided in the non-display area NDA. Pads, which are areas electrically connected to electronic elements or printed circuit boards, may be arranged or provided in the non-display area NDA.

The electronic apparatus 1001 may have different lengths in the x-axis direction and the y-axis direction. For example, as illustrated in FIG. 5, the length in the x-axis direction may be shorter than the length in the y-axis direction. As another example, the length in the x-axis direction may be substantially the same as the length in the y-axis direction. As another example, the length in the x-axis direction may be longer than the length in the y-axis direction.

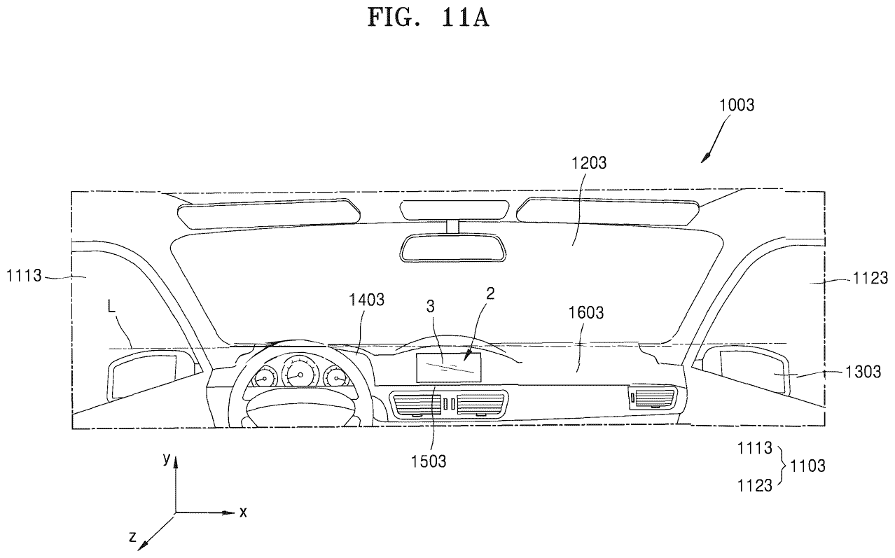

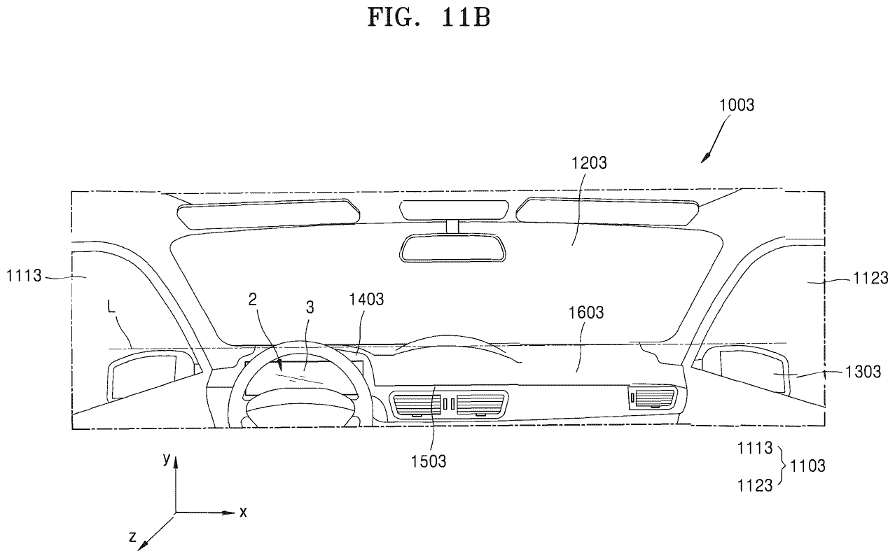

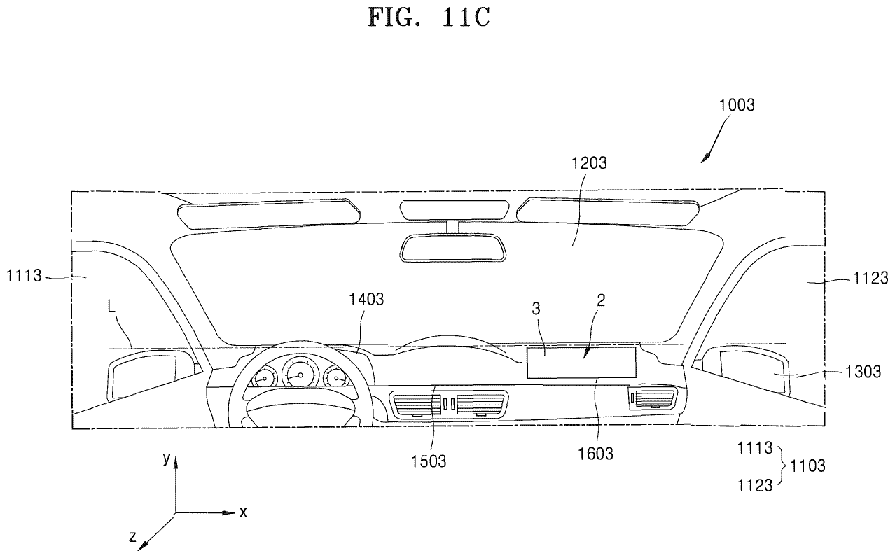

### Descriptions for FIGS. 10 and 11A to 11C

FIG. 10 is a diagram schematically illustrating the exterior of a vehicle 1003 as an electronic apparatus including an electronic device 10-1 or 10-2 according to one or more embodiments. FIGS. 11A to 11C are diagrams schematically illustrating the interior of the vehicle 1003 according to one or more embodiments.

Referring to FIGS. 10, 11A, 11B, and 11C, the vehicle 1003 may refer to one or more suitable apparatuses that transport passengers, goods, and/or animals from a starting point to a destination. The vehicle 1003 may include cars that travel on rods or tracks, ships that travel seas or rivers, and airplanes that fly through the air using the force of the air.

The vehicle 1003 may travel on roads or tracks. The vehicle 1003 may move in a certain (e.g., set or predetermined) direction depending on rotation of at least one wheel. For example, the vehicle 1003 may include three-wheeled or four-wheeled cars, construction machinery, motorcycles, moto devices, bicycles, and/or trains traveling on tracks.

The vehicle 1003 may include a body having an interior and an exterior, and a chassis including mechanical devices required or desired for driving, excluding the body. The exterior of the body may include a front panel, a bonnet, a roof panel, a rear panel, a trunk, and a pillar provided at the boundaries between the doors. The chassis of the vehicle 1003 may include a power generation device, a power transmission device, a driving device, a steering device, a braking device, a suspension device, a transmission device, a fuel device, and wheels on all sides.

The vehicle 1003 may include side window glass 1103, front window glass 1203, side mirrors 1303, a cluster 1403, a center fascia 1503, a passenger side dashboard 1603, and a display device 2.

The side window glass 1103 and the front window glass 1203 may be separated by a pillar arranged or provided between the side window glass 1103 and the front window glass 1203.

The side window glass 1103 may be installed on sides of the vehicle 1003. In one or more embodiments, the side window glass 1103 may be installed on the doors of the vehicle 1003. The side window glass 1103 may be provided in two or more suitable pieces being opposite to (e.g., facing) each other. In one or more embodiments, the side window glass 1103 may include a first side window glass 1113 and a second side window glass 1123. In one or more embodiments, the first side window glass 1113 may be arranged or provided adjacent to the cluster 1403. The second side window glass 1123 may be arranged or provided adjacent to the passenger side dashboard 1603.

In one or more embodiments, the side window glasses 1103 may be spaced and/or apart (e.g., spaced apart or separated) from each other in the x direction or −x direction. For example, the first side window glass 1113 and the second side window glass 1123 may be spaced and/or apart (e.g., spaced apart or separated) from each other in the x direction or −x direction. For example, a virtual straight line L connecting the side window glasses 1103 may extend in the x direction or −x direction. For example, the virtual straight line L connecting the first side window glass 1113 and the second side window glass 1123 may extend in the x direction or −x direction.

The front window glass 1203 may be installed at the front of the vehicle 1003. The front window glass 1203 may be located or provided between the side window glasses 1103 being opposite to (e.g., facing) each other.

The side mirrors 1303 may provide a view of the rear of the vehicle 1003. The side mirrors 1303 may be installed on the exterior of the body. In one or more embodiments, the side mirrors 1303 may be provided in plural. One of the plurality of side mirrors 1303 may be located or provided on the outside of the first side window glass 1113. Another of the plurality of side mirrors 1303 may be located or provided on the outside of the second side window glass 1123.

The cluster 1403 may be located or provided in front of a steering wheel. The cluster 1403 may include a tachometer, a speedometer, a coolant temperature gauge, a fuel gauge, a direction indicator, a high beam indicator, a warning light, a seatbelt warning light, an odometer, a trip meter, an automatic transmission shift lever indicator, a door open warning light, an engine oil warning light, and/or a low fuel warning light.

The center fascia 1503 may include a control panel having a plurality of buttons arranged or provided to adjust an audio device, an air conditioning system, and a seat heater. The center fascia 1503 may be located or provided on one side of the cluster 1403.

The passenger side dashboard 1603 may be spaced and/or apart (e.g., spaced apart or separated) from the cluster 1403, with the center fascia 1503 therebetween. In one or more embodiments, the cluster 1403 may be positioned or provided to correspond to the driver's side, and the passenger side dashboard 1603 may be positioned or provided to correspond to the passenger's side. In one or more embodiments, the cluster 1403 may be adjacent to the first side window glass 1113, and the passenger side dashboard 1603 may be adjacent to the second side window glass 1123.

In one or more embodiments, the display device 2 may include a display panel 3, and the display panel 3 may display an image. The display device 2 may be located or provided inside the vehicle 1003. In one or more embodiments, the display device 2 may be located or provided between the side window glasses 1103 being opposite to (e.g., facing) each other. The display device 2 may be positioned or provided on at least one of the cluster 1403, the center fascia 1503, or the passenger side dashboard 1603.

The display device 2 may include an organic light emitting display, an inorganic light emitting display, a quantum dot display, and/or the like.

Referring to FIG. 11A, the display device 2 may be located or provided on the center fascia 1503. In one or more embodiments, the display device 2 may display navigation information. In one or more embodiments, the display device 2 may display information related to audios, videos, and/or vehicle settings.

Referring to FIG. 11B, the display device 2 may be located or provided on the cluster 1403. In this case, the cluster 1403 may represent driving information and/or the like via the display device 2. For example, the cluster 1403 may be implemented in a digital format. The digital cluster 1403 may display vehicle information and driving information as images. For example, the needle of the tachometer, the gauge, and one or more suitable warning light icons may be displayed utilizing digital signals.

Referring to FIG. 11C, the display device 2 may be located or provided on the passenger side dashboard 1603. The display device 2 may be embedded in or located or provided on the passenger side dashboard 1603. In one or more embodiments, the display device 2 located or provided on the passenger side dashboard 1603 may display images related to the information shown on the cluster 1403 and/or the center fascia 1503. In one or more embodiments, the display device 2 located or provided on the passenger side dashboard 1603 may display information different from information displayed on the cluster 1403 and/or the center fascia 1503.

### Definition of Terms

As used herein, the C₃-C₆₀ carbocyclic group refers to a cyclic group having 3 to 60 carbon atoms, in which only carbon atoms are used as ring-forming atoms.

The C₁-C₆₀ heterocyclic group refers to a cyclic group having 1 to 60 carbon atoms, in which not only carbon atoms but also a hetero atoms are used as ring-forming atoms.

Each of the C₃-C₆₀ carbocyclic group and the C₁-C₆₀ heterocyclic group may be a monocyclic group formed of one ring or a polycyclic group formed of two or more rings fused together. For example, the number of the ring-forming atoms of the C₁-C₆₀ heterocyclic group may be 3 to 61.

As used herein, the cyclic group includes both the C₃-C₆₀ carbocyclic group and the C₁-C₆₀ heterocyclic group.

As used herein, the π electron-rich C₃-C₆₀ cyclic group is a ring-forming moiety and refers to a cyclic group having 3 to 60 carbon atoms and not including *—N═*′.

As used herein, the π electron-deficient nitrogen-containing C₁-C₆₀ heterocyclic group is a ring-forming moiety and refers to a heterocyclic group having 1 to 60 carbon atoms and including *—N═*′.

For example,
the C₃-C₆₀ carbocyclic group may be i) group T1 or ii) a condensed ring group in which 2 or more group T1s are condensed (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group) and,
the C₁-C₆₀ heterocyclic group may be i) group T2, ii) a condensed ring group in which 2 or more group T2s are condensed, or iii) a condensed ring group in which 1 or more group T2s and 1 or more group T1s are condensed (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group, or a xanthene group).

The π electron-rich C₃-C₆₀ cyclic group may be i) group T1, ii) a condensed ring in which 2 or more group T1s are condensed, iii) group T3, iv) a condensed ring in which 2 or more group T3s are condensed, or v) a condensed ring in which 1 or more group T3s and 1 or more group T1s are condensed (e.g., the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, or a benzothienodibenzothiophene group).

The π electron-deficient nitrogen-containing C₁-C₆₀ heterocyclic group may be i) group T4, ii) a condensed ring in which 2 or more group T4s are condensed, iii) a condensed ring in which 1 or more group T4s and 1 or more group T1 s are condensed, iv) a condensed ring in which 1 or more group T4s and 1 or more group T3s are condensed, or v) a condensed ring in which 1 or more group T4s, 1 or more group T1s, and 1 or more group T3s are condensed (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group).

The group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane group), a norbornene group, a bicyclo[1.1.1]pentane group, a bicyclo[2.1.1]hexane group, a bicyclo[2.2.2]octane group, or a benzene group.

The group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

The group T3 may be a furan group, a thiophene group, a 1H-pyrrole group, a silole group, or a borole group.

The group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

As used herein, the terms cyclic group, C₃-C₆₀ carbocyclic group, C₁-C₆₀ heterocyclic group, π electron-rich C₃-C₆₀ cyclic group, or π electron-deficient nitrogen-containing C₁-C₆₀ heterocyclic group may be i) a group condensed to any cyclic group, ii) a monovalent group, or iii) a polyvalent group (e.g., divalent group, trivalent group, and tetravalent group) according to structures of formular in which the term is used.

For example, the “benzene group” may be a benzo group, a phenyl group, a phenylene group, and/or the like, which may be easily understood by those skilled in the art depending on a structure of a chemical formula including the “benzene group.”

For example, examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and/or a monovalent non-aromatic condensed heteropolycyclic group.

Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and/or a divalent non-aromatic condensed heteropolycyclic group.

As used herein, the C₁-C₆₀ alkyl group refers to a linear or branched monovalent aliphatic hydrocarbon group including 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and/or a tert-decyl group.

As used herein, the C₁-C₆₀ alkylene group refers to a divalent group having the same structure as that of the C₁-C₆₀ alkyl group.

As used herein, the C₂-C₆₀ alkenyl group refers to a monovalent hydrocarbon group including at least one carbon-carbon double bond in the middle or at a terminal of the C₂-C₆₀ alkyl group, and examples thereof may include an ethenyl group, a propenyl group, and/or a butenyl group.

As used herein, the C₂-C₆₀ alkenylene group refers to a divalent group having the same structure as that of the C₂-C₆₀ alkenyl group.

As used herein, the C₂-C₆₀ alkynyl group refers to a monovalent hydrocarbon group including at least one carbon-carbon triple bond in the middle or at a terminal of the C₂-C₆₀ alkyl group, and examples thereof may include an ethynyl group and/or a propynyl group.

As used herein, the C₂-C₆₀ alkynylene group refers to a divalent group having the same structure as that of the C₂-C₆₀ alkynyl group.

As used herein, the C₁-C₆₀ alkoxy group refers to a monovalent group having a chemical formula of —OA₁₀₁ (where the A₁₀₁ is the C₁-C₆₀ alkyl group), and examples thereof may include a methoxy group, an ethoxy group, and/or an isopropyloxy group.

As used herein, the C₃-C₁₀ cycloalkyl group refers to a monovalent saturated hydrocarbon cyclic group containing 3 to 10 carbon atoms, and examples thereof may include cyclopropyl group, a cyclobutyl group, a cyclopentyl group, a cyclohexyl group, a cycloheptyl group, a cyclooctyl group, an adamantanyl group, a norbornanyl group (or, bicyclo[2.2.1]heptyl), bicyclo[1.1.1]pentyl, bicyclo[2.1.1]hexyl, and/or bicyclo[2.2.2]octyl group.

As used herein, the C₃-C₁₀ cycloalkylene group refers to a divalent group having the same structure as that of the C₃-C₁₀ cycloalkyl group.

As used herein, the C₁-C₁₀ heterocycloalkyl group refers to a monovalent cyclic group containing 1 to 10 carbon atoms and further including at least one hetero atom, as a ring-forming atom, and examples thereof may include a 1,2,3,4-oxatriazolidinyl group, a tetrahydrofuranyl group, and/or a tetrahydrothiophenyl group.

As used herein, the C₁-C₁₀ heterocycloalkylene group refers to a divalent group having the same structure as that of the C₁-C₁₀ heterocycloalkyl group.

As used herein, the C₃-C₁₀ cycloalkenyl group refers to a monovalent cyclic group containing 3 to 10 carbon atoms and including at least one carbon-carbon double bond within the ring without aromaticity, and examples thereof may include a cyclopentenyl group, a cyclohexenyl group, and/or a cycloheptenyl group.

As used herein, the C₃-C₁₀ cycloalkenylene group refers to a divalent group having the same structure as that of the C₃-C₁₀ cycloalkenyl group.

As used herein, the C₁-C₁₀ heterocycloalkenyl group refers to a monovalent cyclic group containing 1 to 10 carbon atoms and further including at least one hetero atom, as a ring-forming atom, in addition to carbon atoms with at least one double bond within the ring. Examples of the C₁-C₁₀ heterocycloalkenyl group may include 4,5-dihydro-1,2,3,4-oxatriazolyl group, a 2,3-dihydrofuranyl group, and/or a 2,3-dihydrothiophenyl group.

As used herein, the C₁-C₁₀ heterocycloalkenylene group refers to a divalent group having the same structure as that of the C₁-C₁₀ heterocycloalkenyl group.

As used herein, the C₆-C₆₀ aryl group refers to a monovalent group having a carbocyclic aromatic system containing 6 to 60 carbon atoms.

The C₆-C₆₀ arylene group refers to a divalent group having a carbocyclic aromatic system containing 6 to 60 carbon atoms.

Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and/or an ovalenyl group.

If (e.g., when) the C₆-C₆₀ aryl group and the C₆-C₆₀ arylene group include two or more rings, the two or more rings may be condensed with each other.

As used herein, the C₁-C₆₀ heteroaryl group refers to a monovalent group having a heterocyclic aromatic system containing 1 to 60 carbon atoms and further including at least one hetero atom, as a ring-forming atom, in addition to carbon atoms.

The C₁-C₆₀ heteroarylene group refers to a divalent group having a heterocyclic aromatic system containing 1 to 60 carbon atoms and further including at least one hetero atom, as a ring-forming atom in addition to carbon atoms.

Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and/or a naphthyridinyl group.

If (e.g., when) the C₁-C₆₀ heteroaryl group and the C₁-C₆₀ heteroarylene group include two or more rings, the two or more rings may be condensed with each other.

As used herein, the monovalent non-aromatic condensed polycyclic group refers to a monovalent group containing only carbon atoms (e.g., 8 to 60 carbon atoms), as ring-forming atoms, and having non-aromaticity in which two or more rings are condensed with each other. Examples of the monovalent non-aromatic condensed polycyclic group may include an indenyl group, a fluorenyl group, a spiro-bifluorenyl group, a benzofluorenyl group, an indenophenanthrenyl group, and/or an indenoanthracenyl group.

As used herein, the divalent non-aromatic condensed polycyclic group refers to a divalent group having the same structure as that of the monovalent non-aromatic condensed polycyclic group.

As used herein, the monovalent non-aromatic condensed heteropolycyclic group refers to a monovalent group (e.g., including 1 to 60 carbon atoms) and at least one hetero atom, as a ring-forming atom in addition to carbon atoms with non-aromaticity in which two or more rings are condensed with each other. Example of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and/or a benzothienodibenzothiophenyl group.

As used herein, the divalent non-aromatic condensed heteropolycyclic group refers to a divalent group having the same structure as that of the monovalent non-aromatic condensed heteropolycyclic group.

As used herein, the C₆-C₆₀ aryloxy group is —OA₁₀₂ (wherein A₁₀₂ is the C₆-C₆₀ aryl group).

The C₆-C₆₀ arylthio group is —SA₁₀₃ (wherein A₁₀₃ is the C₆-C₆₀ aryl group).

As used herein, the C₇-C₆₀ arylalkyl group is -A₁₀₄A₁₀₅ (wherein A₁₀₄ is a C₁-C₅₄ alkylene group, and A₁₀₅ is a C₆-C₅₉ aryl group).

As used herein, the C₂-C₆₀ heteroaryl alkyl group is -A₁₀₆A₁₀₇ (wherein A₁₀₆ is a C₁-C₅₉ alkylene group, and A₁₀₇ is a C₁-C₅₉ heteroaryl group).

As used herein, “R₁ₒₐ” is
deuterium (-D), —F, —CI, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, C₃-C₆₀ carbocyclic group, C₁-C₆₀ heterocyclic group, C₆-C₆₀ aryloxy group, C₆-C₆₀ arylthio group, C₇-C₆₀ arylalkyl group, C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —CI, —Br, —I, a hydroxyl group, a cyano group, a nitro group, C₁-C₆₀ alkyl group, C₂-C₆₀ alkenyl group, C₂-C₆₀ alkynyl group, C₁-C₆₀ alkoxy group, C₃-C₆₀ carbocyclic group, C₁-C₆₀ heterocyclic group, C₆-C₆₀ aryloxy group, C₆-C₆₀ arylthio group, C₇-C₆₀ arylalkyl group, C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

As used herein, Q₁ to Q₃, Q₁₁ to Q₁₃, Q₂₁ to Q₂₃ and Q₃₁ to Q₃₃ may each independently be hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

As used herein, the hetero atom refers to atoms other than carbon atom. Examples of the hetero atom may include O, S, N, P, Si, B, Ge, Se, or any combination thereof.

As used herein, the transition metal may include hafnium (Hf), tantalum (Ta), tungsten (W), rhenium (Re), osmium (Os), iridium (Ir), platinum (Pt), and/or gold (Au).

As used herein, “D” may refer to deuterium, “Ph” may refer to phenyl group, “Me” may refer to methyl group, “Et” may refer to ethyl group, “tert-Bu,” “^{t}Bu”, or “Bu^{t}” may refer to tert-butyl group, and “OMe” may refer to methoxy group.

As used herein, the “biphenyl group” refers to “phenyl group substituted with a phenyl group.” The “biphenyl group” belongs to “substituted phenyl group” with a “C₆-C₆₀ aryl group” as a substituent.

As used herein, the “terphenyl group” refers to “phenyl group substituted with a biphenyl group.” The “terphenyl group” may belong to i) “substituted phenyl group” in which a substituent is “C₆-C₆₀ aryl group substituted with a C₆-C₆₀ aryl group” and ii) “substituted phenyl group” having two substituents, each being “C₆-C₆₀ aryl group”.

As used herein, * and *′ represent binding sites with neighboring atoms in the relevant formula or moiety, unless otherwise defined.

As used herein, the x-axis, the y-axis, and the z-axis are not limited to the three axes of an orthogonal coordinate system, but may be interpreted in a broader sense including the same. For example, the x-axis, the y-axis, and the z-axis may be orthogonal to each other, but may not be orthogonal to one another facing different directions.

### EXAMPLES

### Synthesis Example 1: CuInGaS₂/ZnS/oleylamine

### 1) Synthesis of CuInGaS₂ Core

0.1 mmol to 1 mmol of CuI, 0.3 mmol to 1 mmol of Ga(acac)₃, and 0.1 mmol to 0.5 mmol of InCl₃ were mixed with 10 mmol to 50 mmol of oleylamine, 0.1 mmol to 1 mmol of trioctylphosphine oxide (TOPO), and 1 mmol to 20 mmol of trioctylamine (TOA) in a three-neck flask, and then the mixture was degassed and stirred at 120° C. for 60 minutes to remove oxygen and moisture therefrom, thereby forming a reaction mixture. Then, under an argon atmosphere, 1 mmol to 2 mmol of a sulfur (S)-containing oleylamine (sulfur-oleylamine; hereinafter, referred to as S-oleylamine) was added to the reaction mixture. After the temperature was raised to 240° C. and maintained for a certain (e.g., set or predetermined) period of time, the reaction mixture was cooled to 200° C. and 4.48 mmol of trioctylphosphine (TOP) was injected thereinto. Then, the reaction was performed for a certain (e.g., set or predetermined) period of time to synthesize a core.

### 2) Preparation of Sulfur-containing Precursor

Oleylamine was degassed at 120° C. for 1 hour and cooled to 50° C. Then, under a nitrogen atmosphere, sulfur (S) was added to oleylamine and sufficiently stirred to form S-containing oleylamine (S-oleylamine), as a S-containing precursor.

### 3) Synthesis of ZnS Shell and Oleylamine Ligand

The synthesized CuInGaS₂ core was diluted in toluene and purified by precipitation using ethanol. Then, the purified CuInGaS₂ core was dispersed in toluene and 0.1 mmol to 100 mmol of the core was added to 10 mL to 100 mL of trioctylamine and degassed at 120° C. Then, 1 mmol to 5 mmol of the S-containing oleylamine, which was maintained at a low temperature (50° C.), was added to the purified CuInGaS₂ core and stirred for 10 minutes. Subsequently, 1 mmol to 5 mmol of a zinc (Zn)-containing oleylamine (Zn-oleylamine) was added to the stirred composition, followed by reaction at 200° C. for 20 minutes to form a ZnS shell and an oleylamine ligand, thereby synthesizing quantum dot B1.

### Synthesis Example 2: CuInGaS₂/ZnS/mPEG4-COO—H

0.05 mmol of mPEG4-COOH was added to Quantum dot B1 and reacted at 100° C. for 2 hours such that 80% of the total number of moles of the oleylamine ligand was substituted with mPEG4-COO—H to synthesize Quantum dot B2 including CuInGaS₂ core/ZnS shell/mPEG4-COO—H ligand.

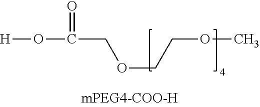

### Synthesis Example 3: CuInGaS₂/ZnS/mPEG4-S—H

0.05 mmol of mPEG4-S—H was added to Quantum dot B1 and reacted at 100° C. for 2 hours such that 80% of the total number of moles of the oleylamine ligand was substituted with mPEG4-S—H in Quantum dot B1 to synthesize Quantum dot B3 including CuInGaS₂ core/ZnS shell/mPEG4-S—H ligand.

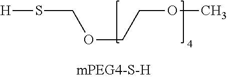

### Synthesis Example 4-1: CuInGaS₂/ZnS/Mg-COO-mPEG4 (Substitution Rate of 80%)

0.025 mmol of Mg-COO-mPEG4 was added to Quantum dot B1 and reacted at 100° C. for 4 hours such that 80% of the total number of moles of the oleylamine ligand was substituted with Mg-COO-mPEG4 to synthesize Quantum dot A1 including CuInGaS₂ core/ZnS shell/Mg-COO-mPEG4 ligand.

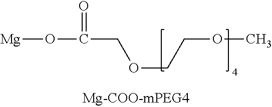

### Synthesis Example 4-2: CuInGaS₂/ZnS/Mg-COO-mPEG4 (Substitution Rate of 70%)

Quantum dot A1-1 including CuInGaS₂ core/ZnS shell/Mg-COO-mPEG4 ligand was synthesized in substantially the same manner as in Synthesis Example 4-1 except that 70% of the total number of moles of the oleylamine ligand was substituted with Mg-COO-mPEG4 in Quantum dot B1 by adding 0.02 mmol of Mg-COO-mPEG4 thereto and performing the reaction at 100° C. for 2 hours.

### Synthesis Example 4-3: CuInGaS₂/ZnS/Mg-COO-mPEG4 (Substitution Rate of 60%)

Quantum dot A1-2 including CuInGaS₂ core/ZnS shell/Mg-COO-mPEG4 ligand was synthesized in substantially the same manner as in Synthesis Example 4-1, except that 60% of the total number of moles of the oleylamine ligand was substituted with Mg-COO-mPEG4 in Quantum dot B1 by adding 0.01 mmol of Mg-COO-mPEG4 thereto and performing the reaction at 100° C. for 2 hours.

### Synthesis Example 5-1: CuInGaS₂/ZnS/Mg-S-mPEG4 (Substitution Rate of 80%)

Quantum dot A2 including CuInGaS₂ core/ZnS shell/Mg-S-mPEG4 ligand was synthesized in substantially the same manner as in Synthesis Example 4-1, except that 80% of the total number of moles of the oleylamine ligand was substituted with Mg-S-mPEG4 in Quantum dot B1 by adding 0.025 mmol of Mg-S-mPEG4 thereto and performing the reaction at 100° C. for 4 hours.

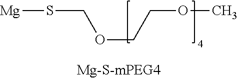

### Synthesis Example 5-2: CuInGaS₂/ZnS/Mg-S-mPEG4 (Substitution Rate of 70%)

Quantum dot A2-1 including CuInGaS₂ core/ZnS shell/Mg-S-mPEG4 ligand was synthesized in substantially the same manner as in Synthesis Example 5-1, except that 70% of the total number of moles of the oleylamine ligand was substituted with Mg-S-mPEG4 in Quantum dot B1 by adding 0.02 mmol of Mg-S-mPEG4 thereto and performing the reaction at 100° C. for 2 hours.

### Synthesis Example 5-3: CuInGaS₂/ZnS/Mg-S-mPEG4 (Substitution Rate of 60%)

Quantum dot A2-2 including CuInGaS₂ core/ZnS shell/Mg-S-mPEG4 ligand was synthesized in substantially the same manner as in Synthesis Example 5-1, except that 60% of the total number of moles of the oleylamine ligand was substituted with Mg-S-mPEG4 in Quantum dot B1 by adding 0.01 mmol of Mg-S-mPEG4 thereto and performing the reaction at 100° C. for 2 hours.

### Synthesis Example 6: CuInGaS₂/ZnS/Mn-COO-mPEG4 (Substitution Rate of 80%)

Quantum dot A3 including CuInGaS₂ core/ZnS shell/Mn-COO-mPEG4 ligand was synthesized in substantially the same manner as in Synthesis Example 5-1, except that 80% of the total number of moles of the oleylamine ligand was substituted with Mn-COO-mPEG4 in Quantum dot B1 by adding 0.025 mmol of Mn-COO-mPEG4 thereto and performing the reaction at 100° C. for 4 hours.

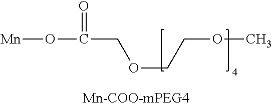

### Synthesis Example 7: CuInGaS₂/ZnS/Mn-S-mPEG4

Quantum dot A4 including CuInGaS₂ core/ZnS shell/Mn-S-mPEG4 ligand was synthesized by substituting 80% of the total number of moles of the oleylamine ligand with Mn-S-mPEG4 in Quantum dot B1 by adding 0.025 mmol of Mn-S-mPEG4 to Quantum dot B1 and performing the reaction at 100° C. for 4 hours.

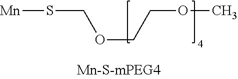

### Synthesis Example 8: CuInGaS₂/ZnS/Zn-COO-mPEG4

Quantum dot A5 including CuInGaS₂ core/ZnS shell/Zn-COO-mPEG4 ligand was synthesized by substituting 80% of the total number of moles of the oleylamine ligand with Zn-COO-mPEG4 in Quantum dot B1 by adding 0.025 mmol of Zn-COO-mPEG4 to Quantum dot B1 and performing the reaction at 100° C. for 4 hours.

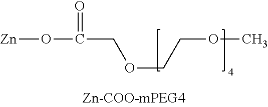

### Synthesis Example 9: CuInGaS₂/ZnS/Zn-S-mPEG4

Quantum dot A6 including CuInGaS₂ core/ZnS shell/Zn-S-mPEG4 ligand was synthesized by substituting 80% of the total number of moles of the oleylamine ligand with Zn-S-mPEG4 in Quantum dot B1 by adding 0.025 mmol of Zn-S-mPEG4 to Quantum dot B1 and performing the reaction at 100° C. for 4 hours.

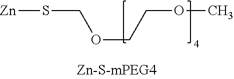

### Comparative Synthesis Example

Quantum dots B4 to B9 that are substantially identical to Quantum dots A1 or A2, except that the cores are modified as illustrated in Table 2, were prepared. For example, each of Quantum dots B4, B6, and B8 has substantially the same shell type or kind, substantially the same ligand type or kind, and substantially the same ligand substitution rate as those of Quantum dot A1, but a different core type or kind. Each of Quantum dots B5, B7, and B9 has substantially the same shell type or kind, substantially the same ligand type or kind, and substantially the same ligand substitution rate as those of Quantum dot A2, but a different core type or kind.

TABLE 2

Quantum dot

| No. | Core | Shell | Ligand |
|---|---|---|---|
| Quantum dot B4 | AgInGaS | ZnS | Mg—COO-mPEG4 |
| Quantum dot B5 | AgInGaS | ZnS | Mg—S-mPEG4 |
| Quantum dot B6 | CuInS | ZnS | Mg—COO-mPEG4 |
| Quantum dot B7 | CuInS | ZnS | Mg—S-mPEG4 |
| Quantum dot B8 | InGaP | ZnS | Mg—COO-mPEG4 |
| Quantum dot B9 | InGaP | ZnS | Mg—S-mPEG4 |

### Preparation Example 1: Film Before Exposure

30 wt % of each of the quantum dots according to the synthesis examples as described herein, 4 wt % of a TiO₂ scattering agent, 1 wt % of diphenyl(2,4,6-trimethylbenzoyl)phosphine oxide (TPO) photoinitiator, and 1 wt % of an additive were dissolved in 64 wt % of 1,6-hexanediol diacrylate monomer. The solution was coated on a quartz substrate to a thickness of 9 μm using a spin coater.

### Preparation Example 2: Film after Exposure

A film prepared in Preparation Example 1 was exposed to light having a maximum emission wavelength of 395 nm at 12 J to prepare an exposed film.

### Evaluation Example 1-1: Evaluation Based on Core Difference

External quantum efficiency (EQE) of the unexposed film prepared in Preparation Example 1 was measured by using a QE2100 device, and the results are shown in Table 3.

EQE of the exposed film prepared in Preparation Example 2 was measured in substantially the same manner, and the results are shown in Table 3.

EQE retention rates before and after exposure to light were calculated by Equation 1 and shown in Table 3.

$$EQE retention rate ( \% ) = ( EQE after exposure / EQE before exposure ) \times 100 \qquad Equation 1$$

TABLE 3

| | | | | EQE (%) | | |
|---|---|---|---|---|---|---|
| | | | | Before | After | EQE |
| | Quantum dot | | | light | light | retention |
| No. | Core | Shell | Ligand | exposure | exposure | rate (%) |
| Quantum | CuInGaS₂ | ZnS | Mg—COO- | 42.1 | 40.0 | 95.0 |
| dot A1 | | | mPEG4 | | | |
| Quantum | CuInGaS₂ | ZnS | Mg—S-mPEG4 | 42.5 | 41.7 | 98.1 |
| dot A2 | | | | | | |
| Quantum | AgInGaS | ZnS | Mg—COO- | 39.0 | 35.1 | 90.0 |
| dot B4 | | | mPEG4 | | | |
| Quantum | AgInGaS | ZnS | Mg—S-mPEG4 | 39.4 | 35.9 | 91.1 |
| dot B5 | | | | | | |
| Quantum | CuInS | ZnS | Mg—COO- | 31.3 | 28.1 | 89.8 |
| dot B6 | | | mPEG4 | | | |
| Quantum | CuInS | ZnS | Mg—S-mPEG4 | 33.1 | 30.3 | 91.5 |
| dot B7 | | | | | | |
| Quantum | InGaP | ZnS | Mg—COO- | 34.4 | 32.8 | 95.4 |
| dot B8 | | | mPEG4 | | | |
| Quantum | InGaP | ZnS | Mg—S-mPEG4 | 35.1 | 34.1 | 97.2 |
| dot B9 | | | | | | |

Based on Table 3, it was confirmed that Quantum dots A1 and A2, in which the CuInGaS₂ core having a small lattice mismatch with or substantially the same lattice constant as the lattice constant of the ZnS shell was used, exhibited higher EQEs both before and after exposure to light, compared to Quantum dots B4 and B5, in which the AgInGaS core having a relatively large lattice mismatch with the ZnS shell was used, Quantum dots B6 and B7, in which the GuInS core was used, and Quantum Dots B8 and B9, in which the InGaP core was used. In one or more embodiments, it was confirmed that Quantum dots A1 and A2 exhibited a higher FOE retention rate before and after light exposure compared to Quantum dots B4 to B7.

### Evaluation Example 1-2: Evaluation Based on Ligand Difference

The results of Evaluation Example 1-1 performed on Quantum dots A1 to A6 and B1 to B3 are shown in Table 4, respectively.

TABLE 4

| | | | | EQE (%) | | |
|---|---|---|---|---|---|---|
| | | | | Before | After | EQE |
| | Quantum dot | | | light | light | retention |
| No. | Core | Shell | Ligand | exposure | exposure | rate (%) |
| Quantum | CuInGaS₂ | ZnS | Mg—COO- | 42.1 | 40.0 | 95.0 |
| dot A1 | | | mPEG4 | | | |
| Quantum | CuInGaS₂ | ZnS | Mg—S-mPEG4 | 42.5 | 41.7 | 98.1 |
| dot A2 | | | | | | |
| Quantum | CuInGaS₂ | ZnS | Mn—COO- | 41.9 | 39.6 | 94.5 |
| dot A3 | | | mPEG4 | | | |
| Quantum | CuInGaS₂ | ZnS | Mn—S-mPEG4 | 42.3 | 40.5 | 95.7 |
| dot A4 | | | | | | |
| Quantum | CuInGaS₂ | ZnS | Zn—COO- | 42.8 | 38.7 | 90.4 |
| dot A5 | | | mPEG4 | | | |
| Quantum | CuInGaS₂ | ZnS | Zn—S-mPEG4 | 42.5 | 39.1 | 92.0 |
| dot A6 | | | | | | |
| Quantum | CuInGaS₂ | ZnS | oleylamine | Evaluation failure due to | | |
| dot B1 | | | | unsuccessful ink formulation | | |
| Quantum | CuInGaS₂ | ZnS | mPEG4-COO—H | 38.8 | 31.0 | 79.9 |
| dot B2 | | | | | | |
| Quantum | CuInGaS₂ | ZnS | mPEG4-S—H | 41.0 | 36.2 | 88.3 |
| dot B3 | | | | | | |

Based on Table 4, it was confirmed that Quantum dots A1 to A6 including the metal-containing ligands exhibited higher EQEs before and after light exposure and higher EQE retention rates before and after light exposure, compared to Quantum dots B2 and B3, in which the oleylamine ligand was substituted with the metal-free ligand. Also, it was confirmed that Quantum dot B1 including only the unsubstituted oleylamine ligand was not suitable for application to the inkjet process.

### Evaluation Example 1-3: Evaluation Based on Ligand Substitution Rate Difference

The results of Evaluation Example 1-1 performed on Quantum dots A1, A2, A1-1, and A2-1 and Comparative Quantum dots A1-2 and A2-2 are shown in Table 5.

TABLE 5

| | Quantum dot | | | EQE (%) | | EQE |
|---|---|---|---|---|---|---|
| | | | Ligand | Before | After | retention |
| | | | (substitution | light | light | rate |
| No. | Core | Shell | rate) | exposure | exposure | (%) |
| Quantum dot | CuInGaS₂ | ZnS | Mg—COO-mPEG4 | 42.1 | 40.0 | 95.0 |
| A1 | | | (80%) | | | |
| Quantum dot | CuInGaS₂ | ZnS | Mg—S-mPEG4 | 42.5 | 41.7 | 98.1 |
| A2 | | | (80%) | | | |
| Quantum dot | CuInGaS₂ | ZnS | Mg—COO-mPEG4 | 42.0 | 39.6 | 94.4 |
| A1-1 | | | (70%) | | | |
| Quantum dot | CuInGaS₂ | ZnS | Mg—S-mPEG4 | 41.8 | 40.0 | 95.8 |
| A2-1 | | | (70%) | | | |
| Comparative | CuInGaS₂ | ZnS | Mg—COO-mPEG4 | 41.5 | 37.4 | 90.1 |
| Quantum dot | | | (60%) | | | |
| A1-2 | | | | | | |
| Comparative | CuInGaS₂ | ZnS | Mg—S-mPEG4 | 42.2 | 37.5 | 88.9 |
| Quantum dot | | | (60%) | | | |
| A2-2 | | | | | | |

Based on Table 5, it was confirmed that Quantum dots A1, A2, A1-1 and A2-1, in which 70% or more of the oleylamine ligand was substituted with the metal-containing ligand, exhibited higher EQEs at least before light exposure or after light exposure, and/or higher FOE retention rates both before and after light exposure, compared to Comparative Quantum dots A1-2 and A2-2, in which less than 70% of the oleylamine ligand was substituted with the metal-containing ligand.

### Evaluation Example 2: Evaluation on Light Resistance Reliability

The film according to Preparation Example 2 was capped with a SiON capping layer having a thickness of 0.3 μm. Variations of the capped film in external quantum efficiency (FOE) over time was measured under blue light (450 nm) with a brightness of 50,000 nit, and relative FOE values were calculated by setting the initial EQE to 100% and shown in Table 6.

TABLE 6

| Quantum | | | Ligand | 0 hr | 24 hr | 96 hr | 144 hr | 240 hr | 360 hr | 500 hr |
|---|---|---|---|---|---|---|---|---|---|---|
| dot | Core | Shell | (substitution rate) | (%) | (%) | (%) | (%) | (%) | (%) | (%) |
| A2 | CuInGaS₂ | ZnS | Mg—S-mPEG4 | 100 | 97.2 | 95.6 | 91.1 | 89.5 | 88.9 | 88.1 |
| | | | (80%) | | | | | | | |
| A2-1 | | | Mg—S-mPEG4 | 100 | 97.2 | 98.1 | 96.1 | 90.0 | 80.2 | 78.1 |
| | | | (70%) | | | | | | | |
| A2-2 | | | Mg—S-mPEG4 | 100 | 98.9 | 98.5 | 94.1 | 90.2 | 78.9 | 70.7 |
| | | | (60%) | | | | | | | |
| A4 | | | Mn—S-mPEG4 | 100 | 96.5 | 95.2 | 92.4 | 86.7 | 87.7 | 86.1 |
| | | | (80%) | | | | | | | |
| A6 | | | Zn—S-mPEG4 | 100 | 95.9 | 96.1 | 91.9 | 85.1 | 75.2 | 65.0 |
| | | | (80%) | | | | | | | |
| B1 | | | oleylamine | Evaluation failure due to | | | | | | |
| | | | | unsuccessful ink formulation | | | | | | |
| B3 | | | mPEG4-S—H | 100 | 99.9 | 89.2 | 88.7 | 71.3 | 55.5 | 43.9 |
| | | | (80%) | | | | | | | |
| B5 | AgInGaS | | Mg—S-mPEG4 | 100 | 88.5 | 70.8 | 64.9 | 50.9 | 42.2 | 40.1 |
| | | | (80%) | | | | | | | |
| B7 | CuInS | | Mg—S-mPEG4 | 100 | 93.6 | 90.2 | 85.1 | 77.7 | 69.9 | 59.7 |
| | | | (80%) | | | | | | | |
| B9 | InGaP | | Mg—S-mPEG4 | 100 | 90.9 | 81.1 | 82.0 | 70.3 | 59.8 | 50.0 |
| | | | (80%) | | | | | | | |

Although Quantum dots A2, A4, A6, and B3 include sulfur (S) in the ligand and have substantially the same ligand substitution rate, they are different in that whether the ligand includes a metal and types or kinds of the metal. Referring to Table 6, it was confirmed that Quantum dots A2, A4, and A6 according to one or more embodiments had superior light resistance reliability over time to Quantum dot B3 including the metal-free ligand.

Also, although Quantum dots A2, B5, B7, and B9 include substantially the same type or kind of ligand and substantially the same ligand substitution rate, the types or kinds of the core are different. It was confirmed that Quantum dot A2 according to one or more embodiments including the core with a relatively small lattice mismatch with the shell, had superior light resistance reliability over time to Quantum dots B5, B7, and B9 including the core with a large lattice mismatch with the shell.

As confirmed in Table 4, Quantum dot B1 including only the unsubstituted oleylamine ligand was not suitable for application to the inkjet process.

Also, it was confirmed that Quantum dots A2 and A2-1 according to one or more embodiments having relatively greater substitution rates of the metal-containing ligand had superior light resistance reliability over time to Comparative Quantum dot A2-2 having a relatively smaller substitution rate of the metal-containing ligand.

Therefore, the quantum dot according to one or more embodiments may have long lifespan because the EQE maintains above a certain level for a long period of time.

A high external quantum efficiency (EQE) may be obtained if (e.g., when) the lattice mismatch between the core and the shell is small or the lattice constants are substantially the same. As the conduction band minimum (CBM) of the shell increases, the possibility that excited electrons migrate from the core to the shell during light exposure may decrease. As a result, the phenomenon that the ligand detaches from the surface of the quantum dot caused by migration of excited electrons from the core to the shell may be prevented or suppressed (or reduced). Therefore, external quantum efficiency retention rates before and after light exposure may increase. Also, by combining the core, the shell, and the metal-containing ligand according to one or more embodiments, long lifespan may be obtained because the EQE retention rate over time under blue light is high indicating that the EQE is maintained at a certain level or higher for a long time.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. A quantum dot comprising:
a core comprising CuInGaS₂;
a shell around at least a portion of the core; and
a metal-containing ligand around at least a portion of the shell,
wherein the metal-containing ligand comprises a metal and a repeating unit represented by Formula 1: 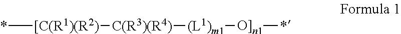
wherein, in Formula 1,
L¹ is a C₁-C₆₀ alkylene group unsubstituted or substituted with at least one R₁₀ₐ,
m1 is 0 or 1,
n1 is 1 to 20,
R¹ to R⁴ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
wherein R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁), —S(═O)₂(Q₁), —P(═O)(Q₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof, and
* and *′ are each independently a binding site with a neighboring atom.

2. The quantum dot as claimed in claim 1, wherein the quantum dot absorbs light having a wavelength of about 400 nm to about 500 nm and emits light having a wavelength of about 600 nm to about 680 nm.

3. The quantum dot as claimed in claim 1, wherein a difference between a conduction band minimum (CBM) of the core and a CBM of the shell surrounded by the metal-containing ligand is greater than about 0.3 eV.

4. The quantum dot as claimed in claim 1, wherein a difference between a lattice constant of the core and a lattice constant of the shell is 0 Å to about 0.2 Å.

5. The quantum dot as claimed in claim 1, wherein the shell comprises ZnS, ZnMgS, ZnMnS, ZnAlS, MnS, or any combination thereof.

6. The quantum dot as claimed in claim 1, wherein, based on a total number of moles of the ligand around the shell, a mole fraction of the metal-containing ligand is about 70% to 100%.

7. The quantum dot as claimed in claim 1, wherein the metal-containing ligand has a molecular weight of about 200 g/mol to about 1000 g/mol.

8. The quantum dot as claimed in claim 1, wherein the metal is Mg, Mn, or Zn.

9. The quantum dot as claimed in claim 1, wherein m1 in Formula 1 is 0.

10. The quantum dot as claimed in claim 1, wherein, in Formula 1,
R¹ to R⁴ are each independently hydrogen, deuterium, —F, —Cl, —Br, —I, a hydroxyl group, a cyano group, or a C₁-C₆₀ alkyl group unsubstituted or substituted with at least one R₁₀ₐ.

11. The quantum dot as claimed in claim 1, wherein the metal-containing ligand is represented by Formula 2: 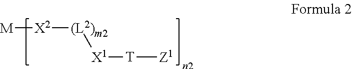
wherein, in Formula 2,
M is the metal,
n2 is 1 to 6,
T is a repeating unit represented by Formula 1, * of Formula 1 is a binding site with X¹ of Formula 2, and *′ of Formula 1 is a binding site with Z¹ of Formula 2,
L² is a C₁-C₆₀ alkylene group unsubstituted or substituted with at least one R₁₀ₐ,
m2 is 0 or 1,
X¹ is O or S,
X² is *¹—O(C═O)—*², *¹—O—*², *¹—S—*², *¹—N(Z²)—*² or *¹—P(Z²)—*², wherein *¹ is a binding site with M and *² is a binding site with L² or X¹,
Z¹ and Z² are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
R₁₀ₐ and Q₁ to Q₃ are the same as defined in Formula 1, respectively.

12. The quantum dot as claimed in claim 11, wherein n2 in Formula 2 is 1.

13. An electronic device comprising:
a first electrode;
a second electrode opposite to the first electrode;
an intermediate layer between the first electrode and the second electrode;
a thin film transistor electrically connected to the first electrode; and
the quantum dot as claimed in claim 1.

14. The electronic device as claimed in claim 13, wherein the intermediate layer comprises a hole transport region, an emission layer, and an electron transport region that are sequentially provided on the first electrode.

15. The electronic device as claimed in claim 14, wherein the emission layer comprises the quantum dot.

16. The electronic device as claimed in claim 14, further comprising a color conversion layer on the second electrode,
wherein the color conversion layer comprises the quantum dot.

17. The electronic device as claimed in claim 13, wherein the intermediate layer comprises a plurality of stacks,
wherein each of the plurality of stacks comprises a hole transport region, an emission layer, and an electron transport region that are sequentially provided on the first electrode.

18. The electronic device as claimed in claim 13, further comprising a color filter, a touchscreen layer, a polarizing layer, or any combination thereof.

19. The electronic device as claimed in claim 13, further comprising:
a backlight below the thin film transistor; and
a performance improvement layer between the backlight and the thin film transistor,
wherein the performance improvement layer comprises the quantum dot.

20. An electronic apparatus comprises:
the electronic device as claimed in claim 13; and
at least one selected from among a processor to transmit a signal to the electronic device, a memory to store data information for operation of the electronic device, and a power module to supply power for operation of the electronic device.
